(19) United States
(12) Patent Application Publication
(10) Pub. No.: US 2024/0315005 A1
(43) Pub. Date: Sep. 19, 2024

(54) SEMICONDUCTOR DEVICES

(71) Applicant: SAMSUNG ELECTRONICS CO., LTD., Suwon-si (KR)

(72) Inventors: Kiseok LEE, Suwon-si (KR); Sangjae PARK, Suwon-si (KR); Huijung KIM, Suwon-si (KR); Taejin PARK, Suwon-si (KR); Chansic YOON, Suwon-si (KR); Myeongdong LEE, Suwon-si (KR)

(21) Appl. No.: 18/388,266

(22) Filed: Nov. 9, 2023

(30) Foreign Application Priority Data
Mar. 13, 2023 (KR) 10-2023-0032573

(51) Int. Cl. H10B 12/00

(52) U.S. Cl. CPC H10B 12/315; H10B 12/0335; H10B 12/482

(57) ABSTRACT

A semiconductor device includes an active pattern array including active patterns on a substrate; a first contact structure on a central portion of each active pattern; a bit line structure on the first contact structure; a second contact structure on an end of each active pattern; a third contact structure on the second contact structure; and a capacitor electrically connected to the third contact structure, wherein the active pattern array includes active pattern rows spaced apart from each other in a second direction parallel the substrate, the active pattern rows include active patterns spaced apart from each other in a first direction parallel to the substrate, the active patterns extend in a third direction having an acute angle with the first/second directions, the active patterns in the rows are aligned in the first direction, and the second contact structure has a rectangular shape in a plan view.

### CROSS-REFERENCE TO RELATED APPLICATION

This application claims priority under 35 U.S.C. § 119 to Korean Patent Application No. 10-2023-0032573 filed on Mar. 13, 2023, in the Korean Intellectual Property Office, the disclosure of which is hereby incorporated by reference in its entirety.

### 1. FIELD

Embodiments relate to a semiconductor device.

### 2. DESCRIPTION OF THE RELATED ART

A DRAM device may include gate structures which extend through upper portions of active patterns in a first direction, bit line structures on central portions of the active patterns, each of which extends in a second direction, contact plug structures on opposite end portions, respectively, of corresponding ones of the active patterns, and capacitors on corresponding ones, respectively, of the contact plug structures.

### SUMMARY

The embodiments may be realized by providing a semiconductor device including a substrate; an active pattern array including active patterns on the substrate; a first contact structure on a central portion of each of the active patterns; at least one bit line structure on the first contact structure; a second contact structure on an end portion of each of the active patterns; at least one third contact structure on the second contact structure; and a capacitor electrically connected to the at least one third contact structure, wherein the active pattern array includes active pattern rows spaced apart from each other in a second direction substantially parallel to an upper surface of the substrate, each of the active pattern rows includes the active patterns spaced apart from each other in a first direction substantially parallel to the upper surface of the substrate and substantially orthogonal to the second direction, each of the active patterns extends in a third direction having an acute angle with the first direction and the second direction, the active patterns in each of the active pattern rows are aligned in the first direction, and the second contact structure has a rectangular shape in a plan view.

The embodiments may be realized by providing a semiconductor device including a substrate; an active pattern on the substrate; a first contact structure on a central portion of the active pattern; a bit line structure on the first contact structure; a second contact structure on an end portion of the active pattern; a third contact structure on the second contact structure; a spacer surrounding the third contact structure and having a lower portion and an upper portion, a thickness of the upper portion being smaller than a thickness of the lower portion; a landing pad on the third contact structure; and a capacitor on the landing pad.

The embodiments may be realized by providing a semiconductor device including a substrate; an active pattern array including active patterns on the substrate; an isolation pattern on the substrate, the isolation pattern covering sidewalls of the active patterns; gate structures spaced apart from each other in a second direction substantially parallel to an upper surface of the substrate, each of the gate structures extending through upper portions of the active patterns and the isolation pattern in a first direction substantially parallel to the upper surface of the substrate and substantially orthogonal to the second direction; bit line structures on central portions of the active patterns and the isolation pattern, each of the bit line structures extending in the second direction, and the bit line structures being spaced apart from each other in the first direction; a first contact structure on an end portion of each of the active patterns; a second contact structure on the first contact structure; and a capacitor electrically connected to the second contact structure, wherein the active pattern array includes active pattern rows spaced apart from each other in the second direction, each of the active pattern rows includes the active patterns spaced apart from each other in the first direction, each of the active patterns extends in a third direction having an acute angle with the first direction and the second direction, the active patterns in each of the active pattern rows are aligned in the first direction, and the second contact structure has a rectangular shape in a plan view.

### BRIEF DESCRIPTION OF THE DRAWINGS

Features will be apparent to those of skill in the art by describing in detail exemplary embodiments with reference to the attached drawings in which:

FIGS. 1 to 3 are a plan view and cross-sectional views illustrating a semiconductor device in accordance with example embodiments.

FIGS. 4 to 42 are plan views and cross-sectional views of stages in a method of manufacturing a semiconductor device in accordance with example embodiments.

FIGS. 43 and 44 are cross-sectional views illustrating a semiconductor device in accordance with example embodiments.

FIGS. 45 to 47 are a plan view and cross-sectional views illustrating a semiconductor device in accordance with example embodiments.

FIGS. 48 to 65 are plan views and cross-sectional views of stages in a method of manufacturing a semiconductor device in accordance with example embodiments.

FIGS. 66 to 68 are a plan view and cross-sectional views illustrating a semiconductor device in accordance with example embodiments.

FIGS. 69 to 80 are plan views and cross-sectional views of stages in a method of manufacturing a semiconductor device in accordance with example embodiments.

FIGS. 81 to 83 are a plan view and cross-sectional views illustrating a semiconductor device in accordance with example embodiments.

FIGS. 84 to 92 are plan views and cross-sectional views of stages in a method of manufacturing a semiconductor device in accordance with example embodiments.

### DETAILED DESCRIPTION

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively, and are not intended to imply or require sequential inclusion.

Hereinafter, two directions among horizontal directions that are substantially parallel to an upper surface of a substrate 100, which may be substantially orthogonal to each other, may be referred as first and second directions D1 and D2, respectively, and a direction among the horizontal directions, which may have an acute angle with respect to each of the first and second directions D1 and D2 and substantially orthogonal to each other, may be referred to as third and fourth directions D3 and D4, respectively.

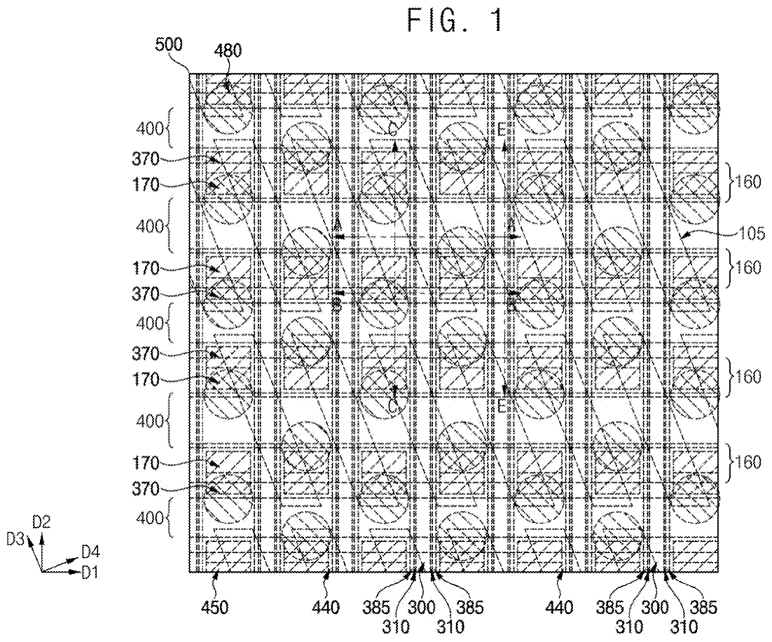

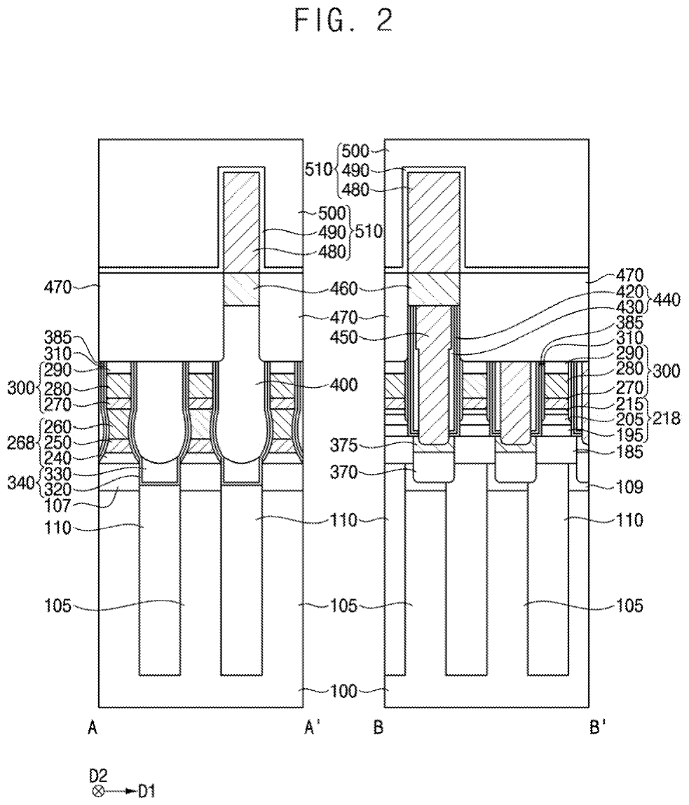

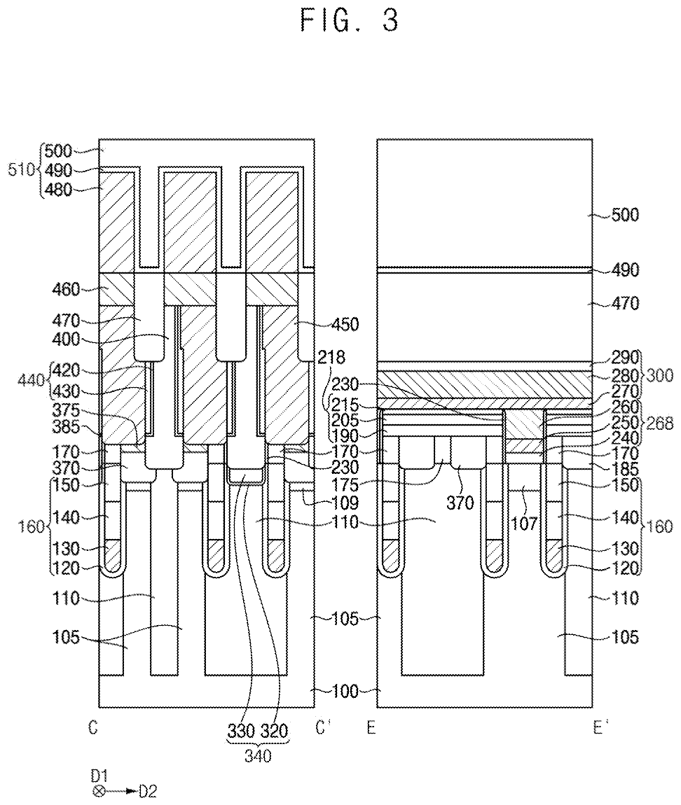

FIGS. 1 to 3 are a plan view and cross-sectional views illustrating a semiconductor device in accordance with example embodiments. Specifically, FIG. 1 is the plan view, FIG. 2 includes cross-sectional views taken along line A-A′ and line B-B′ of FIG. 1, and FIG. 3 includes cross-sectional views taken along line C-C′ and line E-E′ of FIG. 1.

The semiconductor device may include an active pattern 105, a gate structure 160, a bit line structure 300, a filling structure 340, a buffer structure 218, a first fence pattern 400, a first contact structure 268, a second contact structure 370, a third contact structure 450, a first spacer structure 440, a landing pad 460, and a capacitor 510 on a substrate 100.

The semiconductor device may further include an isolation pattern 110, a first mold layer 170, a second mold layer 175, a third mold layer 180, a first spacer 230, a second spacer 310, a third spacer 385, a second ohmic contact pattern 375, and an insulation pattern 470.

The substrate 100 may include silicon, germanium, silicon-germanium, or a III-V group compound semiconductor, e.g., GaP, GaAs, GaSb, or the like. In an implementation, the substrate 100 may be a silicon-on-insulator (SOI) substrate or a germanium-on-insulator (GOI) substrate. As used herein, the term “or” is not necessarily an exclusive term, e.g., “A or B” would include A, B, or A and B.

The active pattern 105 may be defined on the substrate 100, and a sidewall of the active pattern 105 may be covered by the isolation pattern 110 on the substrate 100.

The active pattern 105 may extend (e.g., lengthwise) in the third direction D3 to a certain length, and a plurality of active patterns 105 may be spaced apart from each other in the first direction D1 to form an active pattern row. In an implementation, a plurality of active pattern rows may be spaced apart from each other in the second direction D2 to form an active pattern array. In an implementation, the active patterns 105 in each of the active pattern rows may be aligned with each other in the first direction D1. In an implementation, end portions of the active patterns 105 disposed in the first direction D1, which may correspond to each other in the first direction D1, may be aligned with each other along the first direction D1.

The active pattern 105 may include a material substantially the same as a material of the substrate 100, and the isolation pattern 110 may include an oxide, e.g., silicon oxide. A first impurity region 107 may be at an upper portion of a central portion of the active pattern 105 in the third direction D3, and a second impurity region 109 may be at an upper portion of each of end portions of the active pattern 105 in the third direction D3. Each of the first and second impurity regions 107 and 109 may include, e.g., n-type impurities or p-type impurities.

The gate structure 160 may extend in the first direction D1 through upper portions of the active pattern 105 and the isolation pattern 110, and a plurality of gate structures 160 may be spaced apart from each other in the second direction D2. The gate structure 160 may include a first conductive pattern 130, a second conductive pattern 140, and a first mask 150 sequentially stacked in a vertical direction substantially perpendicular to an upper surface of the substrate 100, and further include a gate insulation pattern 120, which may cover sidewalls of the first conductive pattern 130, the second conductive pattern 140, and the first mask 150, and a lower surface of the first conductive pattern 130.

The gate insulation pattern 120 may include an oxide, e.g., silicon oxide, the first conductive pattern 130 may include, e.g., a metal, a metal nitride, a metal silicide, or the like, the second conductive pattern 140 may include, e.g., polysilicon doped with n-type impurities or p-type impurities, and the first mask 150 may include an insulating nitride, e.g., silicon nitride.

In an implementation, two gate structures 160 spaced apart from each other in the second direction D2 may extend through an upper portion of a single active pattern 105.

In an implementation, a dummy gate structure extending in the first direction D1 through an upper portion of the isolation pattern 110 between the active pattern rows and an upper portion of each of the active patterns 105 adjacent to the upper portion of the isolation pattern 110 may be further included.

The first contact structure 268 may be on the central portion of the active pattern 105, and may include a pad 240, a first ohmic contact pattern 250, and a second metal pattern 260 sequentially stacked. In an implementation, a plurality of first contact structures 268 may be spaced apart from each other in the first and second directions D1 and D2. The pad 240 may include, e.g., polysilicon doped with impurities, the first ohmic contact pattern 250 may include a metal silicide, e.g., cobalt silicide, nickel silicide, titanium silicide, or the like, and the second metal pattern 260 may include a metal, e.g., tungsten, niobium, copper, aluminum, or the like.

A first mold layer 170, second mold layer 175, and third mold layer 185 may be on the active pattern 105 and the isolation pattern 110. The first mold layer 170 may extend in the first direction D1 and a plurality of the first mold layers 170 may be spaced apart from each other in the second direction D2. A plurality of the second mold layers 175 may be spaced apart from each other in the first and second directions D1 and D2, and a plurality of third mold layers 185 may be spaced apart from each other in the first and second directions D1 and D2. The second mold layers 175 and the third mold layers 185 may be under the bit line structure 300.

In an implementation, upper surfaces of the first and second mold layers 170 and 175 and an upper surface of the third mold layer 185 may be substantially coplanar with each other. In an implementation, the third mold layer 185 may have a lower surface lower than (e.g., closer to the substrate 100 in the vertical direction than) lower surfaces of the first and second mold layers 170 and 175.

The first mold layer 170 and the second mold layer 175 may include an insulating nitride, e.g., silicon nitride, and the third mold layer 185 may include an oxide, e.g., silicon oxide.

The buffer structure 218 may be between the third mold layer 185 and the bit line structure 300, and may include first to third buffers 195, 205, and 215 sequentially stacked in the vertical direction. A plurality of buffer structures 218 may be spaced apart from each other in the first and second directions D1 and D2. The first buffer 195 may include an oxide, e.g., silicon oxide, the second buffer 205 may include a high-k material, and the third buffer 215 may include a nitride, e.g., silicon nitride.

The bit line structure 300 may extend in the second direction D2, and a plurality of the bit line structures 300 may be spaced apart from each other in the first direction D1. The bit line structure 300 may overlap the central portion of the active pattern 105 in the vertical direction, and the first contact structure 268 may be between the bit line structure 300 and the active pattern 105. The bit line structure 355 may contact an upper surface of the buffer structure 218.

The bit line structure 300 may include a barrier pattern 270, a third metal pattern 280, and a second mask 290 sequentially stacked in the vertical direction. The barrier pattern 270 may include a metal nitride, e.g., titanium nitride or a metal silicon nitride, e.g., titanium silicon nitride, the third metal pattern 280 may include a metal, e.g., tungsten, and the second mask 290 may include an insulating nitride, e.g., silicon nitride.

The filling structure 340 may be on the isolation pattern 110 between the first contact structures 268 neighboring in the first direction D1. The filling structure 340 may have a lower surface lower than a lower surface of the first contact structure 268 or a lower surface of the third mold layer 185.

The filling structure 340 may include a second filling pattern 330 and a first filling pattern 320 covering a sidewall and a lower surface of the second filling pattern 330. The first filling pattern 320 may include an oxide, e.g., silicon oxide or silicon oxycarbide, and the second filling pattern 330 may include an insulating nitride, e.g., silicon nitride or silicon oxycarbonitride.

The first spacer 230 may be on a sidewall of the first mold layer 170 and a sidewall of the buffer structure 218, and may contact a sidewall of the first contact structure 268. The first spacer 230 may include an insulating nitride, e.g., silicon nitride.

The second spacer 310 may be on a sidewall of the bit line structure 300, a sidewall of the first contact structure 268, and sidewalls of the second and third buffers 205 and 215, and the third spacer 385 may be on an outer sidewall of the second spacer 310 and a sidewall of the first buffer 195. Each of the second and third spacers 310 and 385 may include an insulating nitride, e.g., silicon nitride.

The second contact structure 370 may be on each of opposite end portions of the active pattern 105, and may include, e.g., polysilicon doped with impurities. The second ohmic contact pattern 375 may be on the second contact structure 370, and may include, e.g., metal silicide.

In an implementation, the second contact structure 370 may have a rectangular shape in a plan view.

The third contact structure 450 may be on the second ohmic contact pattern 375, and may include a metal, e.g., tungsten, copper, aluminum, or the like. In an implementation, the third contact structure 450 may include a lower portion having a first width and an upper portion having a second width greater than the first width. In an implementation, the third contact structure 450 may have a rectangular shape in a plan view.

The first spacer structure 440 may surround a sidewall of the third contact structure 450, and may include a fifth spacer 430 and a fourth spacer 420 stacked from the sidewall of the third contact structure 450 in the horizontal direction. The fourth spacer 420 may include an insulating nitride, e.g., silicon nitride, and the fifth spacer 430 may include an oxide, e.g., silicon oxide.

In an implementation, a thickness of an upper portion of the fifth spacer 430 may be smaller than a thickness of a lower portion of the fifth spacer 430. In an implementation, the thickness of the upper portion surrounding an upper portion of the third contact structure 450 may be thinner than the thickness of the lower portion of the fifth spacer 430 surrounding a lower portion of the third contact structure 450.

The first fence pattern 400 may overlap the central portion of the active pattern 105 in the vertical direction and may extend in the first direction D1, or may overlap in the vertical direction the end portions of the active patterns 105 facing each other in the third direction D3 and a portion of the isolation pattern 110 therebetween and may extend in the first direction D1. The first fence pattern 400 may be between the third contact structures 450 neighboring in the second direction D2. In an implementation, the first fence pattern 400 may extend in the first direction D1 through an upper portion of the bit line structure 300, and a lower surface of a portion of the first fence pattern 400 in an area where the bit line structure 300 is formed may be higher than a lower surface of portions of the first fence pattern 400 in other areas.

The first fence pattern 400 may include an insulating nitride, e.g., silicon nitride, silicon oxycarbonitride, or the like.

The landing pad 460 may contact an upper surface of the third contact structure 450, and a plurality of the landing pads 460 may be spaced apart from each other in the first and second directions D1 and D2. In an implementation, the landing pad 460 may have a shape such as a circle, an ellipse, a polygon, a polygon with rounded corners, or the like, in a plan view, and the landing pads 460 may be arranged in a honeycomb pattern. The landing pad 460 may include a metal, a metal nitride, or the like.

The insulation pattern 470 may cover sidewalls of the landing pads 460, and may partially extend through the upper portion of the bit line structure 300 and an upper portion of the first fence pattern 400. The insulation pattern 470 may include an insulating nitride, e.g., silicon nitride.

The capacitor 510 may include a first electrode 480, a dielectric layer 490, and a second electrode 500 sequentially stacked, and the first electrode 480 may contact an upper surface of the landing pad 460. Each of the first and second electrodes 480 and 500 may include a metal, a metal nitride, a metal silicide, silicon-germanium doped with impurities, or the like, and the dielectric layer 490 may include a metal oxide having a high dielectric constant.

In the semiconductor device, the bit line structure 300 may be electrically connected to the central portion of the active pattern 105 through the first contact structure 268, and the capacitor 510 may be electrically connected to the end portion of the active pattern 105 through the landing pad 460, the third contact structure 450, the second ohmic contact pattern 37,5 and the second contact structure 370.

The second contact structure 370 may be between the third mold layers 185 and the first and second mold layers 170 and 175, and may have a rectangular shape in a plan view. The third contact structure 450 may be between the bit line structures 300 and the first fence patterns 400, and may have a rectangular shape in a plan view. Thus, the second contact structure 370 may establish a broad surface contact with the active pattern 105, and the third contact structure 450 may establish a broad surface contact with the second contact structure 370. Accordingly, an electrical connection between the capacitor 510 and the active pattern 105 may be enhanced.

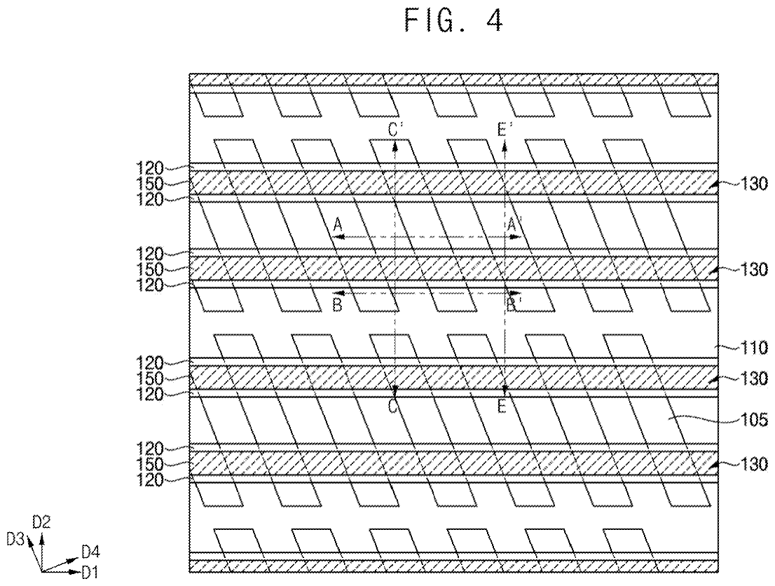

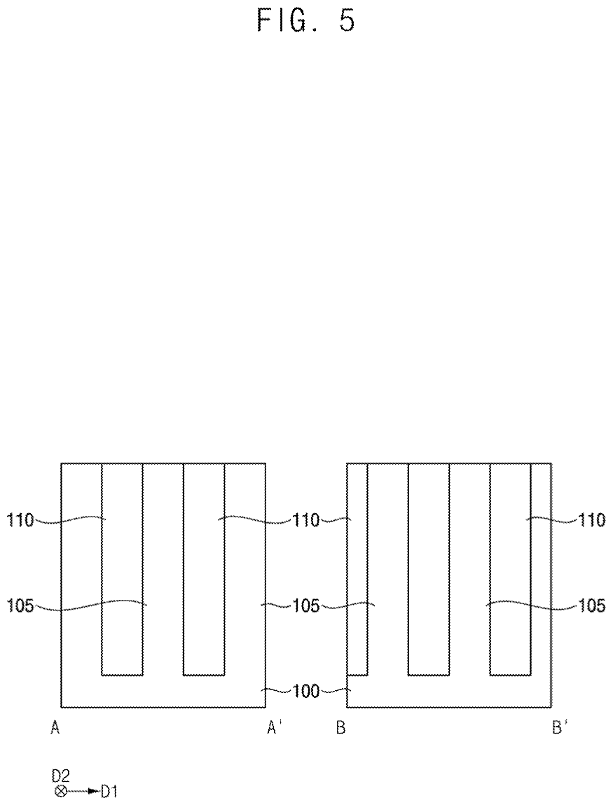

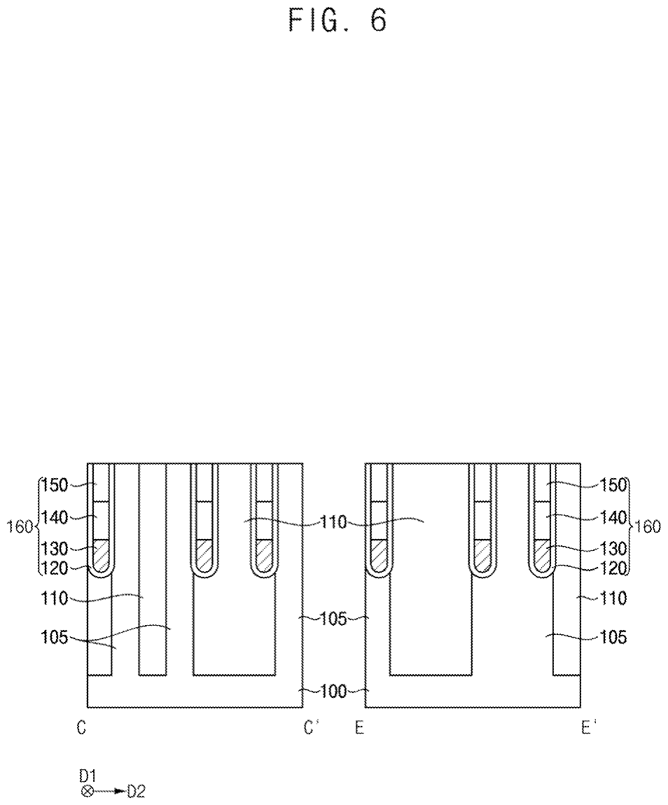

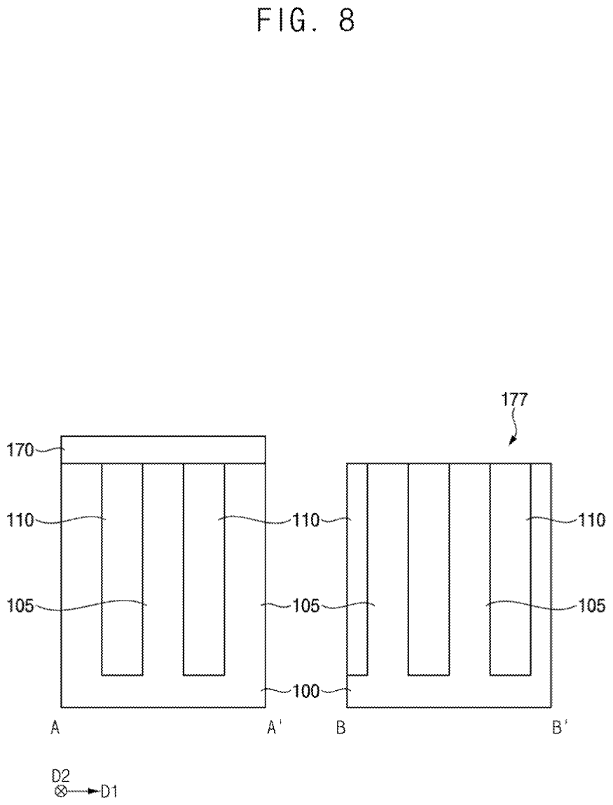

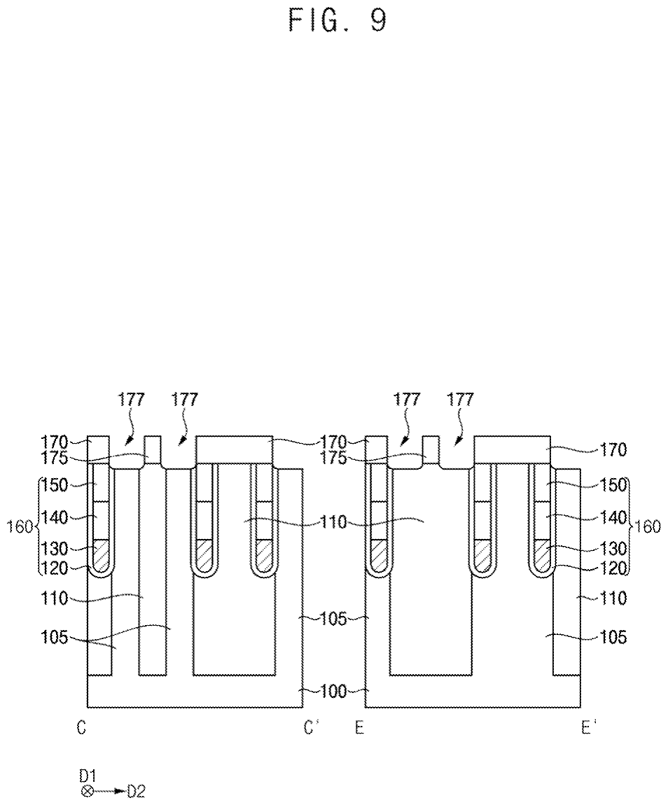

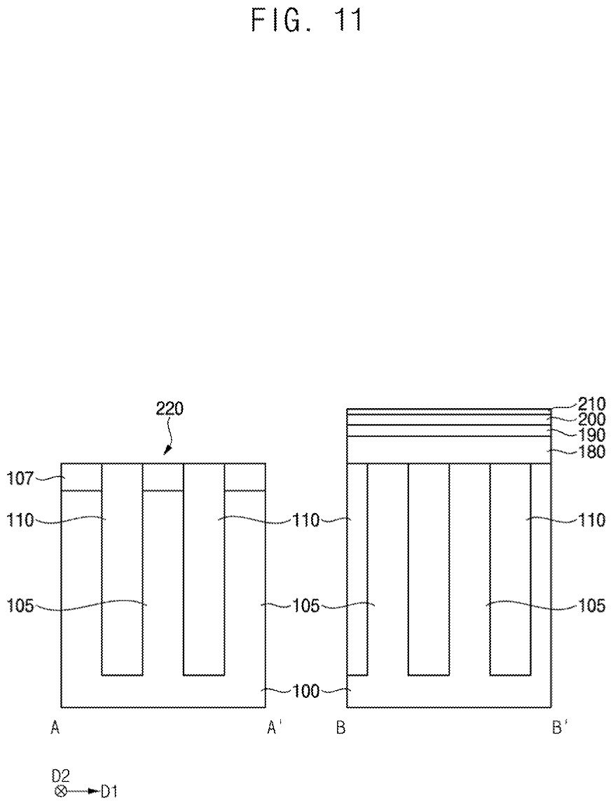

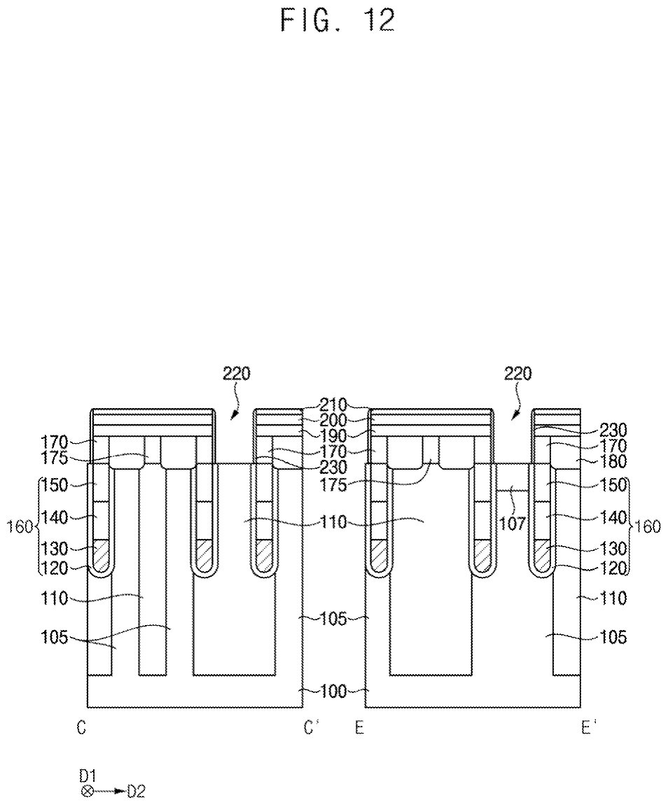

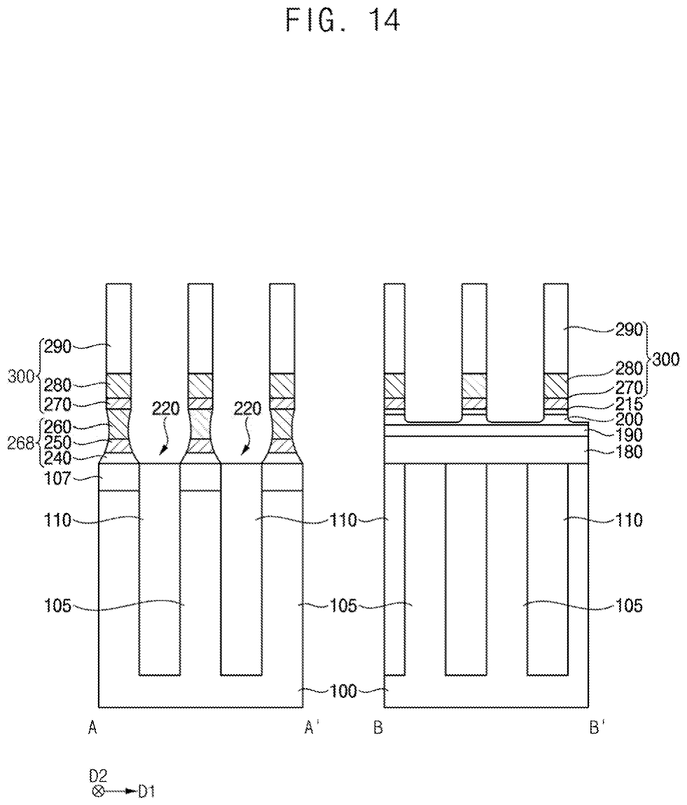

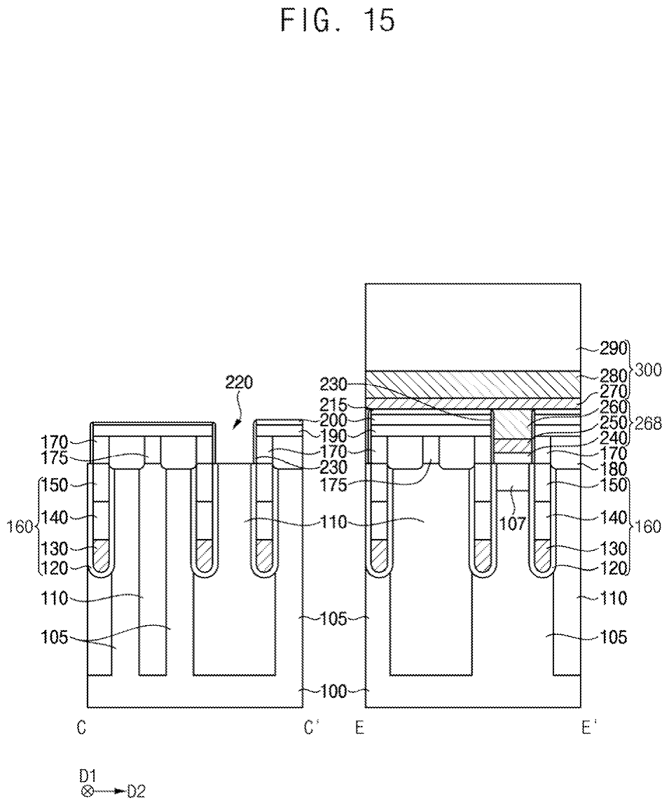

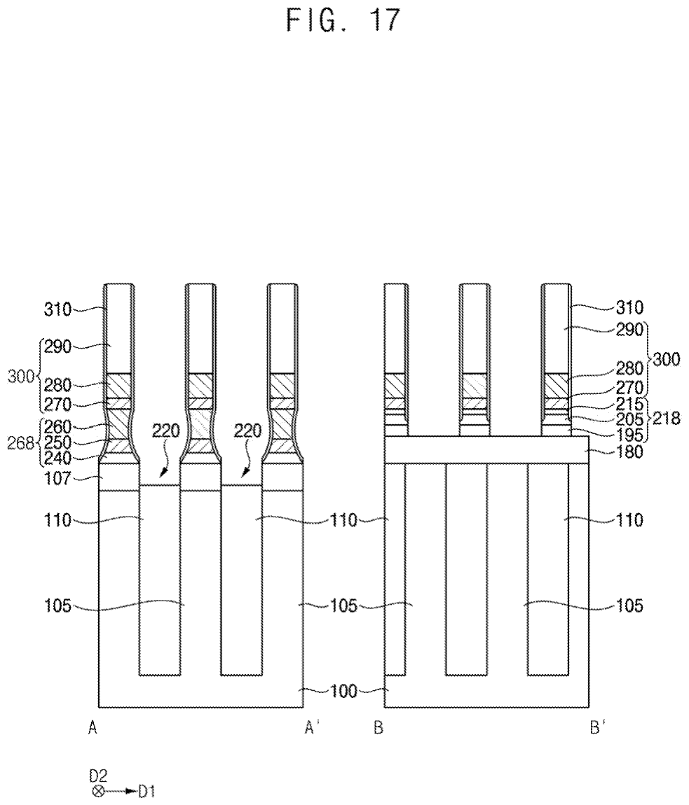

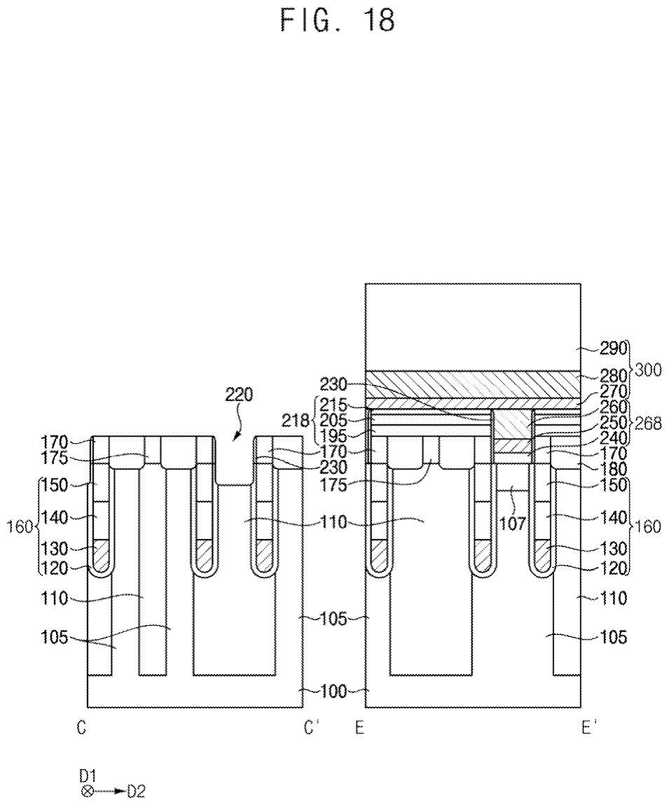

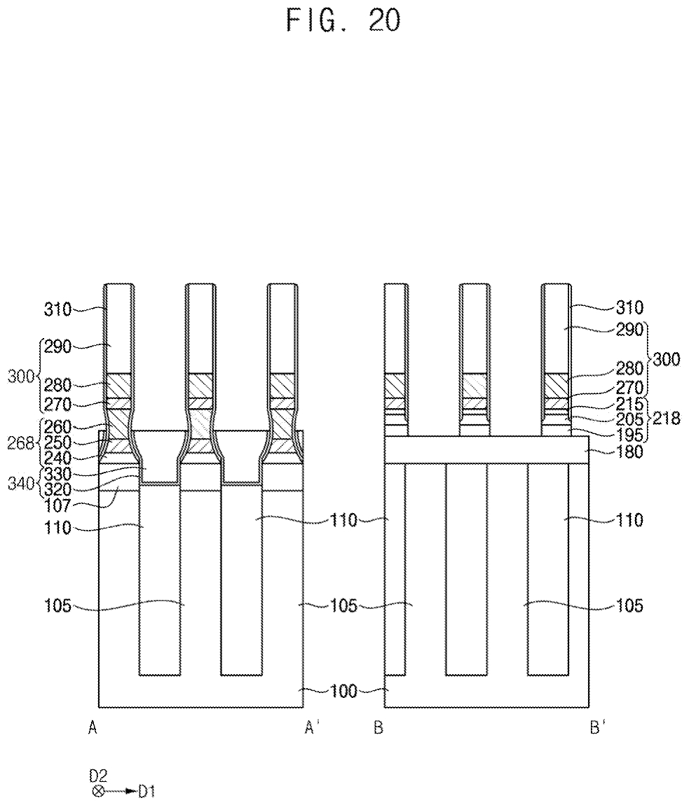

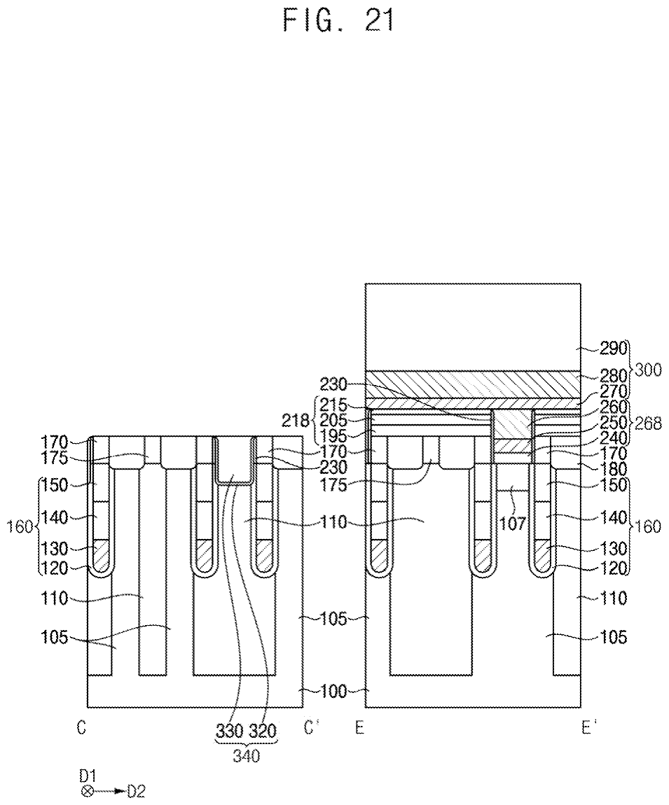

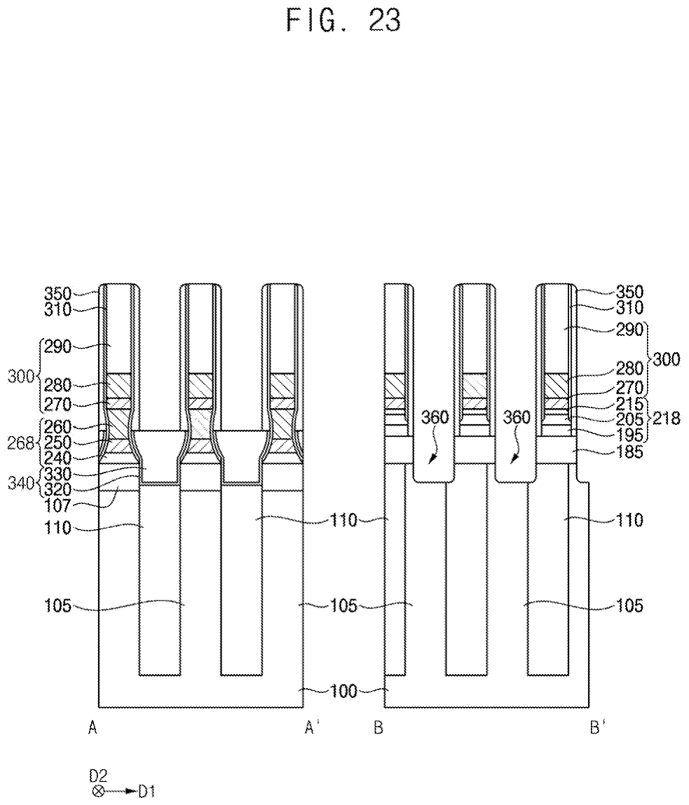

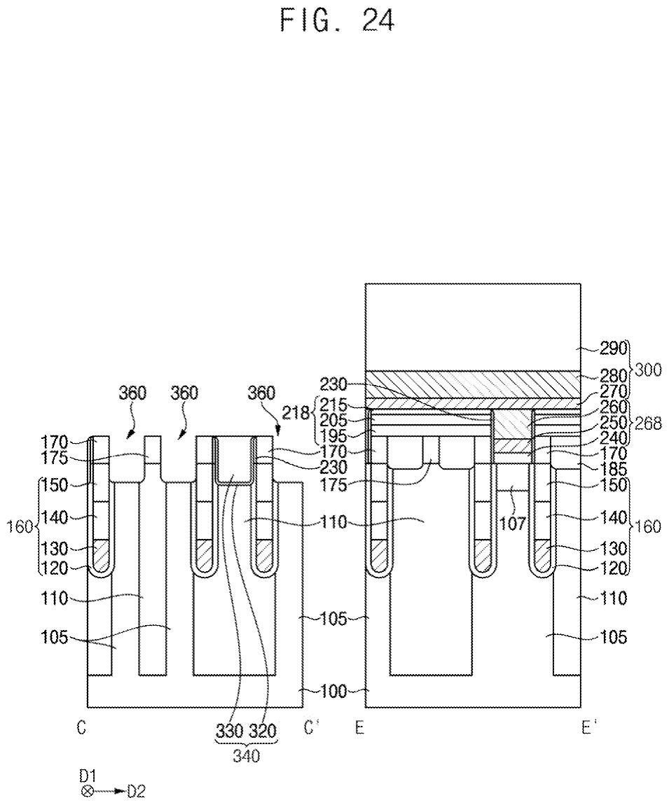

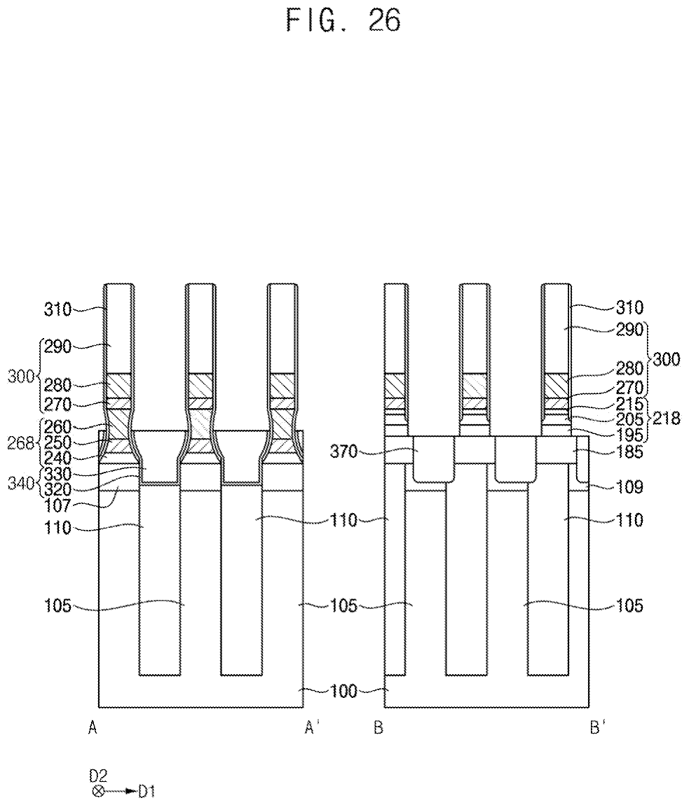

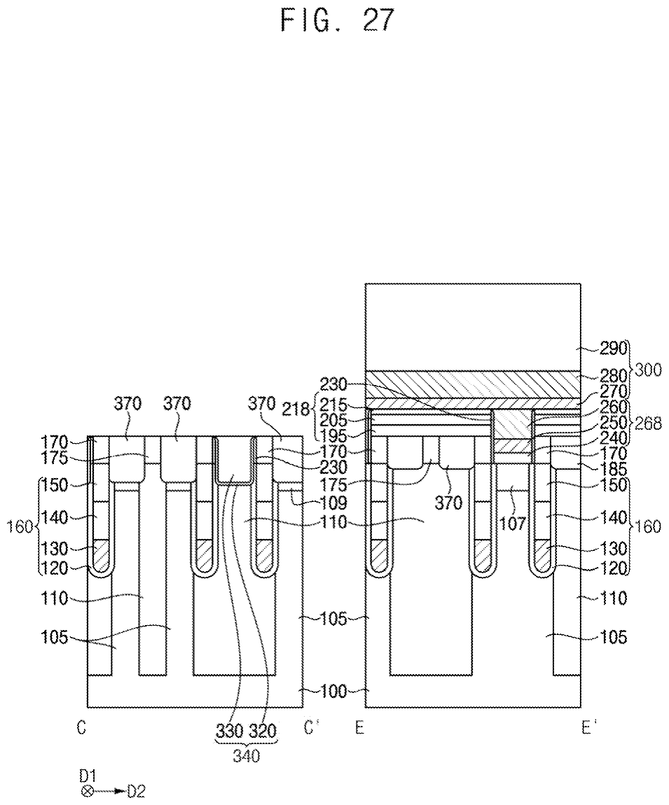

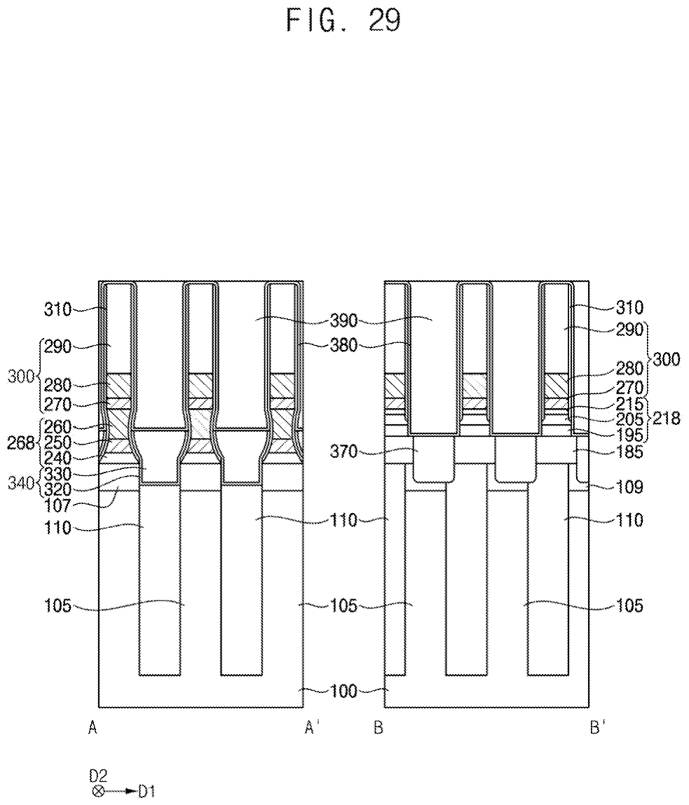

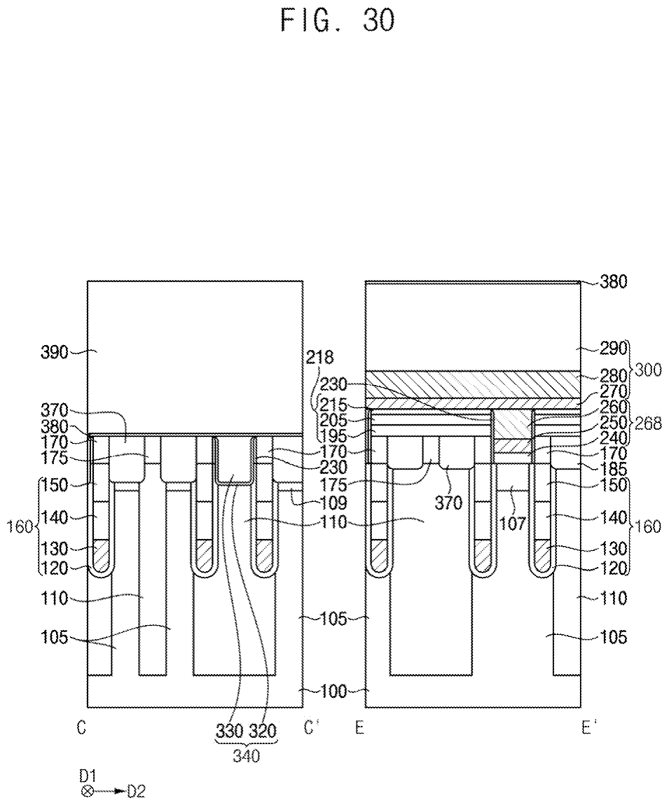

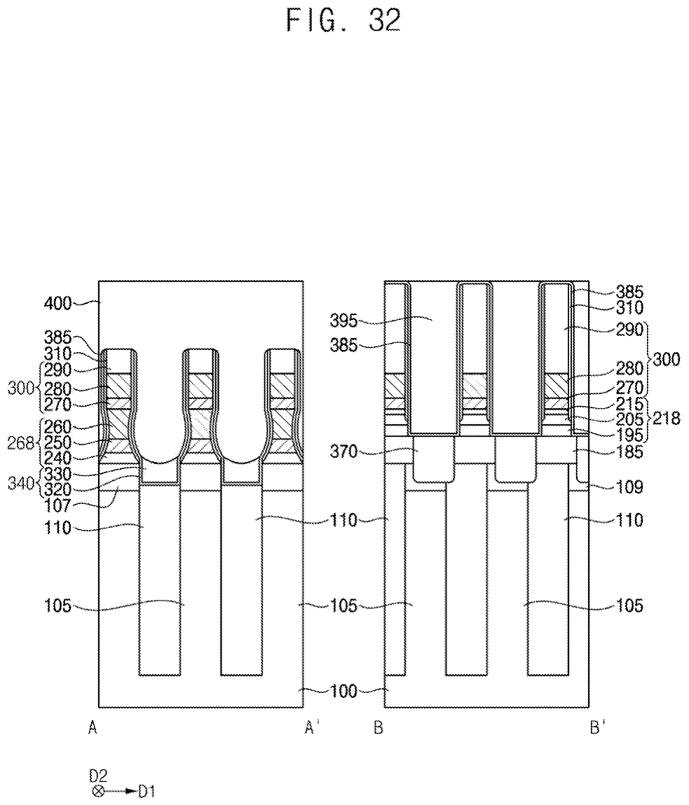

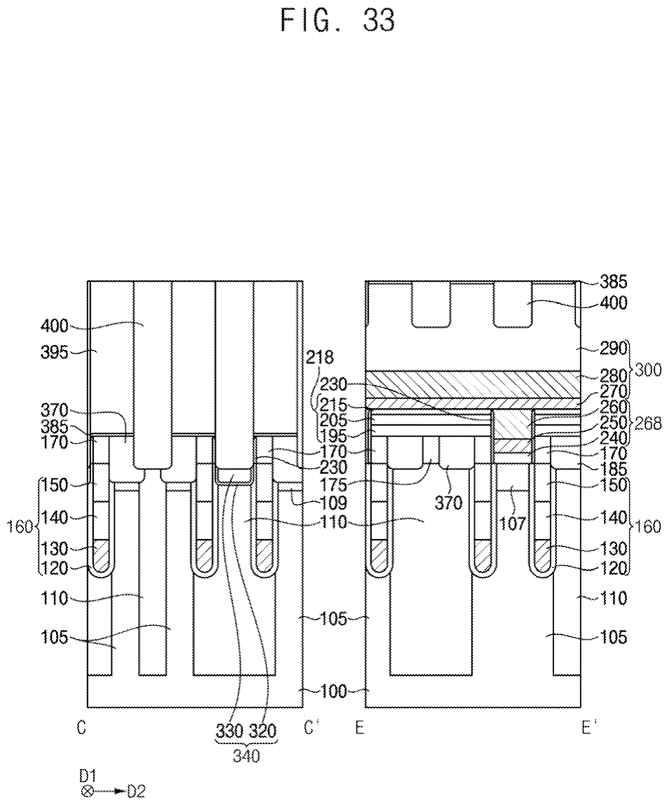

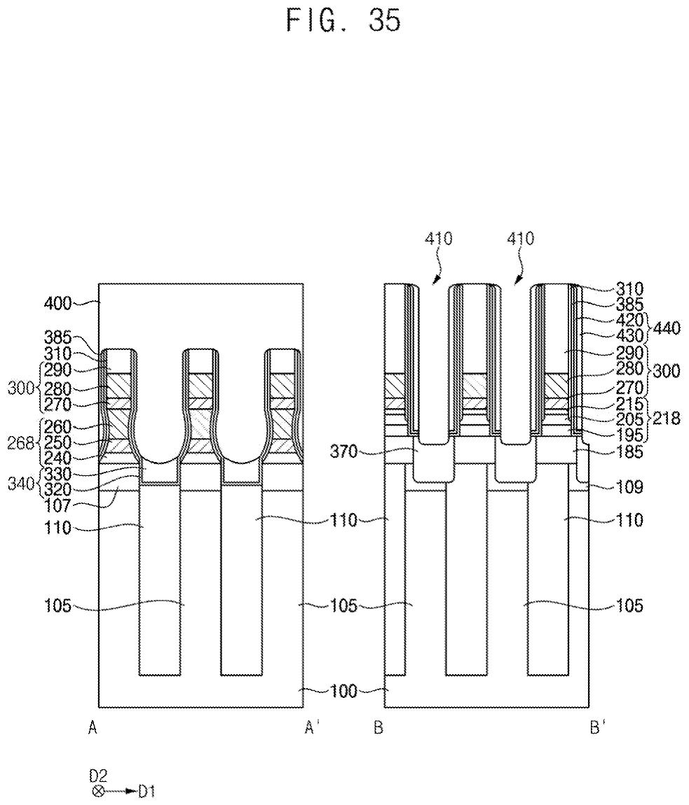

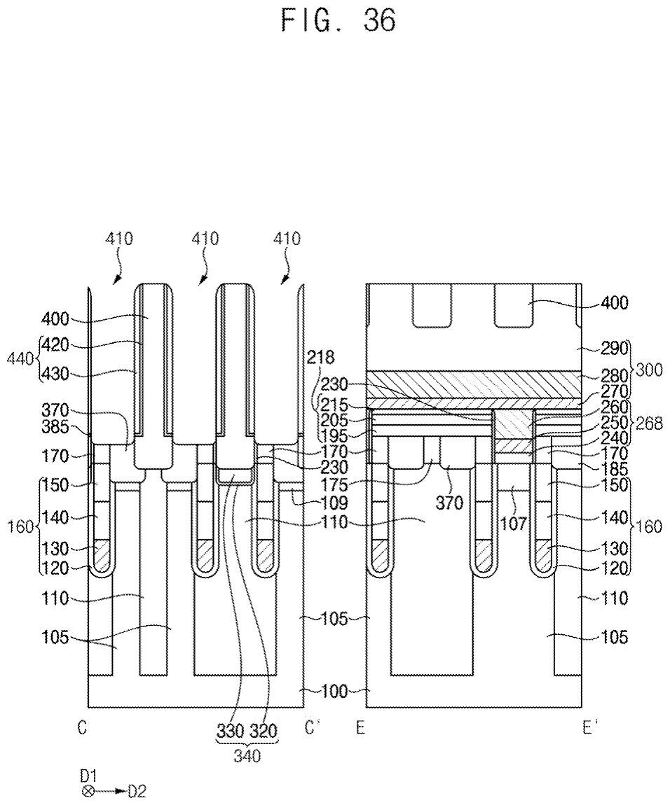

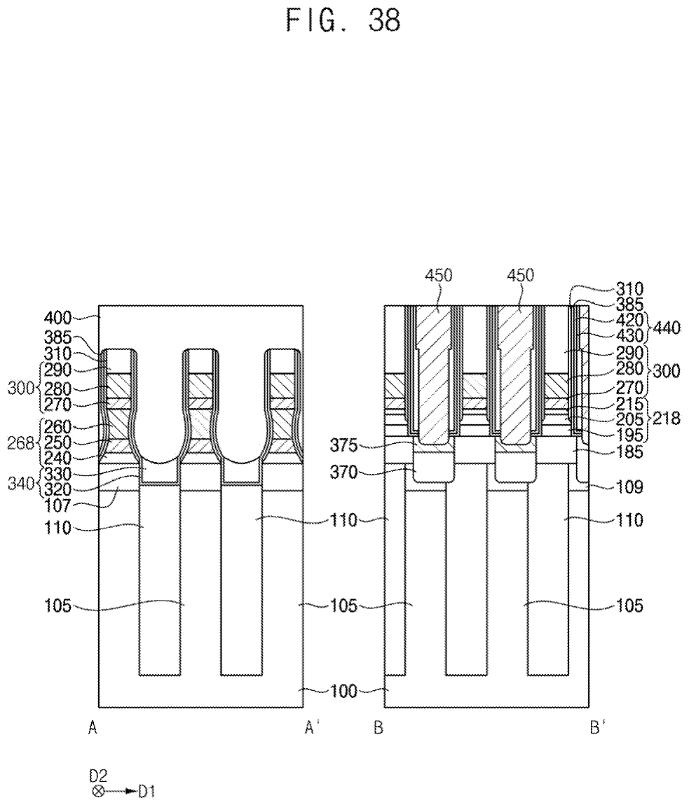

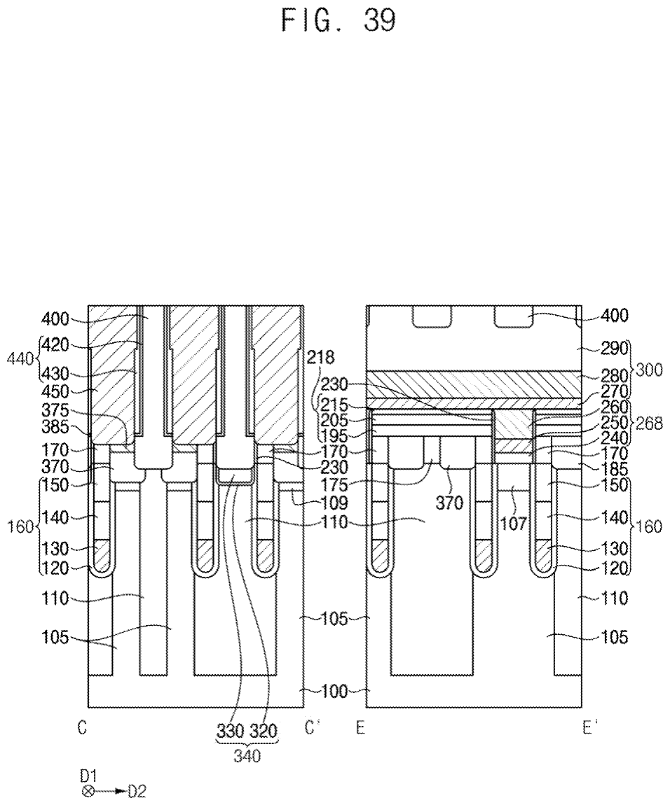

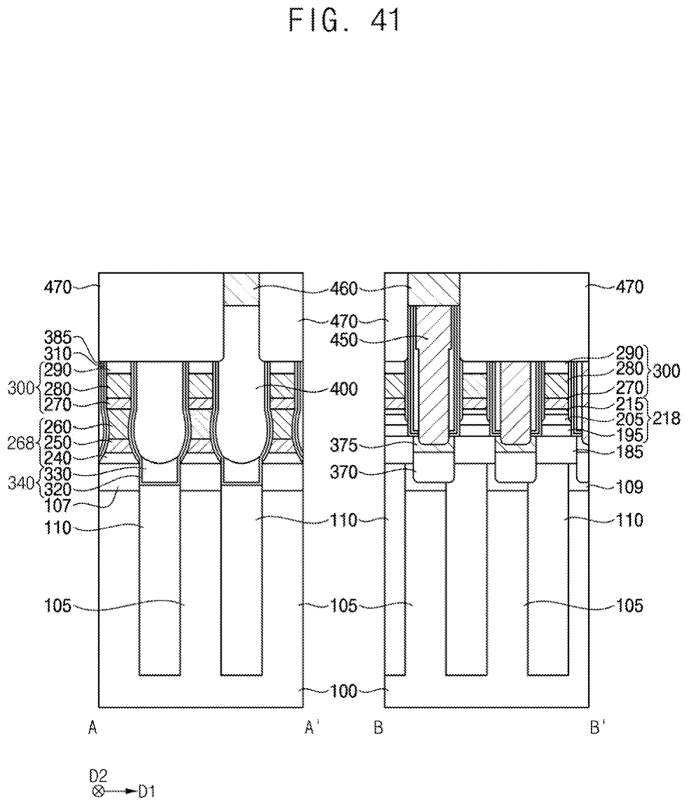

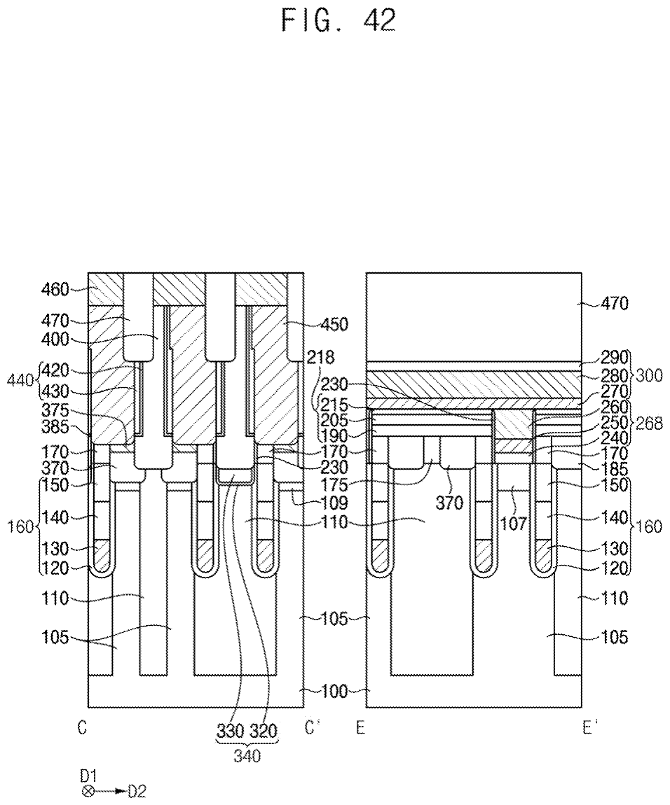

FIGS. 4 to 42 are plan views and cross-sectional views of stages in a method of manufacturing a semiconductor device in accordance with example embodiments. Specifically, FIGS. 4, 7, 10, 13, 16, 19, 22, 28, 31, 34, 37 and 40 are the plan views, each of FIGS. 5, 8, 11, 14, 17, 20, 23, 26, 29, 32, 35, 38 and 41 includes cross-sectional views taken along lines A-A′ and B-B′, respectively, of a corresponding plan view, and each of FIGS. 6, 9, 12, 15, 18, 21, 24, 27, 30, 33, 36, 39 and 42 includes cross-sectional views taken along lines C-C′ and E-E′, respectively, of a corresponding plan view.

Referring to FIGS. 4 to 6, an upper portion of a substrate 100 may be removed to form a recess structure so that an active pattern 105 may be defined, and an isolation pattern 110 may be formed to fill the recess structure.

In an example embodiment, the recess structure may include a first recess extending in the third direction D3 and a second recess extending in the first direction D1 to be connected to the first recess.

In an implementation, the active pattern 105 may extend in the third direction D3 to a certain length on the substrate 100, and a plurality of active patterns 105 may be spaced apart from each other in the first direction D1 to form an active pattern row. In an implementation, a plurality of active pattern rows may be spaced apart from each other in the second direction D2 on the substrate 100 to form an active pattern array.

Upper portions of the active pattern 105 and the isolation pattern 110 may be removed to form a third recess, and a gate insulation layer may be formed on an inner wall of the third recess. A first conductive layer may be formed on the gate insulation layer, an upper portion of the first conductive layer may be removed to form a first conductive pattern 130, a second conductive layer may be formed on the first conductive pattern 130 and the gate insulation layer, and an upper portion of the second conductive layer may be removed to form a second conductive pattern 140. A first mask layer may be formed on the second conductive pattern 140 and the gate insulation layer, and the first mask layer and the gate insulation layer may be planarized until an upper surface of the active pattern 105 and an upper surface of the isolation pattern 110 are exposed to form a first mask 150 and a gate insulation pattern 120, respectively.

The gate insulation pattern 120, the first and second conductive patterns 130 and 140, and the first mask 150 in the third recess may collectively form a gate structure 160.

In an implementation, the gate structure 160 may extend in the first direction D1, and a plurality of the gate structures 160 may be spaced apart from each other in the second direction D2. In an implementation, two gate structures 160 spaced apart from each other in the second direction D2 may be formed at an upper portion of a single active pattern 105. Hereinafter, a portion of the active pattern 105 between the two gate structures 160 may be referred to as a central portion thereof, and a portion of the active pattern 105 at an opposite side of the central portion of the active pattern 105 with respect to a corresponding one of the two gate structures 160 may be referred to as an end portion thereof.

In an implementation, a dummy gate structure extending in the first direction D1 through an upper portion of the isolation pattern 110 between the active pattern rows and the upper portion of each active pattern 105 adjacent to the upper portion of the isolation pattern 110 between the active pattern rows may be further formed.

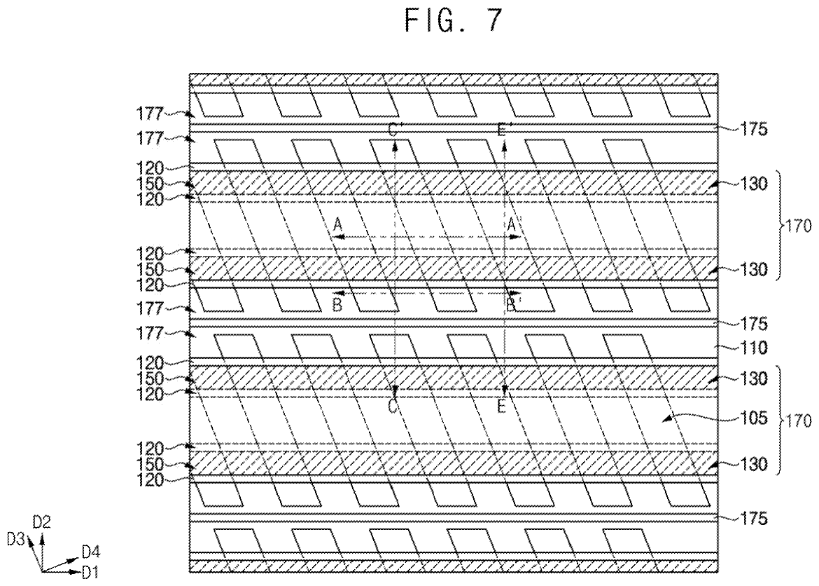

Referring to FIGS. 7 to 9, first and second mold layers 170 and 175 may be formed on the active pattern 105, the isolation pattern 110 and the gate structure 160, and a first opening 177 may be formed between the first and second mold layer 170 and 175.

In an implementation, each of the first and second mold layers 170 and 175 may extend in the first direction D1, and the first opening 177 may also extend in the first direction D1. The first mold layer 170 may cover upper surfaces of the two gate structures 160 extending through the upper portion of the active pattern 105, and the second mold layer 175 may cover an upper surface of a portion of the isolation pattern 110 between active pattern rows neighboring in the second direction D2.

In an implementation, the first mold layer 170 may not cover a portion of the gate insulation pattern 120 of each of the gate structures 160 that is adjacent to the end portion of the active pattern 105, and the second mold layer 175 may be spaced apart from the end portion of the active pattern 105 in the second direction D2.

An etching process using the first and second mold layers 170 and 175 as an etch mask may be performed to partially remove the upper portion of active pattern 105, the upper portion the isolation pattern 110 and an upper portion of gate insulation pattern 120 exposed by the first opening 177, and the first opening 177 may be enlarged downwardly. During the etching process, an upper portion of each end portion of the active pattern 105 may be removed.

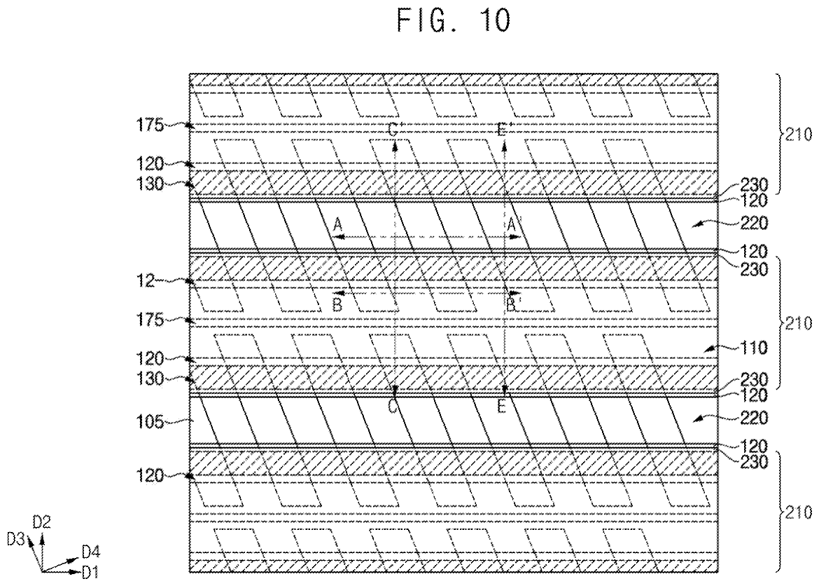

Referring to FIGS. 10 to 12, a third mold layer 180 may be formed on the active pattern 105, the isolation pattern 110, the gate insulation pattern 120 and the first and second mold layers 170 and 175 to fill the first opening 177, a planarization process may be performed on the third mold layer 180.

In an implementation, the planarization process may include a chemical mechanical polishing (CMP) process or an etch-back process. As the planarization process is performed, the third mold layer 180 may be formed in the first opening 177, and may extend in the first direction D1.

First to third buffer layers 190, 200, and 210 may be sequentially stacked on the first to third mold layers 170, 175, and 170 in a vertical direction substantially perpendicular to the upper surface of the substrate 100, and a second opening 220 may be formed through the first to third buffer layers 190, 200, and 210 and the first mold layer 170 under the first to third buffer layers 190, 200, and 210 to expose the upper surfaces of the active pattern 105 and the isolation pattern 110.

The first buffer layer 190 may include an oxide, e.g., silicon oxide, the second buffer layer 200 may include, e.g., a high-k material, and the third buffer layer 210 may include an insulating nitride, e.g., silicon nitride.

In an implementation, the second opening 220 may extend in the first direction D1 to expose the central portion of each of the active patterns 105 in the active pattern row, a portion of the isolation pattern 110 adjacent to the central portion of each of the active patterns 105 in the first direction D1, and a portion of the gate insulation pattern 120 neighboring the central portion of each of the active patterns 105 and the gate insulation pattern 120 in the second direction D2.

A first spacer layer may be formed on the first mold layer 170, the active pattern 105, the isolation pattern 110, and the gate insulation pattern 120 exposed by the second opening 220 and the first to third buffer layers 190, 200, and 210, and an anisotropic etching process may be performed on the first spacer layer to form a first spacer 230 on each of sidewalls of the second opening 220 in the second direction D2. The first spacer 230 may include, e.g., silicon nitride, silicon oxycarbide (SiOC), silicon oxycarbonitride (SiOCN), or the like.

A cleaning process may be additionally performed, and a doping process of implanting impurities, e.g., a gas phase doping (GPD) process may be performed on an upper portion of the central portion of the active pattern 105 exposed by the second opening 220 to form a first impurity region 107.

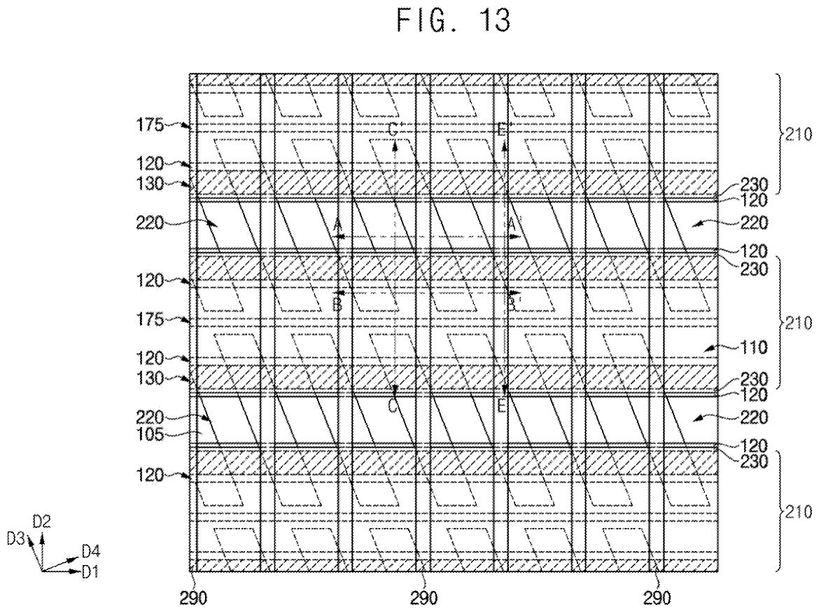

Referring to FIGS. 13 to 15, a pad layer, a first ohmic contact layer, and a second metal layer may be sequentially formed in the second opening 220.

The pad layer may include, e.g., polysilicon doped with impurities. The first ohmic contact layer may be formed by forming a first metal layer on the pad layer and performing a heat treatment process on the first metal layer so that the first metal layer and the pad layer may be reacted with each other. Thus, the first ohmic contact layer may include a metal silicide, e.g., cobalt silicide, nickel silicide, titanium silicide, or the like.

In an implementation, the second metal layer may be independently formed on the first ohmic contact layer. In an implementation, a lower portion of the first metal layer may be reacted with the first pad layer to form the first ohmic contact layer, and a portion of the first metal layer that is not reacted with the first metal layer may remain as the second metal layer.

A planarization process may be further performed on an upper portion of the second metal layer, and thus an upper surface of the second metal layer may be substantially coplanar with an upper surface of the third buffer layer 210.

A barrier layer, a third metal layer and a second mask layer may be sequentially stacked on the third buffer layer 210, the second metal layer and the first spacer 230 in the vertical direction, the second mask layer may be patterned to form a second mask 290, and an etching process using the second mask 290 as an etching mask may be performed to pattern the third metal layer, the barrier layer and the third buffer layer 210, and furthermore, the second metal layer, the first ohmic contact layer and the pad layer may also be patterned.

In an implementation, the pad layer, the first ohmic contact layer and the second metal layer may form a pad 240, a first ohmic contact pattern 250, and a second metal pattern 260, respectively, and the pad 240, the first ohmic contact pattern 250, and the second metal pattern 260 collectively form a first contact structure 268. In an implementation s, a plurality of first contact structures 268 may be spaced apart from each other in the second opening 220 in the first direction D1.

The barrier layer and the third metal layer may form a barrier pattern 270 and a third metal pattern 280, respectively. The barrier pattern 270, the third metal pattern 280 and the second mask 290 sequentially stacked in the vertical direction may collectively form a bit line structure 300. In an implementation, the bit line structure 300 may extend in the second direction D2, and a plurality of bit line structures 300 may be spaced apart from each other in the first direction D1.

The bit line structure 300 may overlap the central portions of the active patterns 105 disposed in the second direction D2, and the first contact structure 268 may be between the bit line structure 300 and each of the active patterns 105 to electrically connect the bit line structure 300 and each of the active patterns 105 to each other.

The third buffer layer 210 may be patterned to remain as a third buffer 215 under the bit line structure 300, and the second buffer layer 200 may also be partially removed.

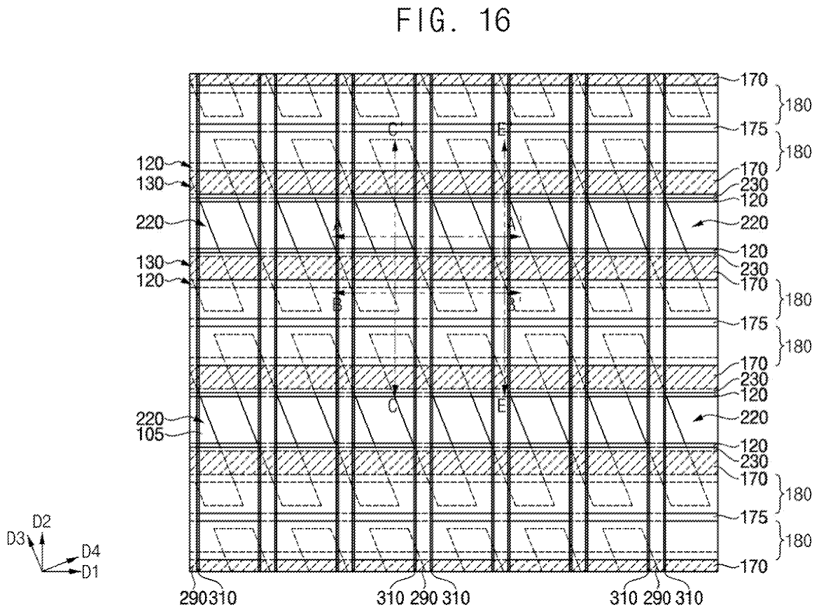

Referring to FIGS. 16 to 18, a second spacer layer may be formed on the bit line structure 300, the first contact structure 268, the third buffer 215, the second buffer layer 200, and the first spacer 230, and on the active pattern 105, the isolation pattern 110, and the gate insulation pattern 120 exposed by the second opening 220, and an anisotropic etching process may be performed on the second spacer layer to form a second spacer 310 on sidewalls of the bit line structure 300, the first contact structure 268, and the third buffer 215.

In an implementation, a wet etching process may be performed on the second buffer layer 200, and thus the second buffer layer 200 may remain as a second buffer 205 under the third buffer 215 and the second spacer 310.

An etching process, e.g., a dry etching process or a wet etching process may be performed on the first buffer layer 190 to form a first buffer 195, and the first buffer 195 may remain under the second buffer 205. The first to third buffers 195, 205, and 215 sequentially stacked in the vertical direction may collectively form a buffer structure 218. In an implementation, a plurality of buffer structures 218 may be spaced apart from each other by the first contact structure 268 and the first spacer 230 in the second direction D2 under the bit line structure 300.

As the etching process is performed, upper surfaces of portions of the first to third mold layers 170, 175, and 180, which may not be overlapped with the bit line structure 300 in the vertical direction, may be exposed, and the upper portions of the active pattern 105, the isolation pattern 110, and the gate insulation pattern 120 exposed by the second opening 220 may also be partially removed.

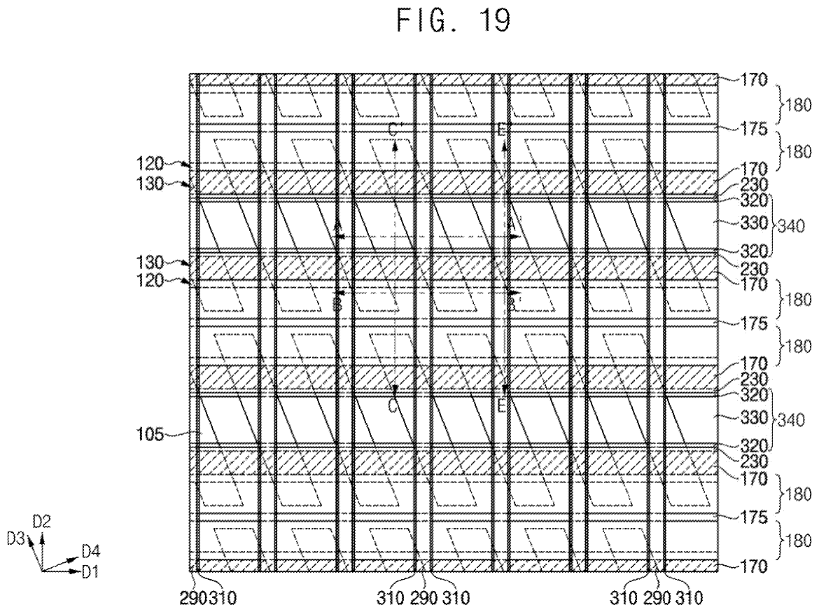

Referring to FIGS. 19 to 21, a filling structure 340 may be formed in the second opening 220.

In an implementation, the filling structure 340 may be formed by forming a first filling layer on the second spacer 310, the first and second buffers 195 and 205 and the first spacer 230, and on the active pattern 105, the isolation pattern 110 and the gate insulation pattern 120 exposed by the second opening 220, forming a second filling layer on the first filling layer to fill the second opening 220, and performing an etching process on the first and second filling layers.

Thus, a first filling pattern 320 may be formed on upper surfaces and upper sidewalls of the active pattern 105, the isolation pattern 110, and the gate insulation pattern 120 exposed by the second opening 220, a sidewall of the first spacer 230, and a lower sidewall of the second spacer 310, a second filling pattern 330 may be formed to fill a remaining portion of the second opening 220, and the first and second filling patterns 320 and 330 may collectively form the filling structure 340.

In an implementation, a plurality of filling structures 340 may be spaced apart from each other in the first direction D1 by the first contact structure 268. In an implementation, an upper surface of the filling structure 340 may be substantially coplanar with the upper surfaces of the first to third mold layers 170, 175, and 180 and an upper surface of the first spacer 230.

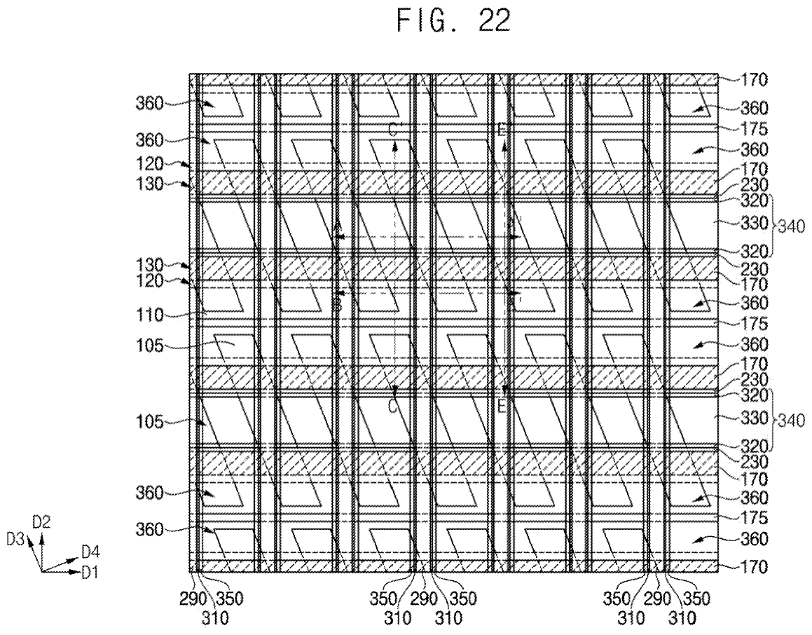

Referring to FIGS. 22 to 24, a first sacrificial spacer layer may be formed on the bit line structure 300, the second spacer 310, the buffer structure 218, the filling structure 340 and the first to third mold layers 170, 175 and 180, and an anisotropic etching process may be performed on the first sacrificial spacer layer to form a first sacrificial spacer 350 on sidewalls of the second spacer 310 and the buffer structure 218.

The first sacrificial spacer 350 may cover a top surface of the first filling pattern 320 in the filling structure 340. The first sacrificial spacer 350 may include an insulating nitride, e.g., silicon nitride.

The third mold layer 180 may be etched by performing an etching process using the bit line structure 300, the second spacer 310 and the first sacrificial spacer 350 as an etching mask, and thus a third opening 360 may be formed to expose the upper surfaces of the active pattern 105, the isolation pattern 110 and the gate insulation pattern 120 under the mold layer 180.

During the etching process, the third mold layer 180 extending in the first direction D1 may be transformed into a plurality of third mold layers 185 spaced apart from each other in the first direction D1, and each of the third mold layers 185 may be formed under the buffer structure 218, the second spacer 310 and the first sacrificial spacer 350. During the etching process, the upper portions of the active pattern 105, the isolation pattern 110 and the gate insulation pattern 120 exposed by the third opening 360 may also be partially etched.

In an implementation, the third opening 360 may be formed at each of opposite sides of the second mold layer 175 in the second direction D2 between bit line structures 300 adjacent to each other in the first direction D1.

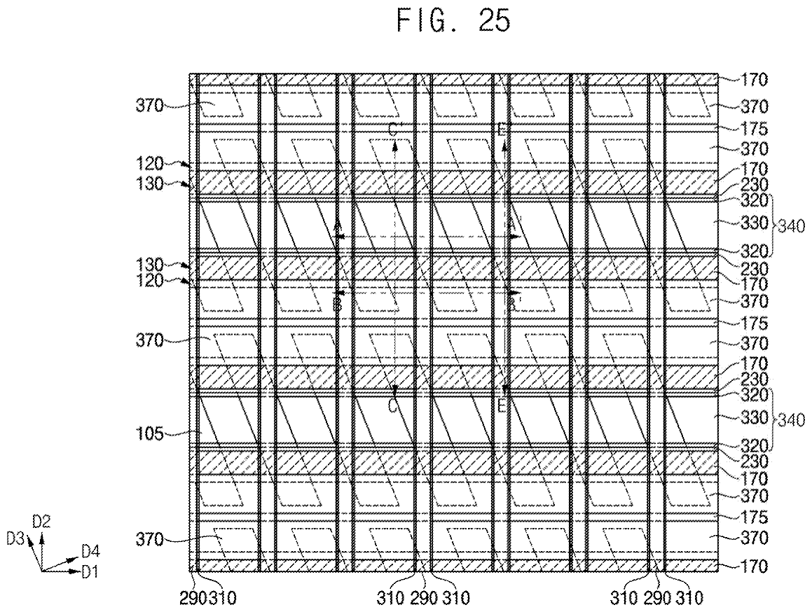

Referring to FIGS. 25 to 27, a doping process of implanting impurities, e.g., a gas phase doping (GPD) process may be performed on an upper portion of the end portion of the active pattern 105 exposed by the third opening 360 to form a second impurity region 109.

A second contact structure 370 may be formed in the third opening 360.

In an implementation, the second contact structure 370 may be formed by forming a second contact layer through a deposition process on the bit line structure 300, the second spacer 310, the first sacrificial spacer 350, the filling structure 340 and the buffer structure 218, and on the active pattern 105, the isolation pattern 110, and the gate insulation pattern 120 exposed by the third opening 360, and performing, e.g., an etch-back process to remove an upper portion of the second contact layer. Thus, an upper surface of the second contact structure 370 may be substantially coplanar with upper surfaces of the first and second mold layers 170 and 175 and the third mold layer 185. The second contact structure 370 may include, e.g., polysilicon doped with impurities.

In an implementation, the second contact structure 370 may be formed by a selective epitaxial growth (SEG) process.

After forming the second contact structure 370, the first sacrificial spacer 350 may be removed by, e.g., a wet etching process. In an implementation, the first sacrificial spacer 350 may be removed before forming the second contact structure 370.

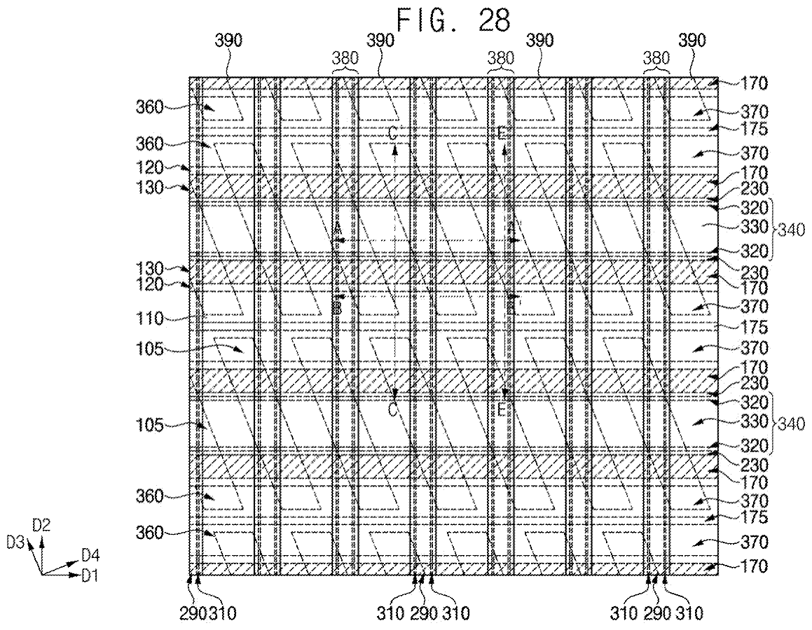

Referring to FIGS. 28 to 30, a third spacer layer 380 may be formed on the bit line structure 300, the second spacer 310, the buffer structure 218, the filling structure 340, the first and second mold layers 170 and 175, and the second contact structure 370, and a first sacrificial insulating interlayer 390 may be formed on the third spacer layer 380 to fill a space between the bit line structures 300.

In an implementation, the first sacrificial insulating interlayer 390 may extend in the second direction D2, and a plurality of first sacrificial insulating interlayers 390 may be spaced apart from each other in the first direction D1. The first sacrificial insulating interlayer 390 may include an oxide, e.g., silicon oxide.

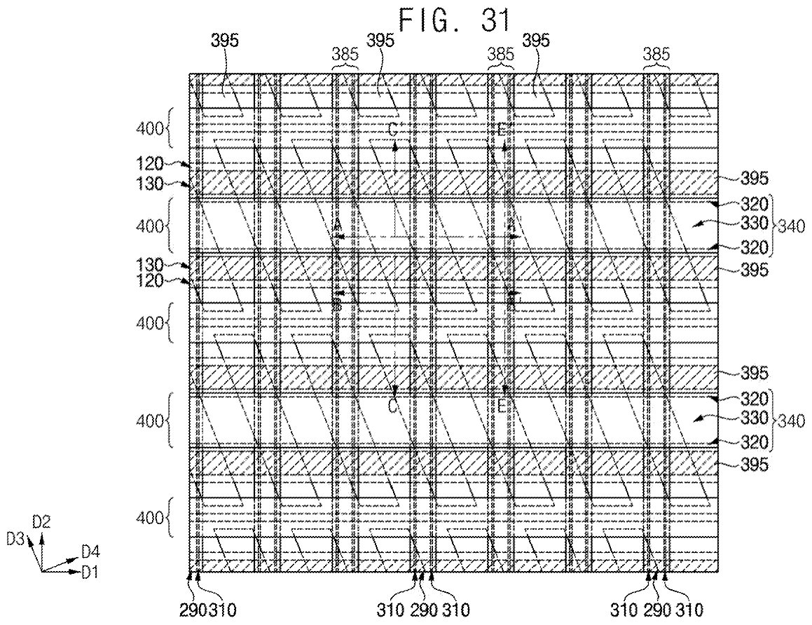

Referring to FIGS. 31 to 33, a first etching mask having a fourth opening extending in the first direction D1 may be formed on the third spacer layer 380 and the first sacrificial insulating interlayer 390, an etching process may be performed using the first etching mask to partially etch the first sacrificial insulating interlayer 390, the third spacer layer 380 under the first sacrificial insulating interlayer 390, an upper portion of the filling structure 340 and the second mold layer 175, and thus the second mold layer 175 extending in the first direction D1 may remain only under the bit line structure 300 so as to be divided into a plurality of second mold layers 175 spaced apart from each other in the first direction D1.

During the etching process, an upper lateral portion of the second contact structure 370 adjacent to the second mold layer 175 may also be partially removed. Thus, a fifth opening may be formed through the first sacrificial insulating interlayer 390 and the third spacer layer 380 to expose the upper surface of the isolation pattern 110 and an upper sidewall of the second contact structure 370 adjacent to the first sacrificial insulating interlayer 390, the upper surface of the filling structure 340 and a sidewall of the first spacer 230.

The first sacrificial insulating interlayer 390 extending in the second direction D2 may be divided into first sacrificial insulating interlayer patterns 395 spaced apart from each other in the second direction D2, and a portion of the third spacer layer 380 where the fifth opening is formed may be removed, and other portions of the third spacer layer 380 may remain as a third spacer 385.

During the etching process, an upper portion of the second mask 290 of a portion of the bit line structure 300 exposed by the fourth opening may also be etched to be removed, and thus a portion of the third spacer layer 380 and a portion of the second spacer 310 on an upper surface and an upper sidewall of the portion of the bit line structure 300 may also be removed.

In an implementation, the fifth opening may extend in the first direction D1 between the first sacrificial insulating interlayer patterns 395, and a bottom of a portion of the fifth opening on the bit line structure 300 may be higher than bottoms of other portions of the fifth opening.

After removing the first etching mask, a first fence pattern 400 may be formed to fill the fifth opening. The first fence pattern 400 may be formed by forming a first fence layer to fill the fifth opening, and removing an upper portion of the first fence layer until an upper surface of the first sacrificial insulating interlayer pattern 395 is exposed through, e.g., an etch back process. In an implementation, the first fence pattern 400 may extend in the first direction D1 between the first sacrificial insulating interlayer patterns 395, and a bottom surface of a portion of the first fence pattern 400 on the bit line structure 300 may be higher than bottom surfaces of other portions of the first fence pattern 400.

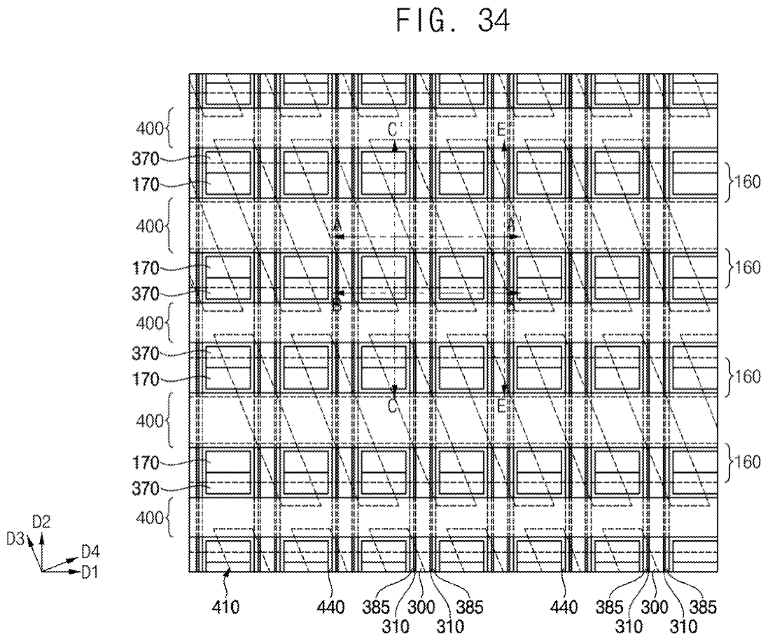

Referring to FIGS. 34 to 36, the first sacrificial insulating interlayer pattern 395 may be removed to expose a surface of the third spacer 385, and thus a sixth opening 410 surrounded by the bit line structures 300 and the first fence patterns 400 may be formed. In an implementation, a plurality of sixth openings 410 may be spaced apart from each other in the first and second directions D1 and D2.

In an implementation, the first sacrificial insulating interlayer pattern 395 may be removed by a wet etching process, and, e.g., an ashing process or a stripping process may be additionally performed. Thus, opposite lateral portions of the first fence pattern 400 in the second direction D2 may be partially removed, so that a width of the first fence pattern 400 in the second direction D2 may be reduced.

A fourth spacer layer may be formed on surfaces of the third spacer 385 and the first fence pattern 400, a fifth spacer layer may be formed on the fourth spacer layer, and an anisotropic etching process may be performed on the fourth and fifth spacer layers.

Thus, a first spacer structure 440 including fourth and fifth spacers 420 and 430 may be formed on sidewalls of the third spacer 385 and the first fence pattern 400. In an implementation, the first spacer structure 440 may have a rectangular closed loop or ring shape at an edge of a space surrounded by the bit line structures 300 and the first fence patterns 400.

An etching process may be performed using the bit line structure 300, the first fence pattern 400 and the first spacer structure 440 as an etching mask to remove a portion of the third spacer 385, which may not be covered by the bit line structure 300, the first fence pattern 400 and the first spacer structure 440, and upper portions of the second contact structure 370 and the first mold layer 170 thereunder, and thus the sixth opening 410 may be enlarged downwardly.

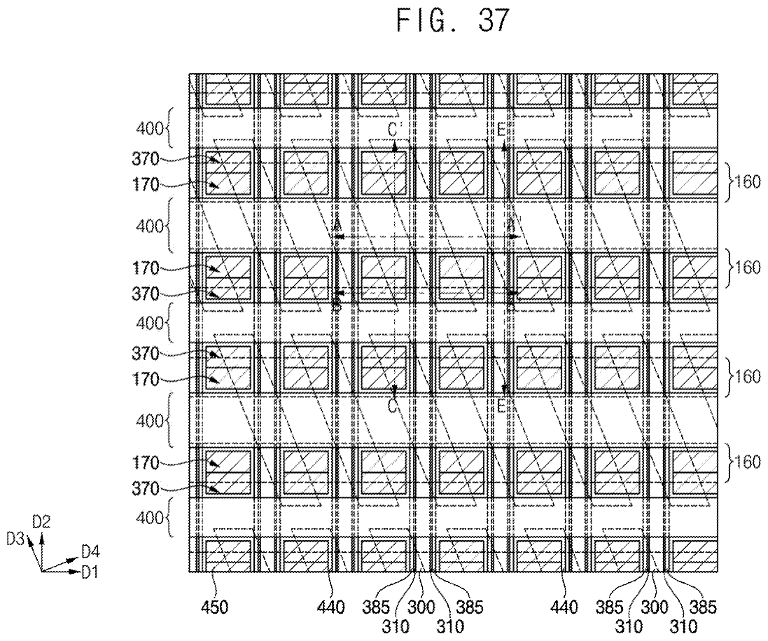

Referring to FIGS. 37 to 39, a third contact pattern may be formed in the sixth opening 410, and an upper portion of the third contact pattern may be removed.

When the upper portion of the third contact pattern is removed, an upper portion of the fifth spacer 430 surrounding the third contact pattern may also be partially removed to reduce a thickness of the fifth spacer 430.

The third contact pattern may include a metal, and an upper portion of the second contact structure 370 exposed by the sixth opening 410 may be converted into a second ohmic contact pattern 375 when the third contact pattern is formed or by a separate heat treatment process after the formation of the third contact pattern.

A fourth contact pattern may be formed on the third contact pattern, and a planarization process may be performed on an upper portion of the fourth contact pattern. Thus, a third contact structure 450 including the third and fourth contact patterns stacked in the vertical direction may be formed in the sixth opening 410.

During the planarization process, upper portions of the bit line structure 300, the first fence pattern 400, the second spacer 310 and the first spacer structure 440 may be partially removed, and upper surfaces the bit line structure 300, the first fence pattern 400, the second spacer 310 and the first spacer structure 440 may be substantially coplanar with an upper surface of the third contact structure 450.

In an implementation, a plurality of third contact structures 450 may be spaced apart from each other in the first and second directions D1 and D2.

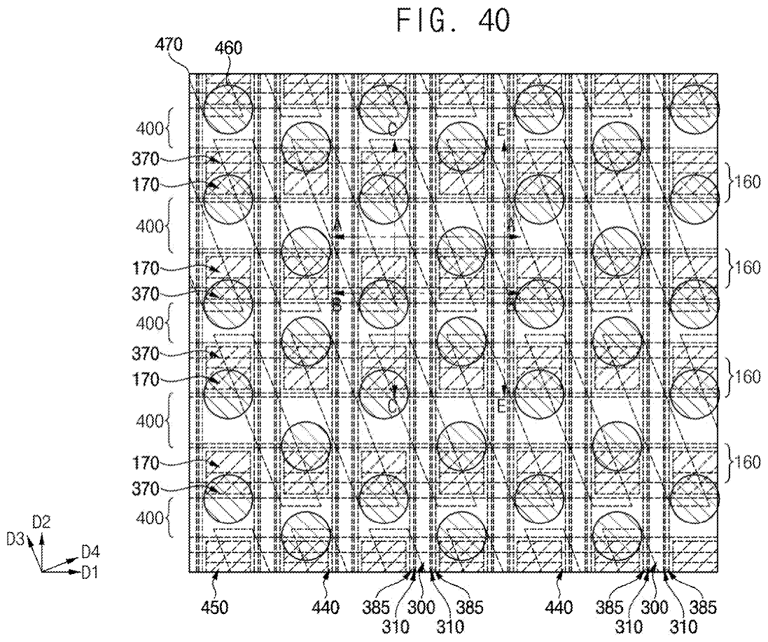

Referring to FIGS. 40 to 42, a landing pad layer may be formed on the bit line structure 300, the second spacer 310, the first fence pattern 400, the first spacer structure 440 and the third contact structure 450, upper portions of the landing pad layer and the bit line structure 300, the second spacer 310, the first spacer structure 440, the first fence pattern 400 and the third contact structure 450 under the landing pad layer may be removed to form a fourth recess, and an insulation pattern 470 may be formed to fill the fourth recess.

In an implementation, the landing pad layer may be divided into a plurality of landing pads 460 spaced apart from each other in the first and second directions D1 and D2, and each of the landing pads 460 may contact the upper surface of the third contact structure 450. In an implementation, the landing pads 460 may be arranged in a honeycomb pattern in a plan view. In an implementation, the landing pads 460 may be arranged in another pattern, e.g., a grid pattern in a plan view.

Referring back to FIGS. 1 to 3, a first electrode 480 may be formed on the landing pad 460, a dielectric layer 490 may be formed on the first electrode 480 and the insulation pattern 470, and a second electrode 500 may be formed on the dielectric layer 490.

The first electrode 480, the dielectric layer 490 and the second electrode 500 may collectively form a capacitor 510.

The semiconductor device may be manufactured by performing the above processes.

In an implementation, the first to third mold layers 170, 175, and 180 may be formed on the active pattern 105 and the isolation pattern 110, the bit line structure 300 may be formed on the first contact structure 268 extending through the first mold layer 170 and contacting the central portion of the active pattern 105, and the filling structure 340 may be formed between the first contact structures 268. The third mold layer 180 between the first and second mold layers 170 and 175 may be patterned by an etching process using the bit line structure 300 as an etch mask to form the third opening 360 exposing each end portion of the active pattern 105, the second contact structure 370 may be formed in the third opening 360, and the second contact structure 370 may be electrically connected to the capacitor 510 through the second ohmic contact pattern 375, the third contact structure 450 and the landing pad 460.

Accordingly, the second contact structure 370 may be self-aligned with the bit line structure 300, and may be surrounded by the first and second mold layers 170 and 175 and the third mold layer 185 to have a rectangular shape in a plan view. Thus, the second contact structure 370 may establish a broad surface contact with the active pattern 105 and the third contact structure 450.

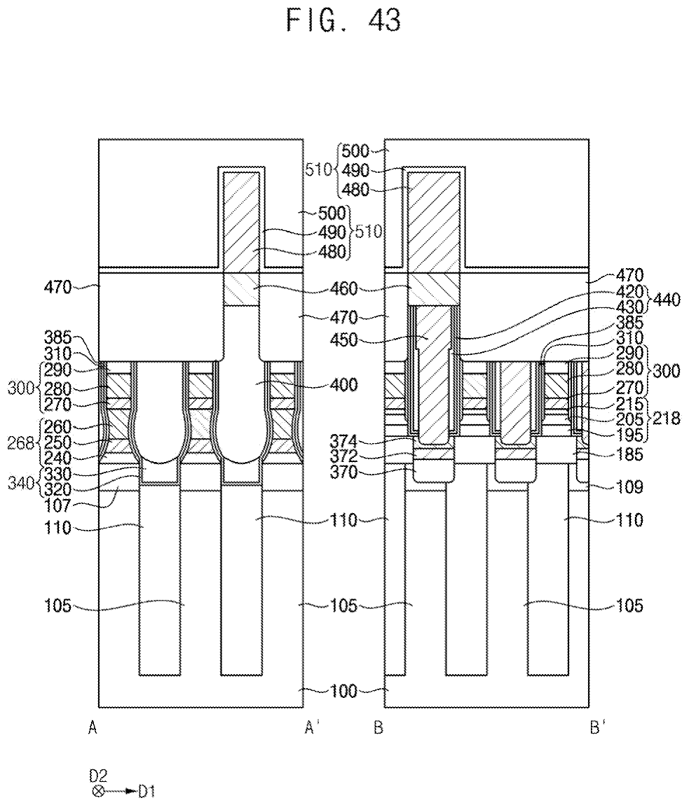

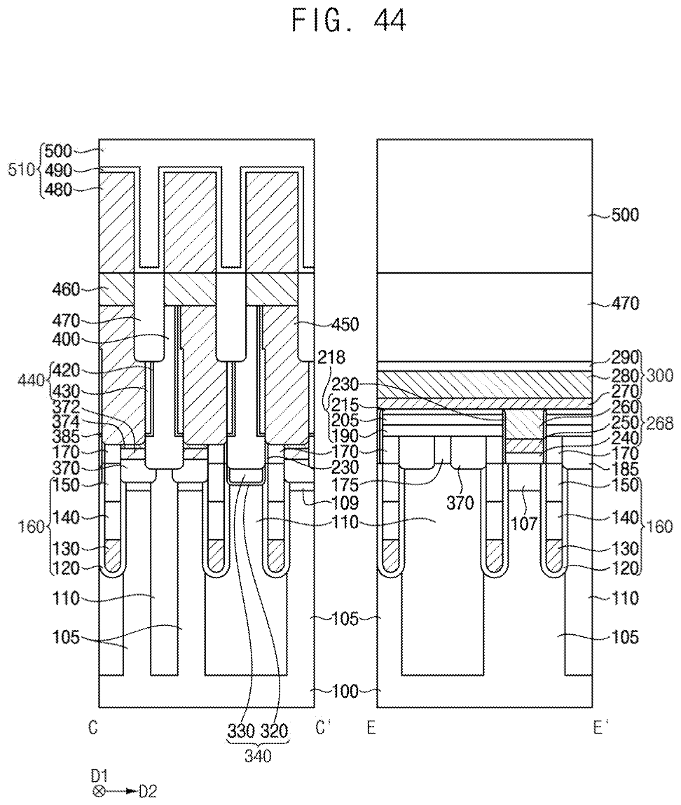

FIGS. 43 and 44 are cross-sectional views illustrating a semiconductor device in accordance with example embodiments, which correspond to FIGS. 2 and 3, respectively. This semiconductor device may be substantially the same as or similar to the semiconductor device of FIGS. 1 to 3, except for some elements, so like reference numerals refer to like elements and repeated explanations may be omitted herein.

Referring to FIGS. 43 and 44, a third ohmic contact pattern 372 and a fourth metal pattern 374 may be stacked on the second contact structure 370, and the fourth metal pattern 374 may contact the third contact structure 450 disposed thereon.

In an implementation, in the semiconductor device described with reference to FIGS. 1 to 3, the second contact structure 370 may include polysilicon doped with impurities, the third contact structure 450 including a metal may be formed on the second contact structure 370, and the second ohmic contact pattern 375 may be formed between the second contact structure 370 and the third contact structure 450. In an implementation, in the semiconductor device described with reference to FIGS. 43 and 44, a metal layer may be deposited on the second contact structure 370 including doped polysilicon, a heat treatment process may be performed on the metal layer so that the metal layer may form the third ohmic contact pattern 372, and the fourth metal pattern 374 including a metal may be further formed on the third ohmic contact pattern 372.

The third ohmic contact pattern 372 may include a metal silicide, e.g., cobalt silicide, nickel silicide, titanium silicide, or the like, and the fourth metal pattern 374 may include a low resistance metal, e.g., tungsten, niobium, copper, aluminum, or the like.

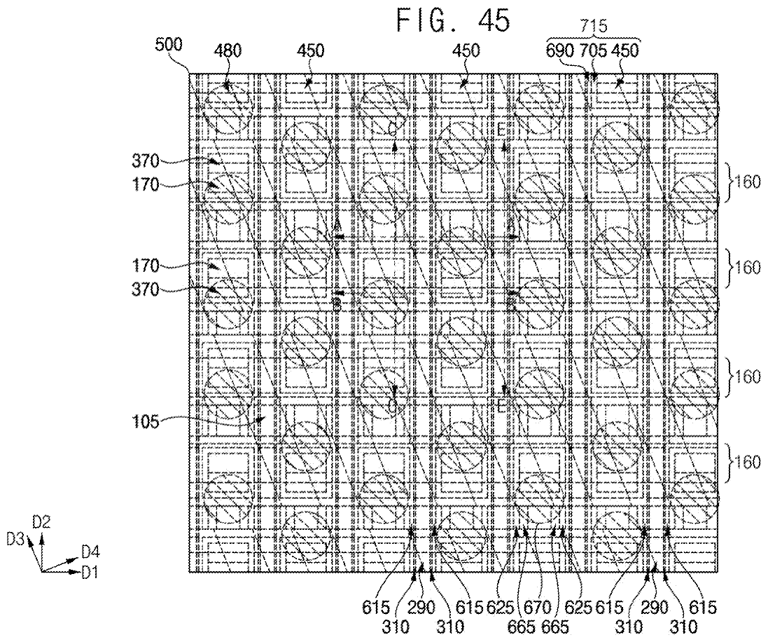

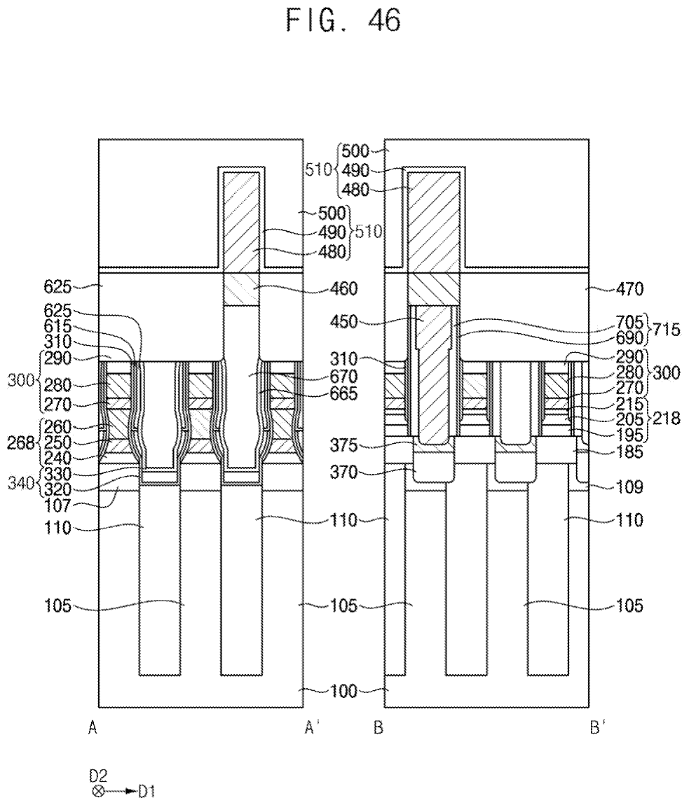

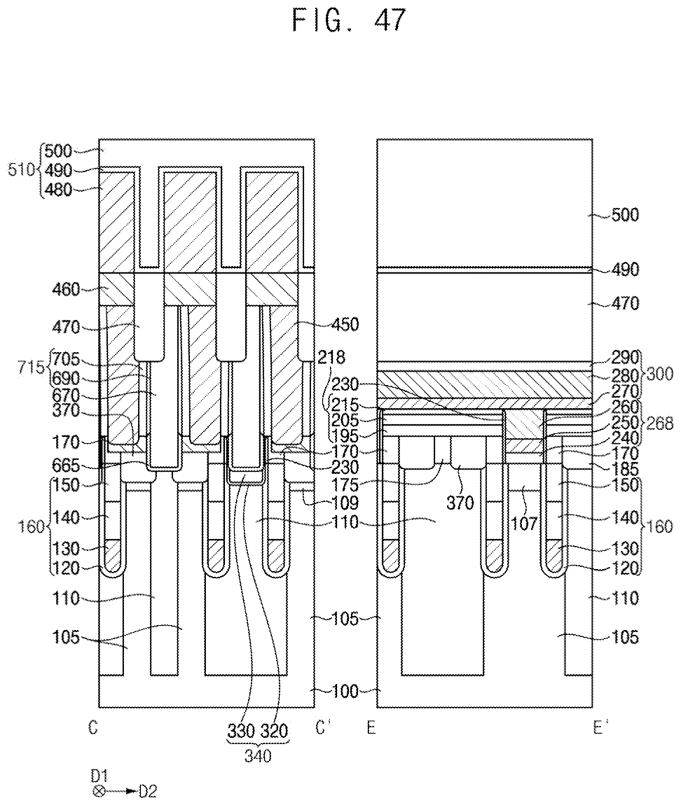

FIGS. 45 to 47 are a plan view and cross-sectional views illustrating a semiconductor device in accordance with example embodiments, which correspond to FIGS. 1 to 3, respectively. This semiconductor device may be substantially the same as or similar to the semiconductor device that of FIGS. 1 to 3, except for some elements, and thus like reference numerals refer to like elements and repeated explanations may be omitted herein.

Referring to FIGS. 45 to 47, the semiconductor device may include a second spacer structure 715 instead of the first spacer structure 440 on an outer sidewall of the second spacer 310 on the sidewall of the bit line structure 300 in the first direction D1, and may include a second fence pattern 670 instead of the first fence pattern 400 extending in the first direction D1. A second spacer structure 715, instead of the first spacer structure 440, may be formed on a sidewall of the second fence pattern 670 in the second direction D2.

In an implementation, the second spacer structure 715 may include seventh and eighth spacers 690 and 705 stacked in the horizontal direction from the sidewall of the second fence pattern 670 in the second direction D2. The seventh spacer 690 may include an oxide, e.g., silicon oxide, and the eighth spacer 705 may include, e.g., silicon oxycarbonitride, silicon oxynitride, silicon nitride, or the like. The second fence pattern 670 may also include a nitride, e.g., silicon oxycarbonitride, silicon oxynitride, silicon nitride, or the like.

A first etch stop pattern 615, instead of the third spacer 385, may be formed on an upper surface of a portion of the bit line structure 300 under the second fence pattern 670 and an outer sidewall of the second spacer on a sidewall of the portion of the bit line structure 300, and a second sacrificial spacer 625 may be formed on an outer sidewall of the first etch stop pattern 615 and an upper surface of the filling structure 340.

The first etch stop pattern 615 may include an oxide, e.g., silicon oxide, and the second sacrificial spacer 625 may include a nitride, e.g., silicon nitride.

A sixth spacer 665 covering a lower sidewall in the second direction D2 and a bottom surface of the second fence pattern 670 may be under the seventh spacer 690, and may contact an upper sidewall of the second contact structure 379 and the upper surface of the isolation pattern 110. The seventh spacer 690 may include nitride, e.g., silicon nitride.

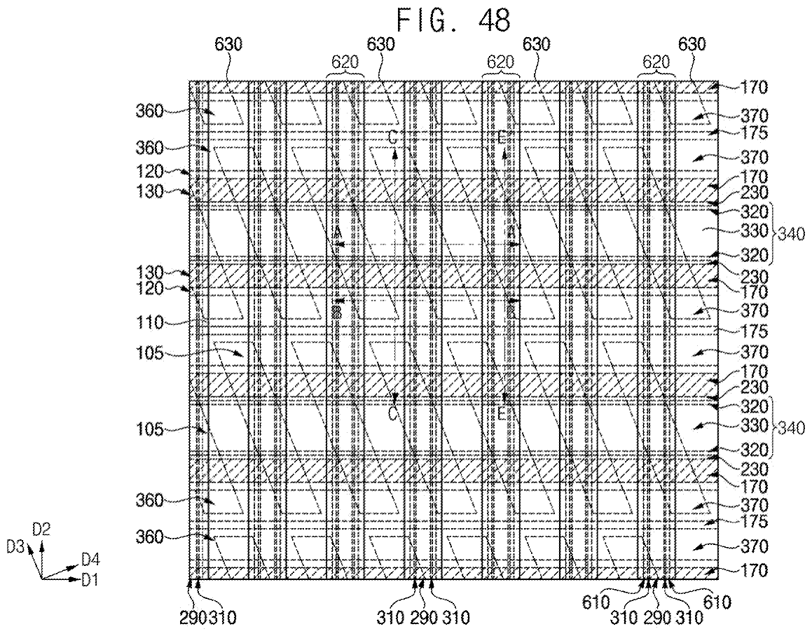

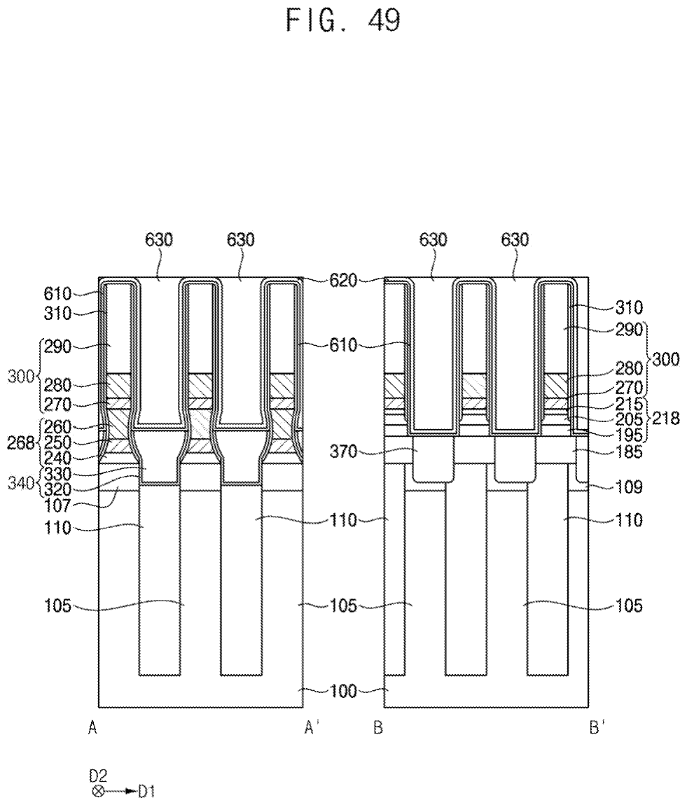

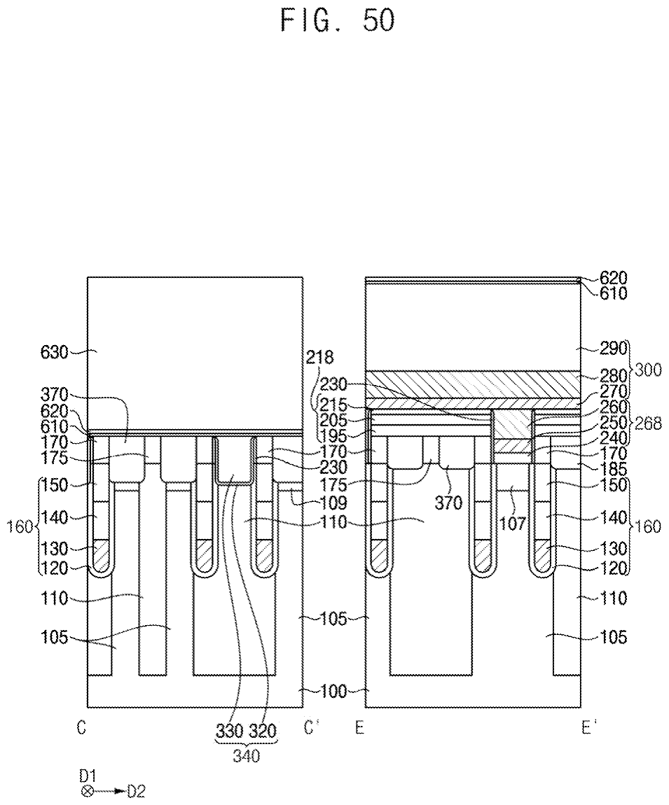

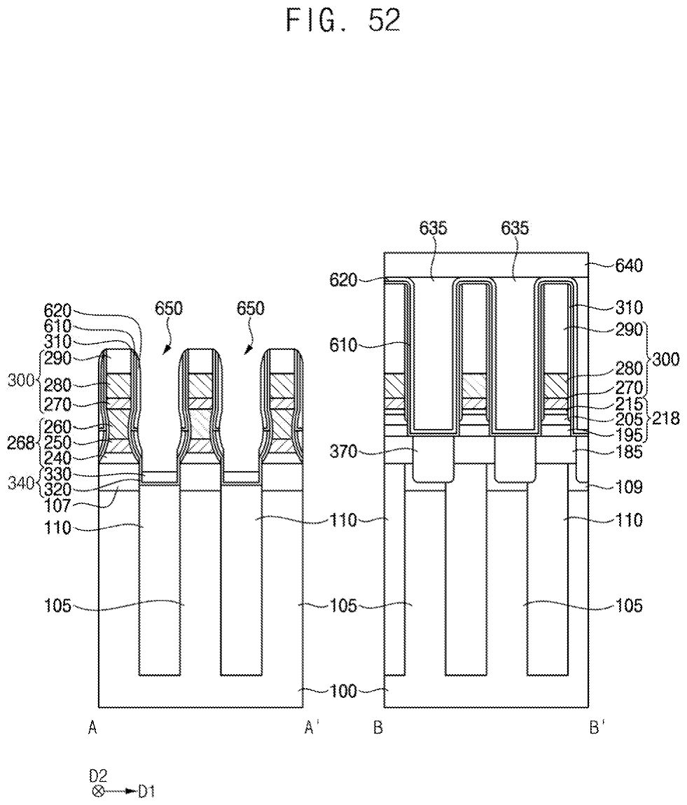

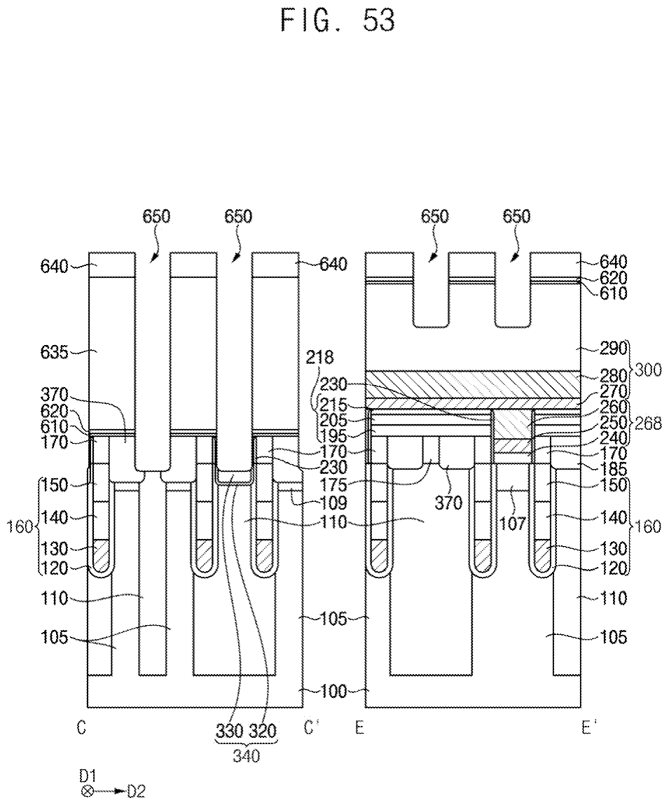

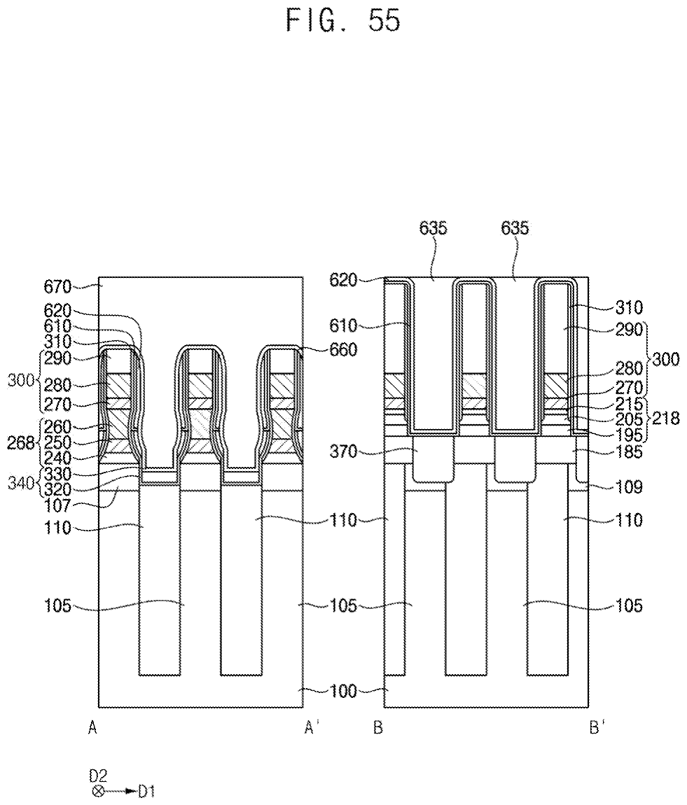

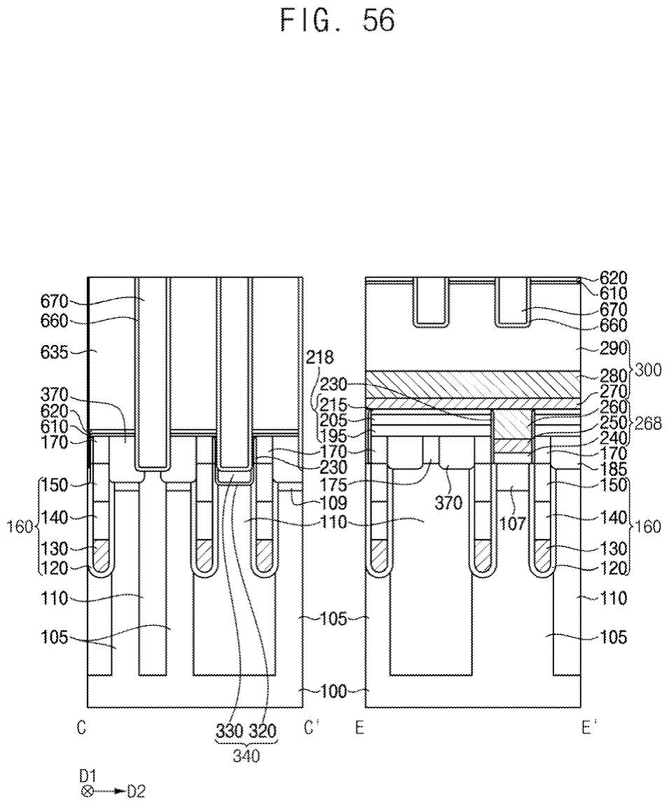

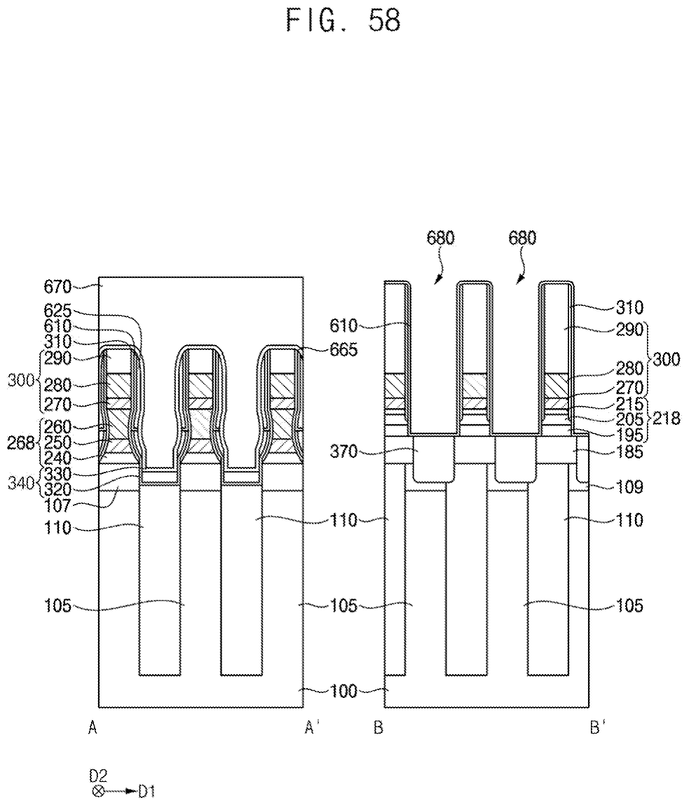

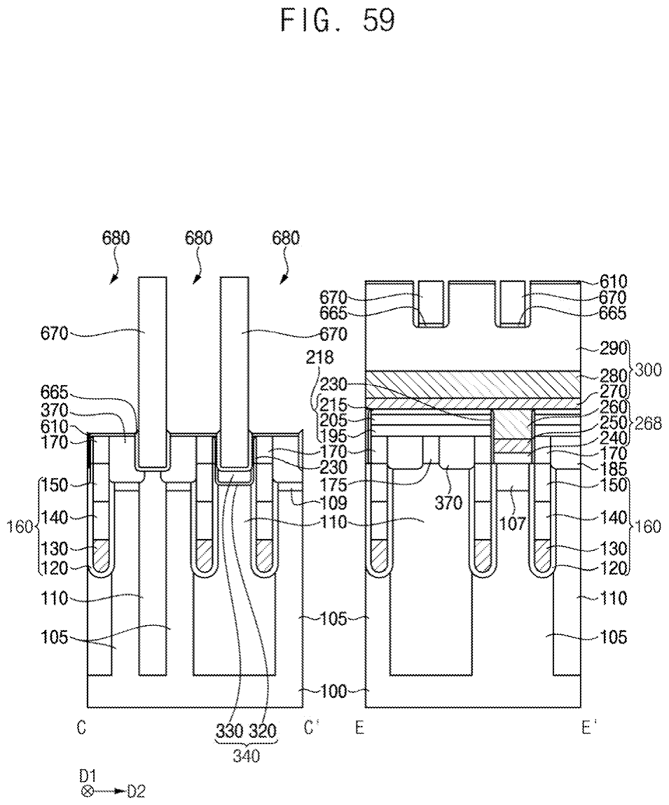

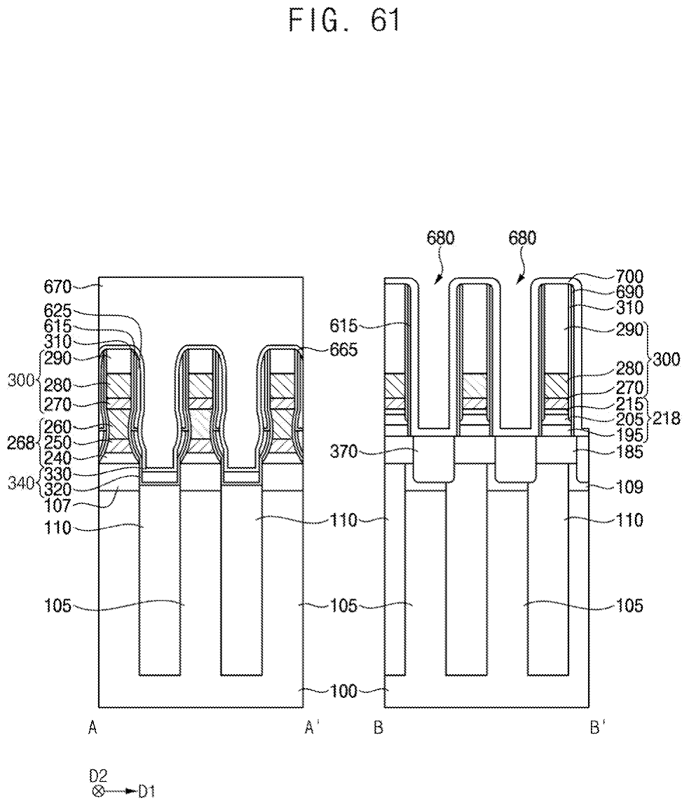

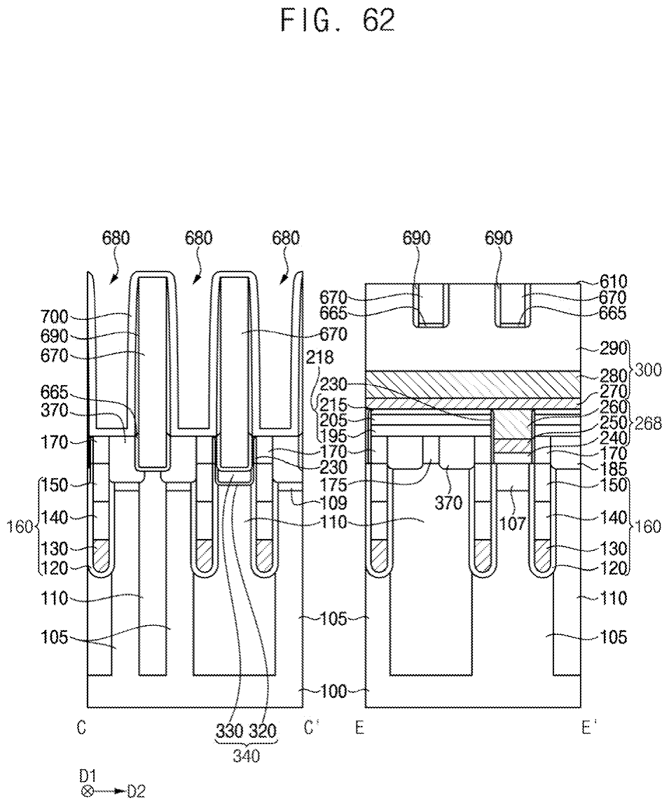

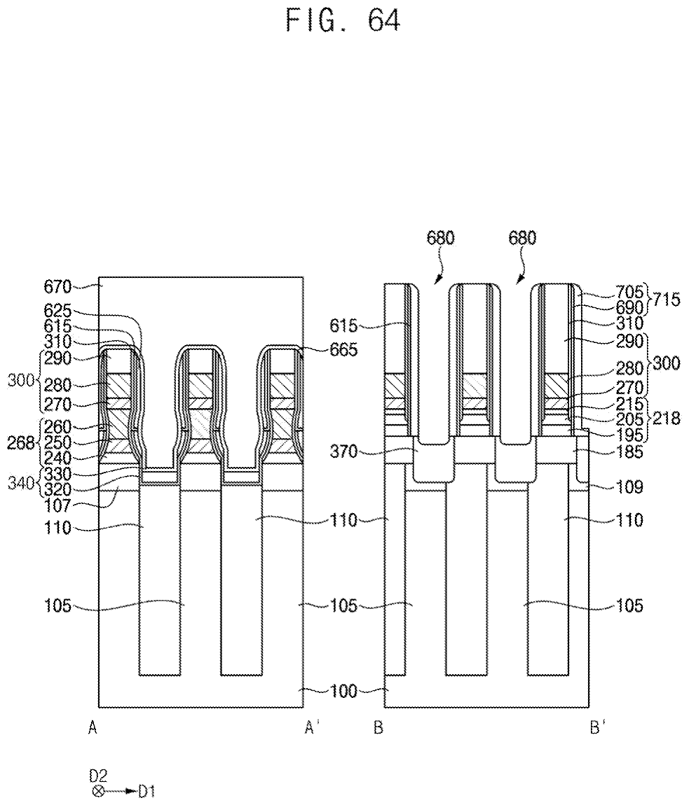

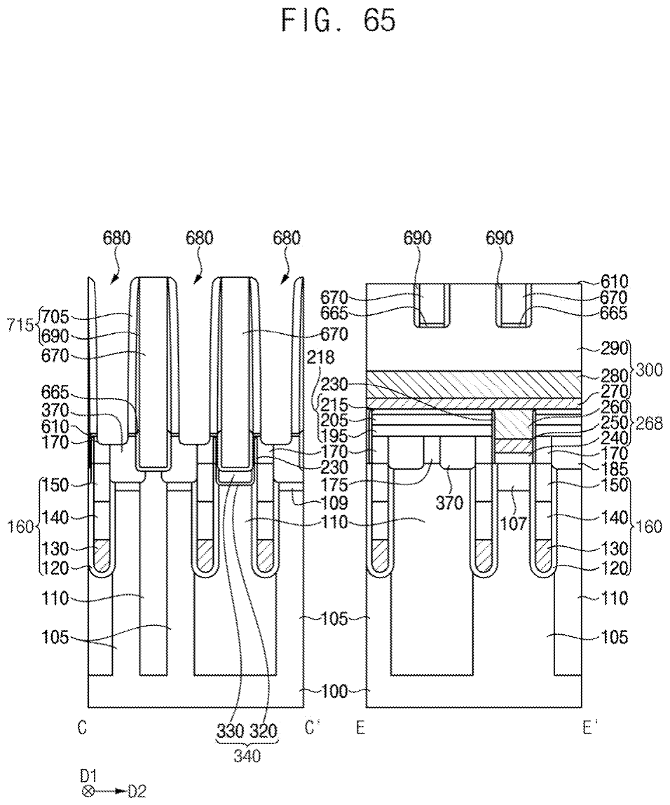

FIGS. 48 to 65 are plan views and cross-sectional views of stages in a method of manufacturing a semiconductor device in accordance with example embodiments. Specifically, FIGS. 48, 51, 54, 57, 60 and 63 are the plan views, and each of FIGS. 49, 52, 55, 58, 61 and 64 includes cross-sectional views taken along lines A-A′ and lines B-B′, respectively, of a corresponding plan view, and each of FIGS. 50, 53, 56, 59, 62 and 65 includes cross-sectional views taken along lines C-C′ and lines E-E′, respectively, of a corresponding plan view. This method of manufacturing the semiconductor device may include processes substantially the same as or similar to those illustrated with reference to FIGS. 1 to 3, and repeated explanations may be omitted herein.

Referring to FIGS. 48 to 50, the processes described with reference to FIGS. 4 to 27 may be performed, a first etch stop layer 610 and a second sacrificial spacer layer 620 may be sequentially formed on the bit line structure 300, the second spacer 310, the buffer structure 218, the filling structure 340, the first and second mold layers 170 and 175 and the second contact structure 370, and an insulating interlayer 630 may be formed on the second sacrificial spacer layer 620 to fill a remaining space between the bit line structures 300.

Thus, the insulating interlayer 630 may extend in the second direction D2, and a plurality of insulating interlayers 630 may be spaced apart from each other in the first direction D1.

Each of the first etch stop layer 610 and the insulating interlayer 630 may include an oxide, e.g., silicon oxide, and the second sacrificial spacer layer 620 may include a nitride, e.g., silicon nitride.

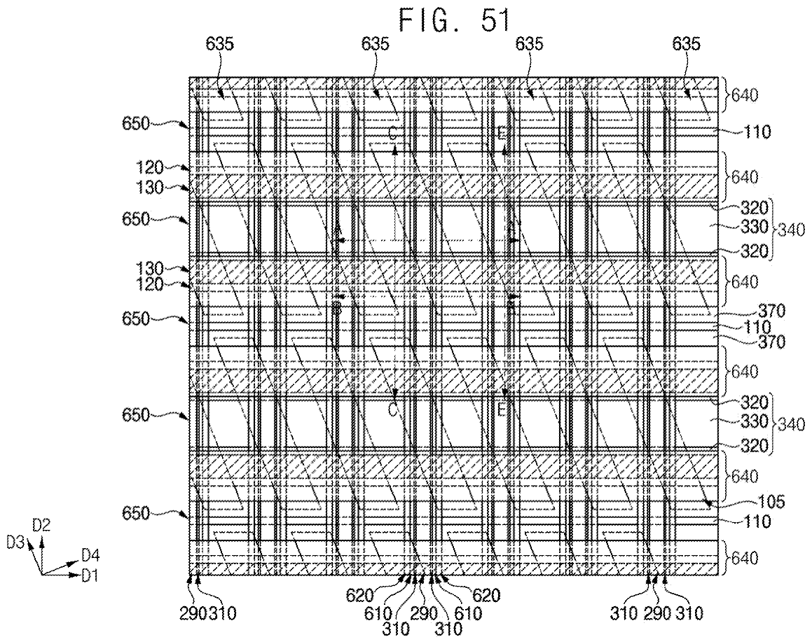

Referring to FIGS. 51 to 53, a second etching mask 640, which may have a seventh opening extending in the first direction D1, may be formed on the second sacrificial spacer layer 620 and the insulating interlayer 630, an etching process using the second etching mask 640 may be performed to partially etch the insulating interlayer 630, the second sacrificial spacer layer 620, the first etch stop layer 610, an upper portion of the filling structure 340 and the second mold layer 175, and thus the second mold layer 175 extending in the first direction D1 may be divided into a plurality of second mold layers 175 spaced apart from each other in the first direction D1 under the bit line structure 300.

During the etching process, an upper lateral portion of the second contact structure 370 adjacent to the second mold layer 175 may also be partially removed. Thus, an eighth opening 650 may be formed through the insulating interlayer 630, the second sacrificial spacer layer 620, and the first etch stop layer 610 to expose the upper surface of the isolation pattern 110 and an upper sidewall of the second contact structure 370 adjacent to the upper surface of the isolation pattern 110, an upper surface of the filling structure 340, and a sidewall of the first spacer 230.

The insulating interlayer 630 extending in the second direction D2 may be divided into a plurality of insulating interlayer patterns 635 spaced apart from each other in the second direction D2. In an implementation, during the etching process, an upper portion of the second mask 290 of a portion of the bit line structure 300 exposed by the seventh opening may be etched to be removed, and thus portions of the second sacrificial spacer layer 620 and the first etch stop layer 610 on the upper surface and the upper sidewall of the portion of the bit line structure 300 may also be removed.

In an implementation, the eighth opening 650 may extend in the first direction D1 between the insulating interlayer patterns 635, and a bottom of a portion of the eighth opening 650 on the bit line structure 300 may be higher than bottoms of other portions of the eighth opening 650.

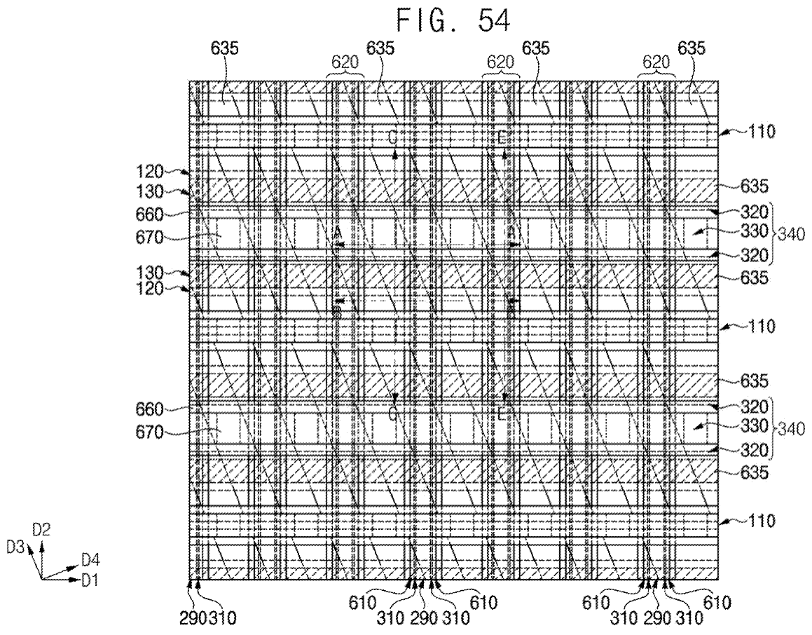

Referring to FIGS. 54 to 56, a preliminary sixth spacer layer may be formed on a bottom and sidewall of the eighth opening 650 and on the second etching mask 640, a second fence layer may be formed on the preliminary sixth spacer layer to fill the eighth opening 650, and the preliminary sixth spacer layer and the second fence layer may be planarized until an upper surface of the insulating interlayer pattern 635 is exposed to form a sixth spacer layer 660 and a second fence pattern 670, respectively.

In an implementation, each of the second fence pattern 670 and the sixth spacer layer 660 may extend in the first direction D1 between the insulating interlayer patterns 635. A bottom surface of a portion of the second fence pattern 670 on the bit line structure 300 may be higher than bottom surfaces of other portions of the second fence pattern 670, and a bottom surface of a portion of the sixth spacer layer 660 on the bit line structure 300 may be higher than bottom surfaces of other portions of the sixth spacer layer 660.

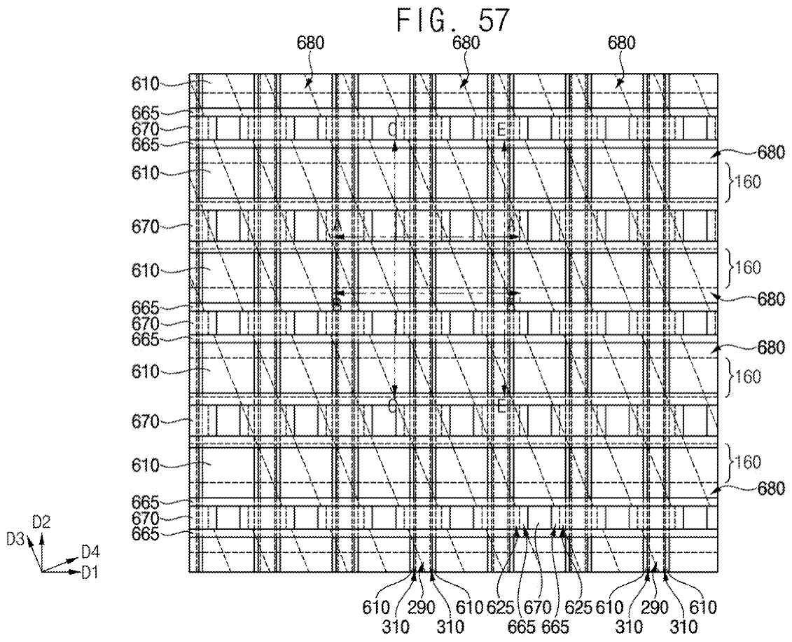

Referring to FIGS. 57 to 59, the insulating interlayer pattern 635 may be removed by, e.g., a wet etching process, to expose a surface of the second sacrificial spacer layer 620 and a surface of the sixth spacer layer 660, and the exposed second sacrificial spacer layer 620 and the exposed sixth spacer layer 660 may be additionally removed to expose a surface of the first etch stop layer 610.

Thus, a ninth opening 680 surrounded by the bit line structures 300 and the second spacers 310 and the first etch stop layer 610 on the sidewalls of the bit line structures 300, and the second fence patterns 670 may be formed. In an implementation, a plurality of ninth openings 680 may be spaced apart from each other in the first and second directions D1 and D2.

The second sacrificial spacer layer 620 may be transformed into a second sacrificial spacer 625 and remain only under the second fence pattern 670, and the sixth spacer layer 660 may be transformed into a sixth spacer 665 and remain only under a lower surface of the second fence pattern 670 and on a lower sidewall in the second direction D2 of the second fence pattern 670.

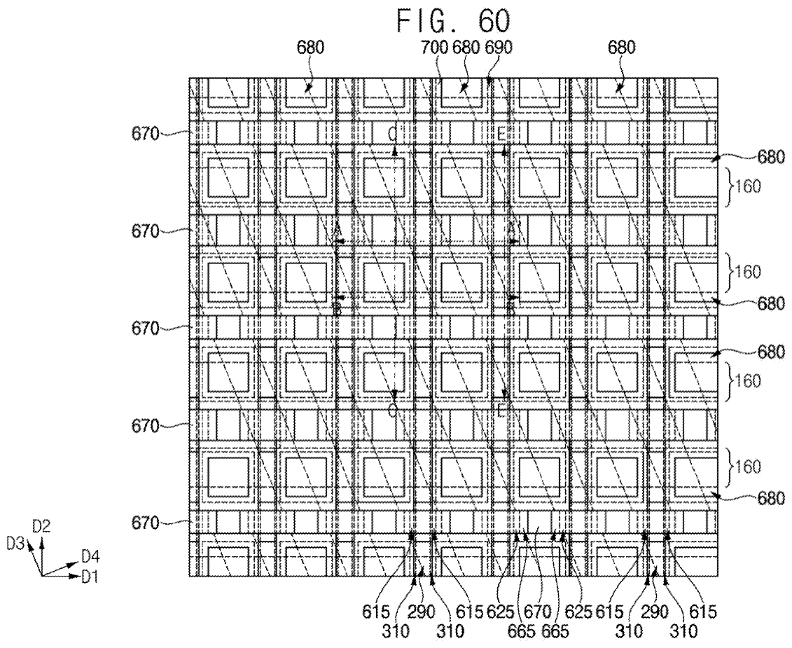

Referring to FIGS. 60 to 62, a seventh spacer layer may be formed on the first etch stop layer 610 and the second fence pattern 670, and the seventh spacer layer may be anisotropically etched to form a seventh spacer layer 690.

In an implementation, the seventh spacer 690 may include a material substantially the same as that of the first etch stop layer 610, e.g., an oxide such as silicon oxide, and thus a portion of the first etch stop layer 610 under the seventh spacer 690 may be merged into the seventh spacer 690. Hereinafter, the merged structure may be referred to as the seventh spacer 690. A portion of the first etch stop layer 610 under a lower surface of the second fence pattern 670 may be referred to as a first etch stop pattern 615.

During the anisotropic etching process, a portion of the seventh spacer layer and a portion of the first etch stop layer 610 on the upper surface of the bit line structure 300, and a portion of the seventh spacer and a portion of the first etch stop layer 610 on a bottom of the ninth opening 680 may be removed to expose the upper surface of the bit line structure 300, and the upper surfaces of the second contact structure 370 and the first mold layer 170.

An eighth spacer layer 700 may be formed on the exposed upper surface of the bit line structure 300, and the exposed upper surfaces of the second contact structure 370 and the first mold layer 170.

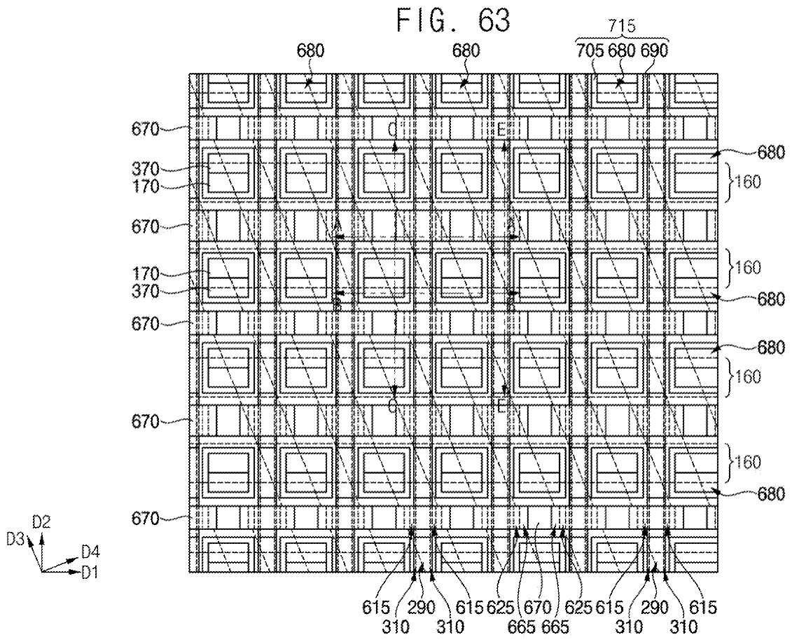

Referring to FIGS. 63 to 65, an anisotropic etching process may be performed on the eighth spacer layer 700 to form an eighth spacer 705, an etching process may be performed using the bit line structure 300, the second spacer 310 and the seventh and eighth spacers 690 and 705 on the sidewall of the bit line structure 300, and the second fence pattern 670 as an etching mask to remove upper portions of the second contact structure 370 and the first mold layer 170, which may not be covered by the etching mask, and thus the ninth opening 680 may be enlarged downwardly.

The seventh and eighth spacers 690 and 705 may collectively form a second spacer structure 715.

Referring back to FIGS. 45 to 47, processes substantially the same as or similar to the processes described with reference to FIGS. 37 to 42 and FIGS. 1 to 3 may be performed.

In an implementation, the third contact pattern may be formed in the ninth opening 680 and the upper portion of the third contact pattern may be removed, and when the upper portion of the third contact pattern is removed, an upper portion of the eighth spacer 705 surrounding the third contact pattern may also be partially removed to reduce a thickness of the eighth spacer 705. An upper portion of the second contact structure 370 exposed by the ninth opening 680 may be converted into the second ohmic contact pattern 375, when the third contact pattern is formed or by a separate heat treatment process.

The fourth contact pattern may be formed on the third contact pattern, and a planarization process may be performed on the upper portion of the fourth contact pattern. Thus, the third contact structure 450 including the third and fourth contact patterns stacked in the vertical direction may be formed in the ninth opening 680.

During the planarization process, upper portions of the bit line structure 300, the second fence pattern 670, the second spacer 310 and the second spacer structure 715 may also be partially removed, and the upper surfaces of the bit line structure 300, the second fence pattern 670, the second spacer 310 and the second spacer structure 715 may be substantially coplanar with the upper surface of the contact structure 450.

The insulation pattern 470, the landing pads 460 and the capacitor 510 may be formed to complete the manufacturing of the semiconductor device.

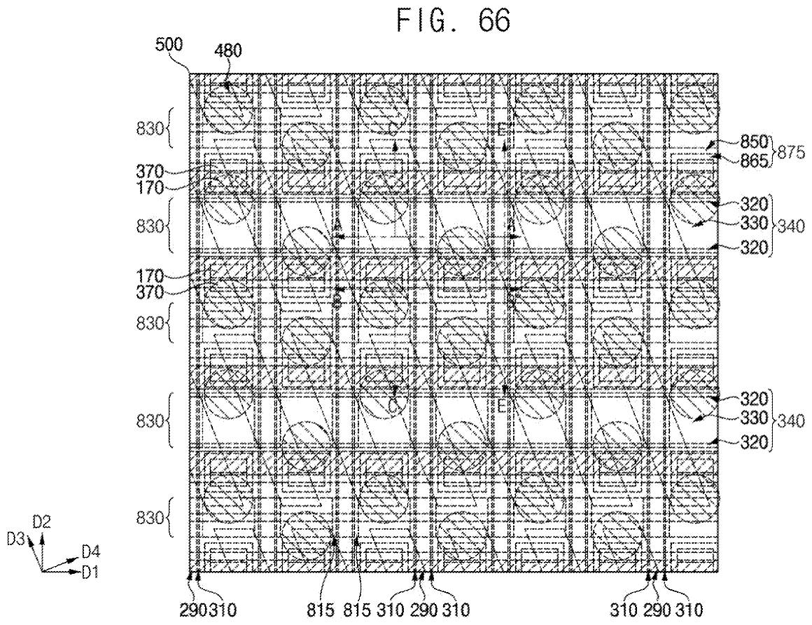

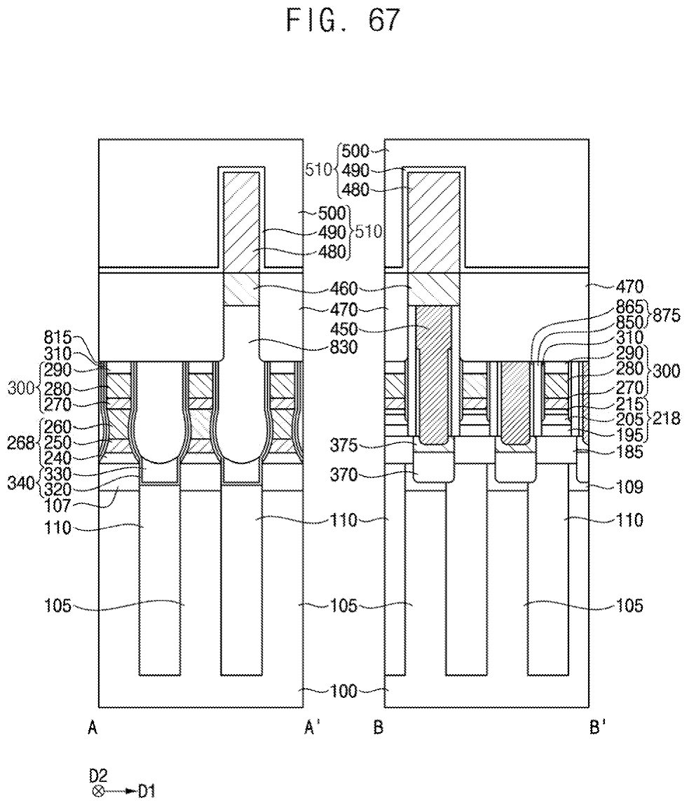

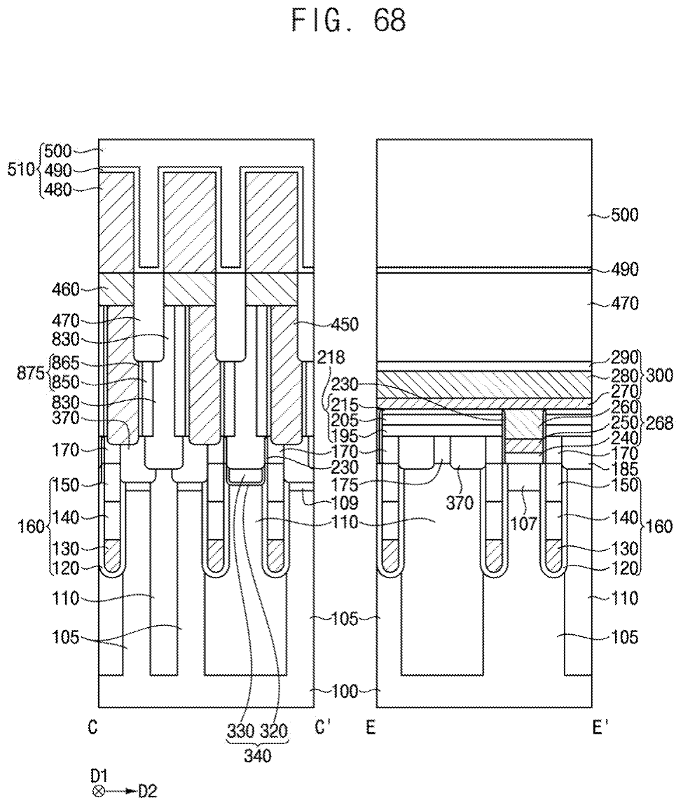

FIGS. 66 to 68 are a plan view and cross-sectional views illustrating a semiconductor device in accordance with example embodiments, which correspond to FIGS. 1 to 3, respectively. This semiconductor device may be substantially the same as or similar to the semiconductor device of FIGS. 1 to 3, except for some elements, so like reference numerals refer to like elements and repeated explanations may be omitted herein.

Referring to FIGS. 66 to 68, the semiconductor device may include a third spacer structure 875, instead of the first spacer structure 440, on the outer wall of the second spacer 310 on the sidewall of the bit line structure 300 in the first direction D1 of the bit line structure 300, and may include a third fence pattern 830 instead of the first fence pattern 400 extending in the first direction D1. The third spacer structure 875, instead of the first spacer structure 440, may also be formed on a sidewall of the third fence pattern 830 in the second direction D2.

In an implementation, the third spacer structure 875 may include tenth and eleventh spacers 850 and 865 stacked in the horizontal direction from the sidewall of the third fence pattern 830 in the second direction D2. The tenth spacer 850 may include an oxide, e.g., silicon oxide, and the eleventh spacer 865 may include, e.g., silicon oxycarbonitride, silicon oxynitride, silicon nitride, or the like. In an implementation, the third fence pattern 830 may include nitride, e.g., silicon oxycarbonitride, silicon oxynitride, silicon nitride, or the like.

A ninth spacer 815, instead of the third spacer 385, may be formed on the upper surface of the portion of the bit line structure 300 under the third fence pattern 830 and the outer sidewall of the second spacer 310 on the sidewall in the first direction D1 of the portion of the bit line structure 300 under the third fence pattern 830. The ninth spacer 815 may include an oxide, e.g., silicon oxide.

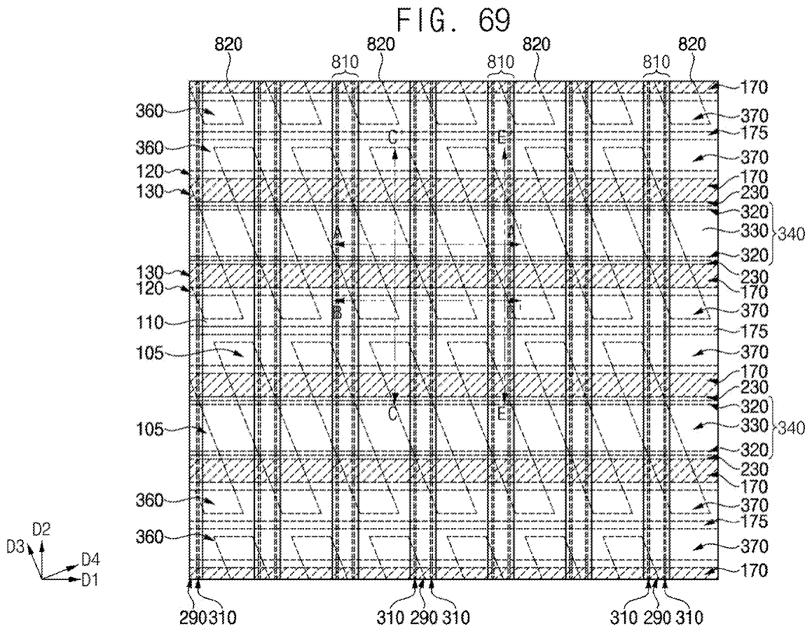

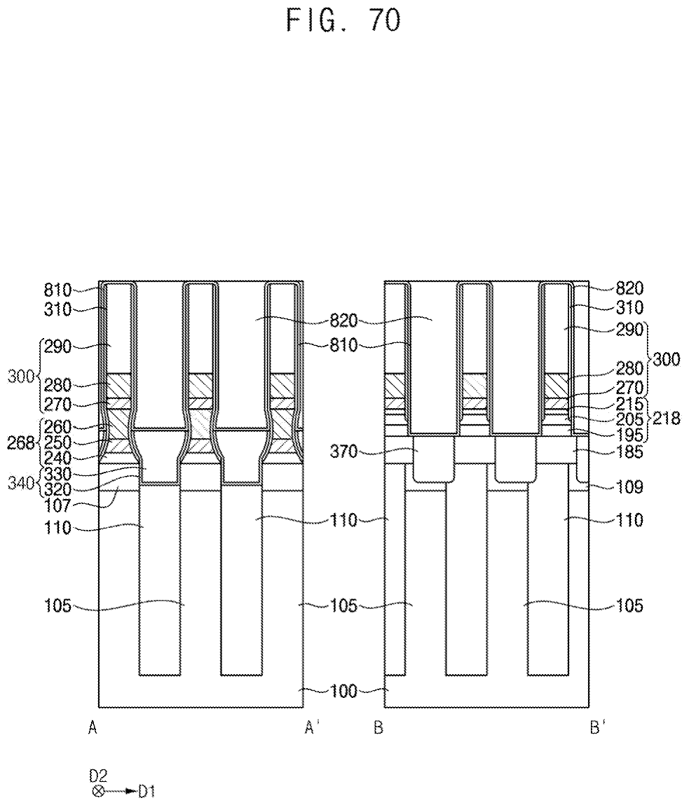

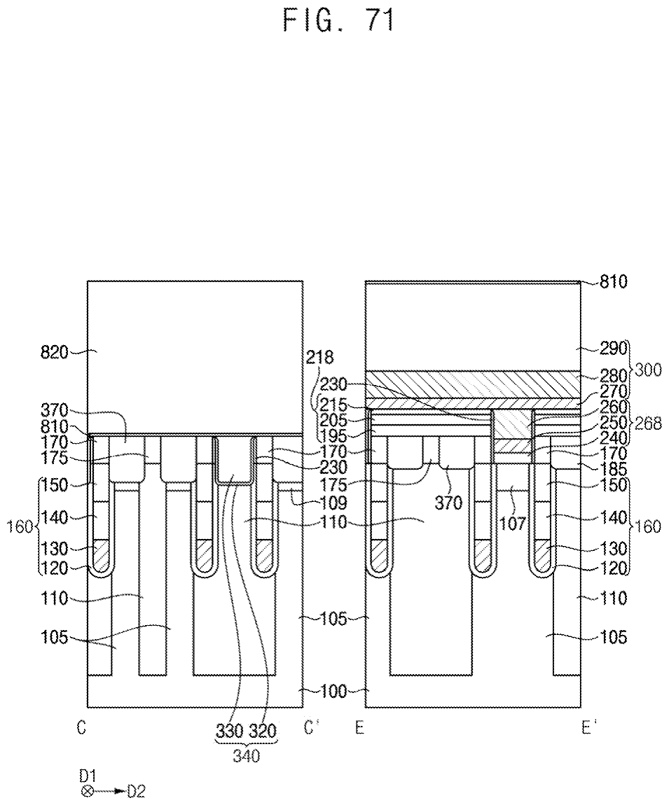

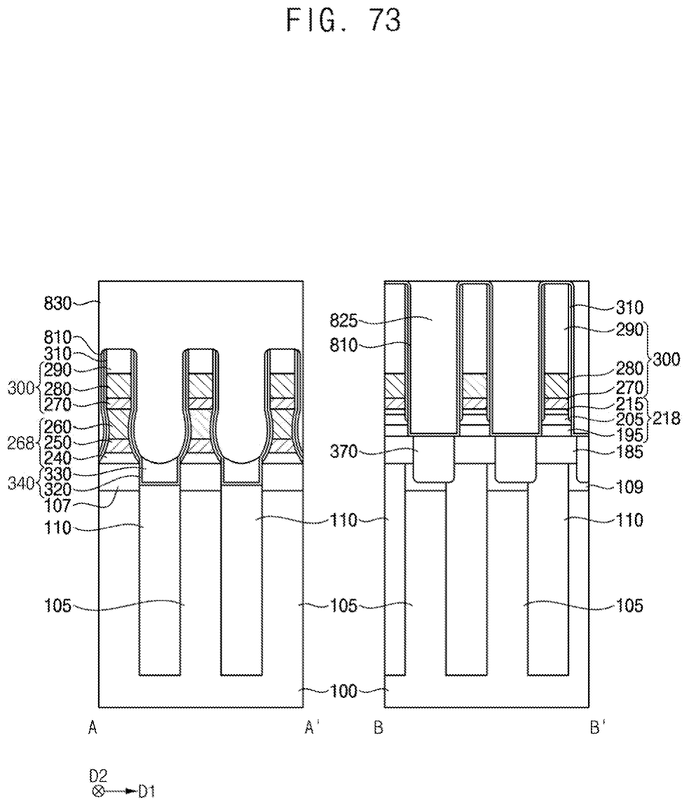

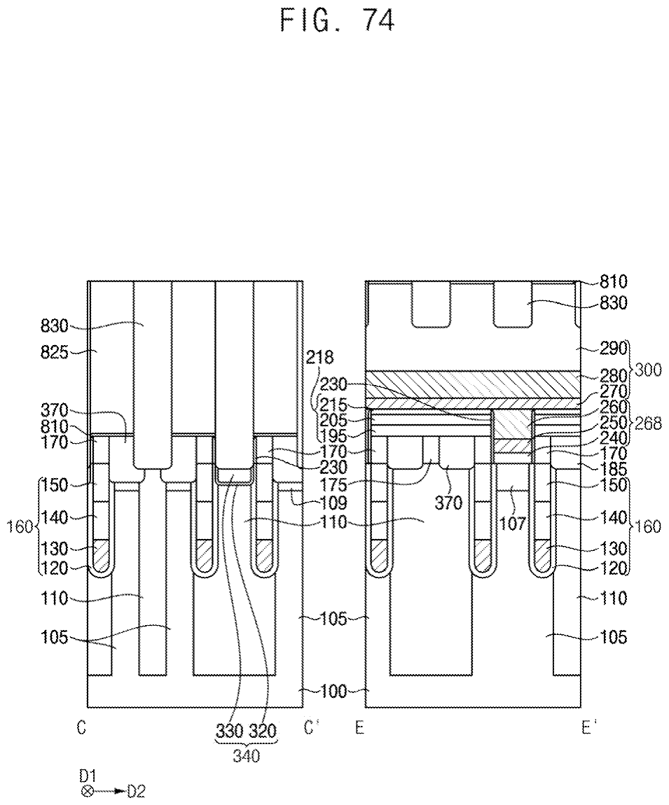

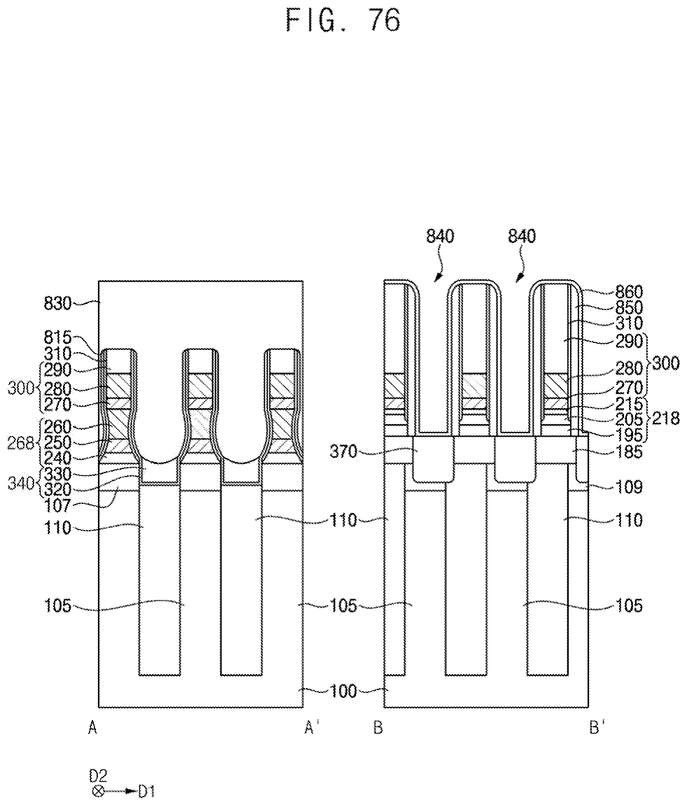

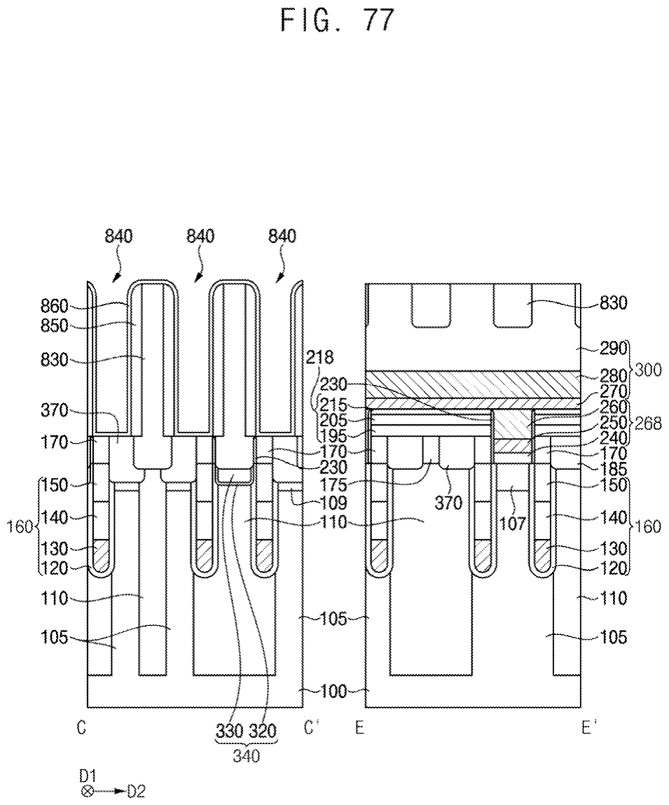

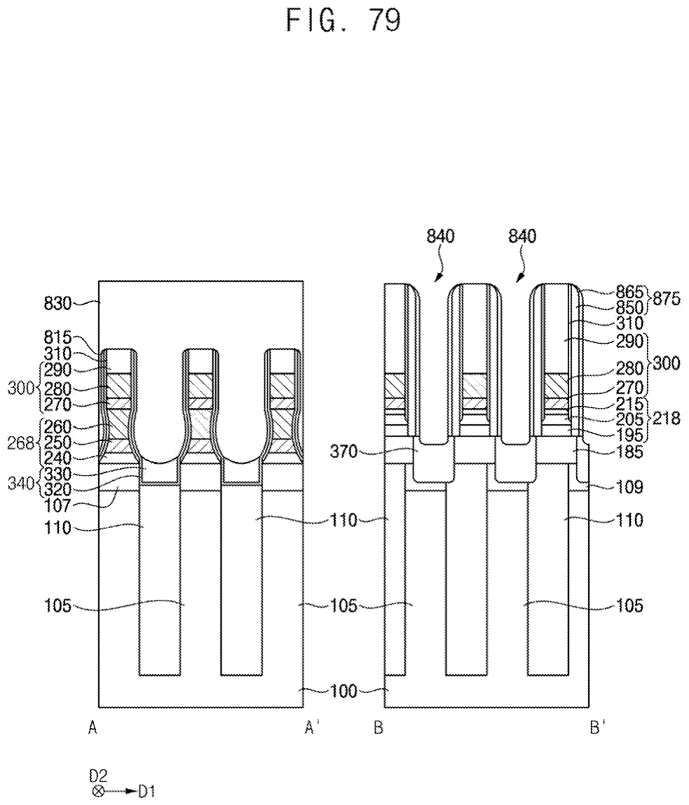

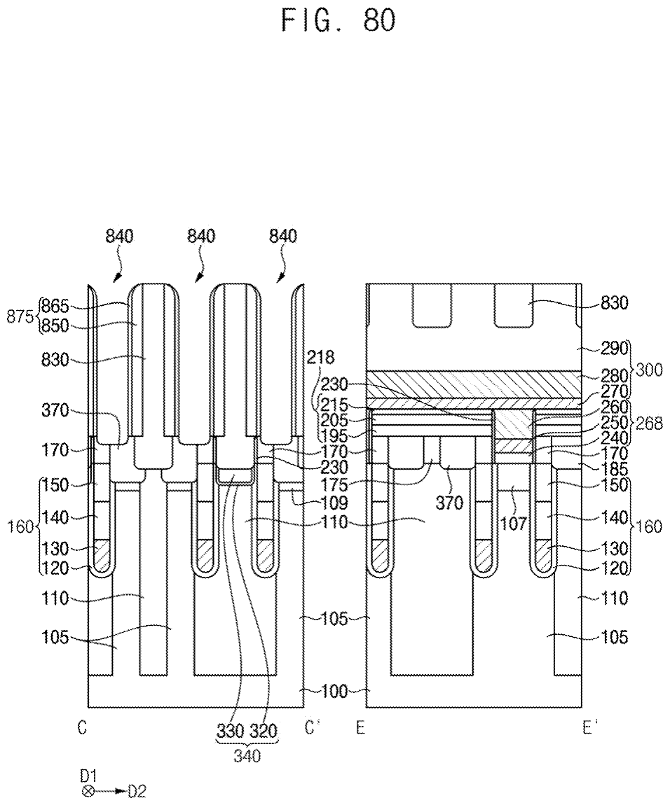

FIGS. 69 to 80 are plan views and cross-sectional views of stages in a method of manufacturing a semiconductor device in accordance with example embodiments. Specifically, FIGS. 69, 72, 75 and 78 are the plan views, each of FIGS. 70, 73, 76 and 79 includes cross-sectional views taken along lines A-A′ and B-B′, respectively, of a corresponding plan view, and each of FIGS. 71, 74, 77 and 80 includes cross-sectional views taken along lines C-C′ and lines E-E′, respectively, of a corresponding plan view. This method of manufacturing the semiconductor device may include processes substantially the same as or similar to those illustrated with reference to FIGS. 4 to 42 and FIGS. 1 to 3, and repeated explanations are omitted herein.

Referring to FIGS. 69 to 71, processes described with reference to FIGS. 4 to 27 may be performed, and a ninth spacer layer 810 may be formed on the bit line structure 300, the second spacer 310, the buffer structure 218, the filling structure 340, the first and second mold layers 170 and 175 and the second contact structure 370, and a second sacrificial insulating interlayer 820 may be formed on the ninth spacer layer 810 to fill a space between the bit line structures 300.

Thus, the second sacrificial insulating interlayer 820 may extend in the second direction D2, and a plurality of second sacrificial insulating interlayers 820 may be spaced apart from each other in the first direction D1.

The ninth spacer layer 810 may include an oxide, e.g., silicon oxide, and the second sacrificial insulating interlayer 820 may include, e.g., an amorphous carbon layer (ACL), spin-on hard-mask (SOH), or the like.

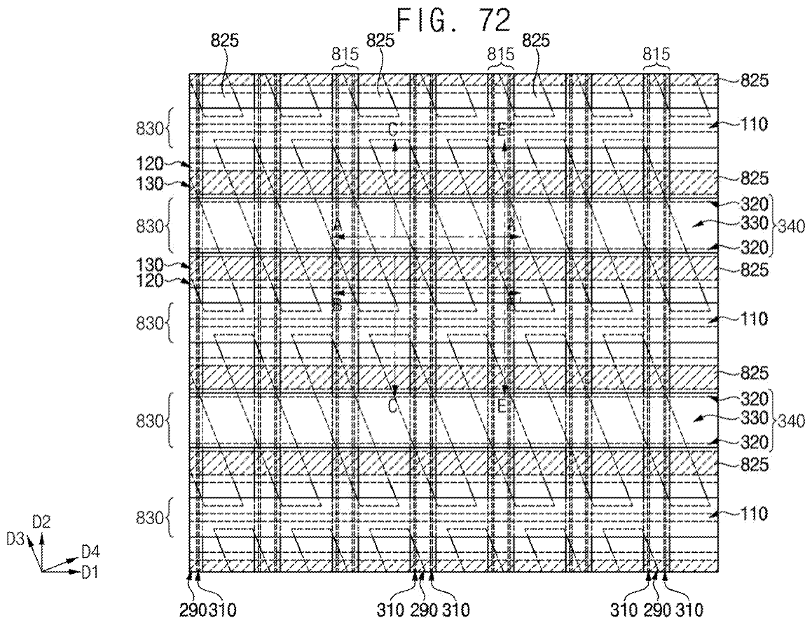

Referring to FIGS. 72 to 74, a third etching mask, which may have a tenth opening extending in the first direction D1, may formed on the second sacrificial insulating interlayer 820 and the ninth spacer layer 810, an etching process using the third etching mask may be performed to partially etch the second sacrificial insulating interlayer 820, the ninth spacer layer 810, the upper portion of the filling structure 340 and the second mold layer 175, and thus the second mold layer 175 extending in first direction D1 may remain only under the bit line structure 300 so as to be divided into a plurality of second mold layers 175 spaced apart from each other in the first direction D1

During the etching process, the upper lateral portion of the second contact structure 370 adjacent to the second mold layer 175 may also be partially removed. Thus, an eleventh opening may be formed through the second sacrificial insulating interlayer 820 and the ninth spacer layer 810 to expose the upper surface of the isolation pattern 110, the upper sidewall of the second contact structure 370 adjacent to the upper surface of the isolation pattern 110 and the sidewall of the first spacer 230.

The second sacrificial insulating interlayer 820 extending in the second direction D2 may be divided into a plurality of second sacrificial insulating interlayer patterns 825 spaced apart from each other in the second direction D2. Also, during the etching process, the upper portion of the second mask 290 of the portion of the bit line structure 300 exposed by the tenth opening may be etched to be removed, and thus a portion of the ninth spacer layer 810 on the upper surface and the upper sidewall of the portion of the bit line structure 300 may also be removed.

In an implementation, the eleventh opening may extend in the first direction D1 between the second sacrificial insulating interlayer patterns 825, and a bottom of a portion of the eleventh opening on the bit line structure 300 may be higher than bottoms of other portions of the eleventh opening.

A third fence layer may be formed to fill the eleventh opening, and the third fence layer may be planarized until an upper surface of the second sacrificial insulating interlayer pattern 825 is exposed to form a third fence pattern 830. Thus, the third fence pattern 830 may extend in the first direction D1 between the second sacrificial insulating interlayer patterns 825, and a bottom surface of a portion of the third fence pattern 830 on the bit line structure 300 may be higher than bottom surfaces of other portions of the third fence pattern 830.

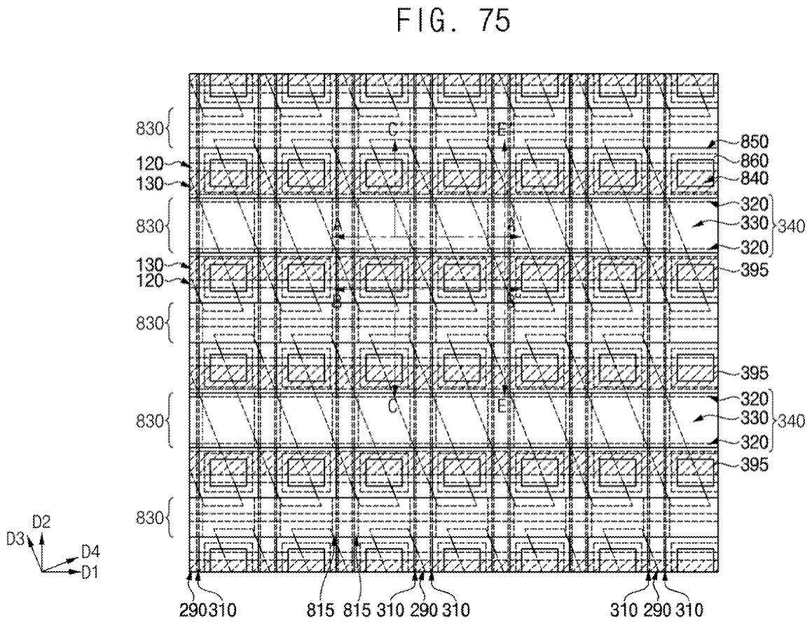

Referring to FIGS. 75 to 77, the second sacrificial insulating interlayer pattern 825 may be removed by, e.g., an ashing process or a stripping process, to expose a surface of the ninth spacer layer 810 and a surface of the third fence pattern 830.

Thus, a twelfth opening 840 surrounded by the bit line structures 300, the second spacers 310 and the ninth spacer layer 810 on the sidewall of the bit line structures 300, and the third fence pattern 830 may be formed. In an implementation, a plurality of twelfth openings 840 may be spaced apart from each other in the first and second directions D1 and D2.

A tenth spacer layer may be formed on the ninth spacer layer 810 and the third fence pattern 830, and may be anisotropically etched to form a tenth spacer 850.

In an implementation, the tenth spacer 850 may include a material substantially the same as that of the ninth spacer layer 810, e.g., an oxide such as silicon oxide, and thus a portion of the ninth spacer layer 810 under the tenth spacer 850 may be merged into the tenth spacer 850. Hereinafter, the merged structure may be referred to as the tenth spacer 850. A portion of the ninth spacer layer 810 under the lower surface of the third fence pattern 830 may be referred to as a ninth spacer 815.

During the anisotropic etching process, a portion of the tenth spacer layer, a portion of the ninth spacer layer 810 on the upper surface of the bit line structure 300, and a portion of the tenth spacer layer and a portion of the ninth spacer layer 810 on a bottom of the twelfth opening 840 may be removed to expose the upper surface of the bit line structure 300, and the upper surfaces of the second contact structure 370 and the first mold layer 170.

An eleventh spacer layer 860 may be formed on the exposed upper surface of the bit line structure 300, the upper surfaces of the second contact structure 370 and the first mold layer 170.

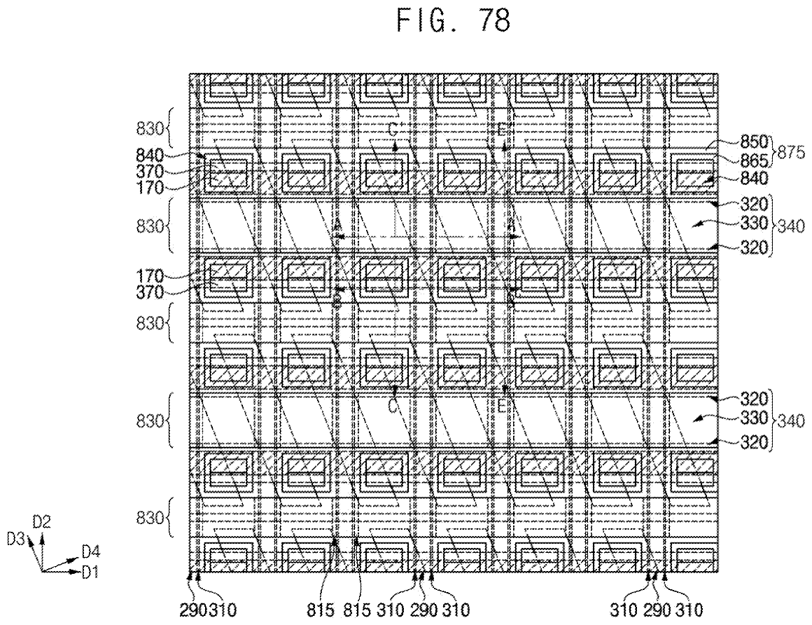

Referring to FIGS. 78 to 80, an anisotropic etching process may be performed on the eleventh spacer layer 860 to form a eleventh spacer 865, an etching process may be performed using the bit line structure 300, the second spacer 310, and the tenth and eleventh spacers 850 and 865 on the sidewall of the bit line structure 300, and the third fence pattern 830 as an etching mask to remove upper portions of the second contact structure 370 and the first mold layer 170, which may not be covered by the etching mask, and thus the twelfth opening 840 may be enlarged downwardly.

The tenth and eleventh spacers 850 and 865 may collectively form a third spacer structure 875.

Referring back to FIGS. 66 to 68, processes substantially the same as or similar to those described with reference to FIGS. 37 to 42 and FIGS. 1 to 3 may be performed.

In an implementation, the second ohmic contact pattern 375, the third contact structure 450, the insulation pattern 470, the landing pad 460 and the capacitor 510 may be formed to complete the manufacture of the semiconductor device.

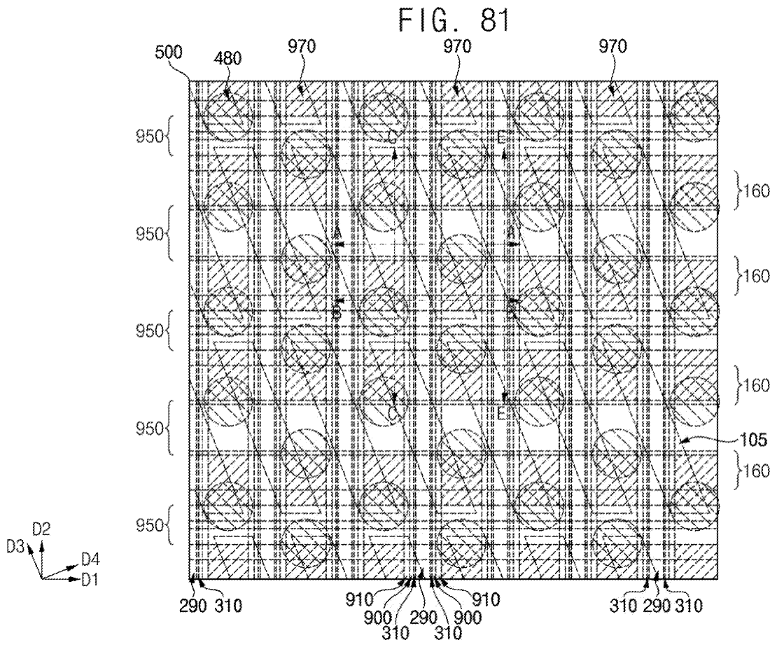

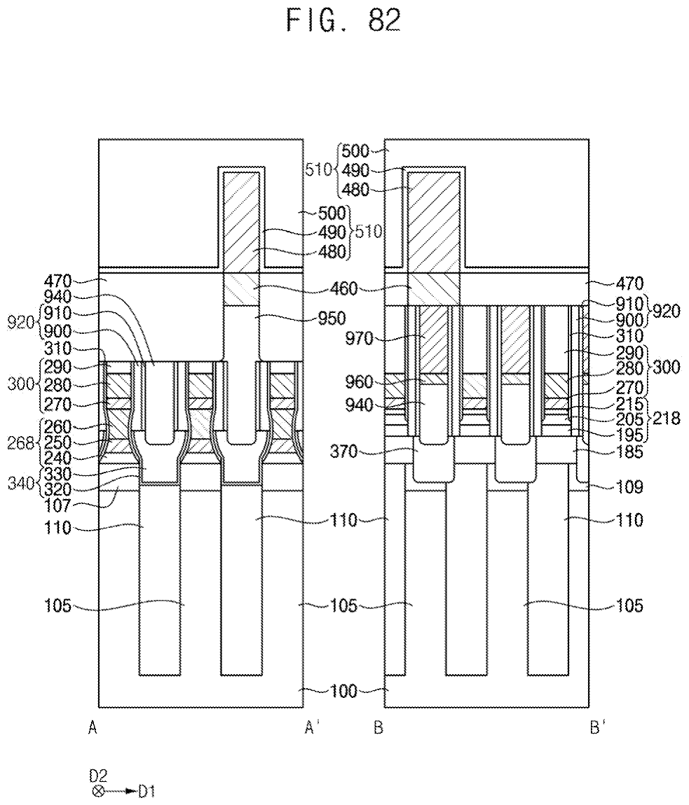

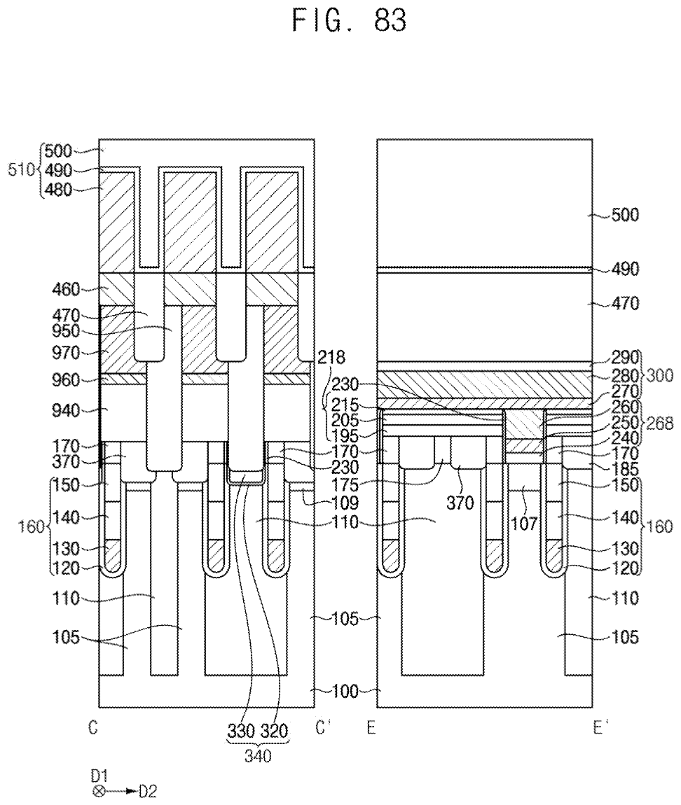

FIGS. 81 to 83 are a plan view and cross-sectional views illustrating a semiconductor device in accordance with example embodiments, which may correspond to FIGS. 1 to 3, respectively. This semiconductor device may be substantially the same as or similar to the semiconductor device that of FIGS. 1 to 3, except for some elements, so like reference numerals refer to like elements and repeated explanations may be omitted herein.

Referring to FIGS. 81 to 83, the semiconductor device may include a fourth spacer structure 920, instead of the first spacer structure 440, on the outer sidewall of the second spacer 310 on the sidewall in the first direction D1 of the bit line structure 300, and may include a fourth fence pattern 950 instead of the first fence pattern 400 extending in the first direction D1.

In an implementation, the fourth spacer structure 920 may include twelfth and thirteenth spacers 900 and 910 stacked in the horizontal direction from the second spacer 310 on the sidewall of the bit line structure 300 in the first direction D1. The twelfth spacer 900 may include an oxide, e.g., silicon oxide, and the thirteenth spacer 910 may include, e.g., silicon oxycarbonitride, silicon oxynitride, silicon nitride, or the like. In an implementation, the fourth fence pattern 950 may include a nitride, e.g., silicon oxycarbonitride, silicon oxynitride, silicon nitride, or the like.

A fifth contact structure 940, a fourth ohmic contact pattern 960, and a sixth contact structure 970 may be formed on the second contact structure 370 between the bit line structure 300 and the second spacer 310 and the fourth spacer structure 920 stacked on the sidewall of the bit line structure 300, and the fourth fence pattern 950.

The fifth contact structure 940 may include, e.g., polysilicon doped with impurities. Unlike the third contact structure 450, the sixth contact structure 970 may have an upper portion and a lower portion having substantially the same width.

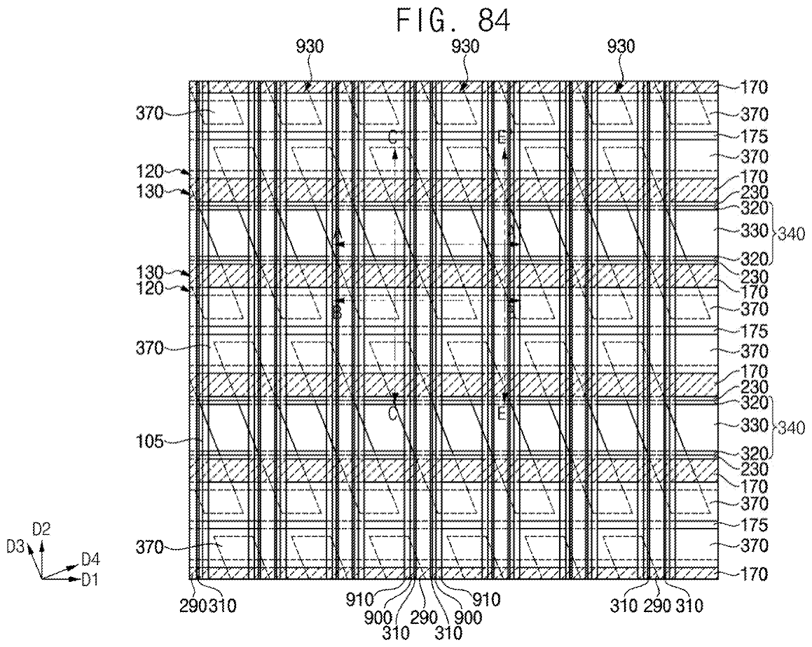

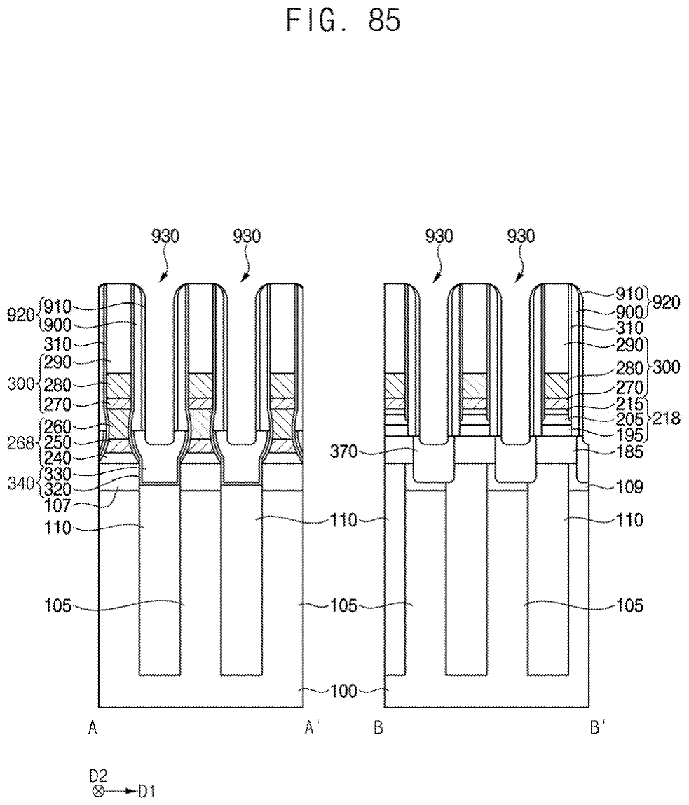

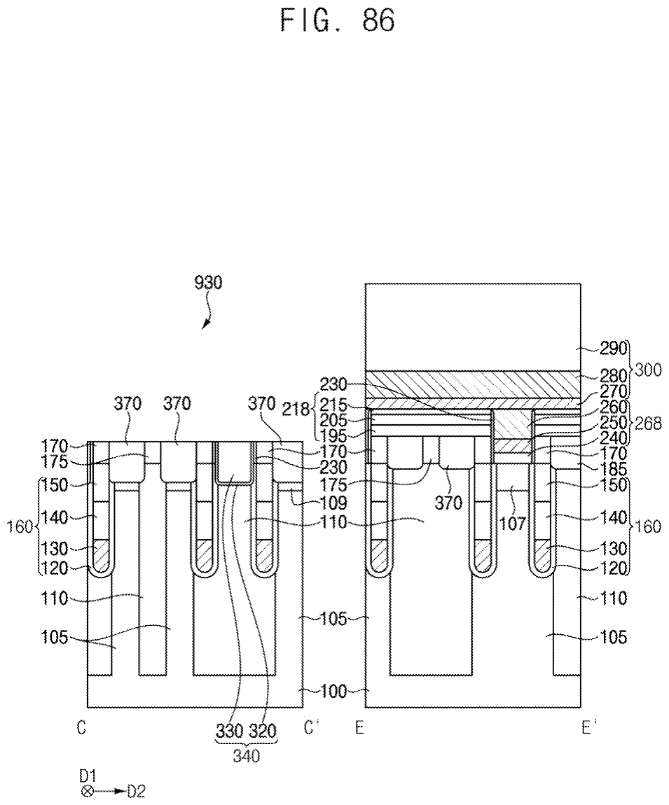

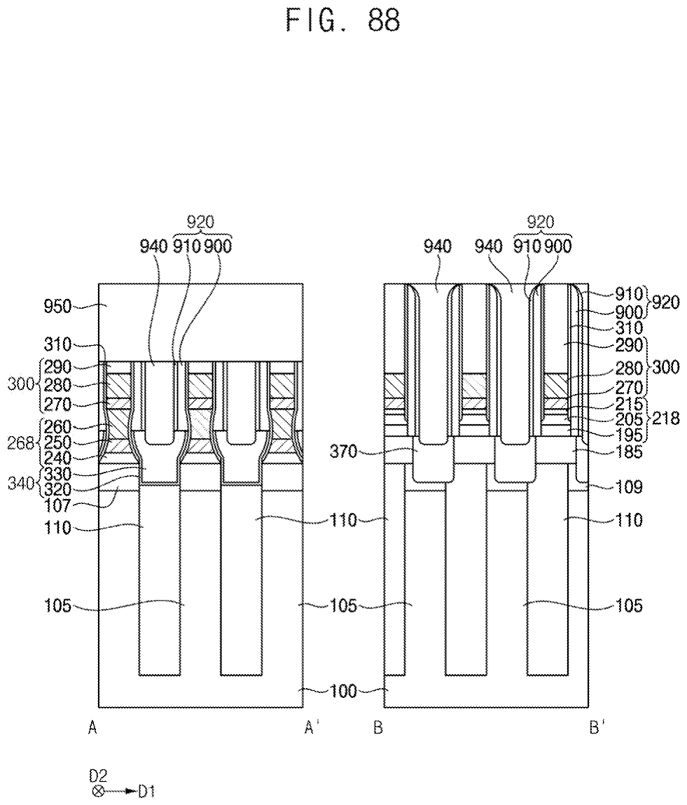

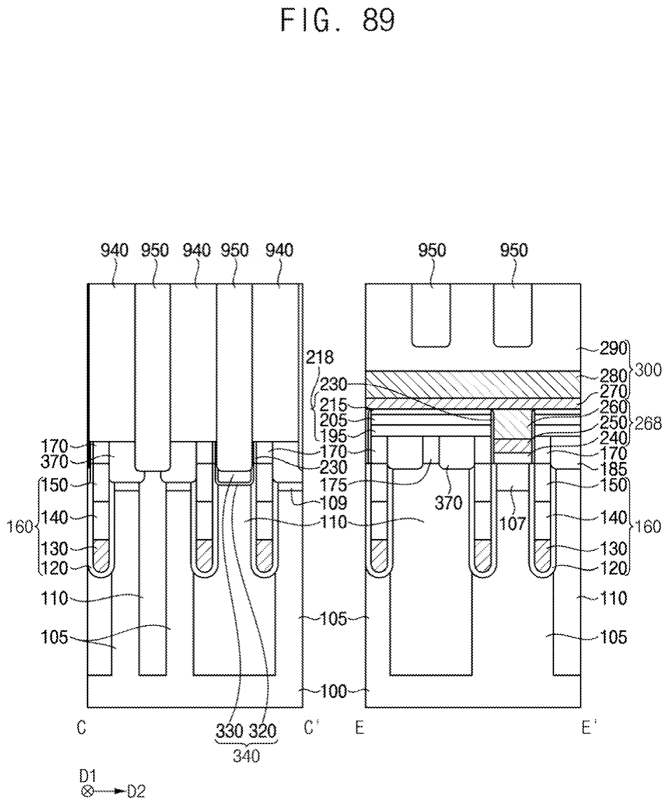

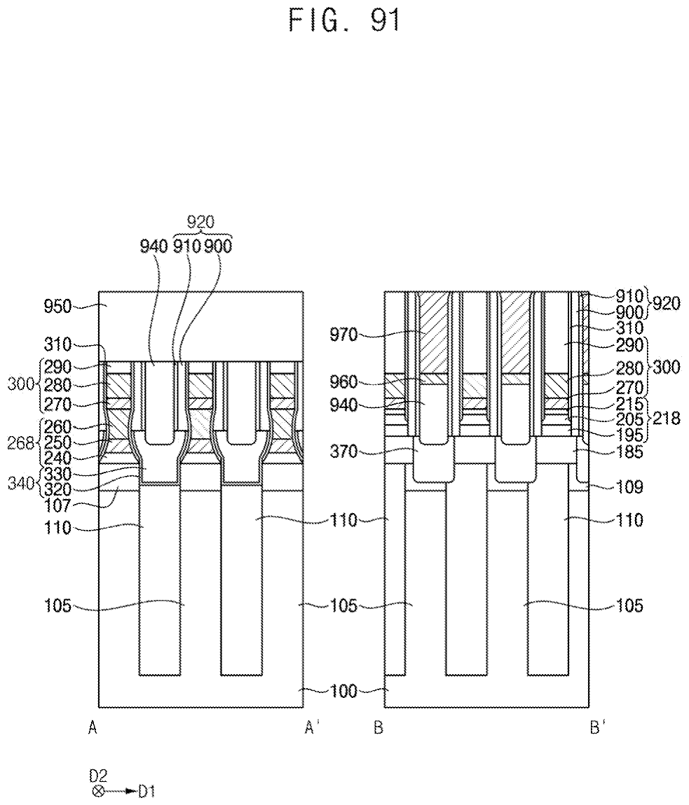

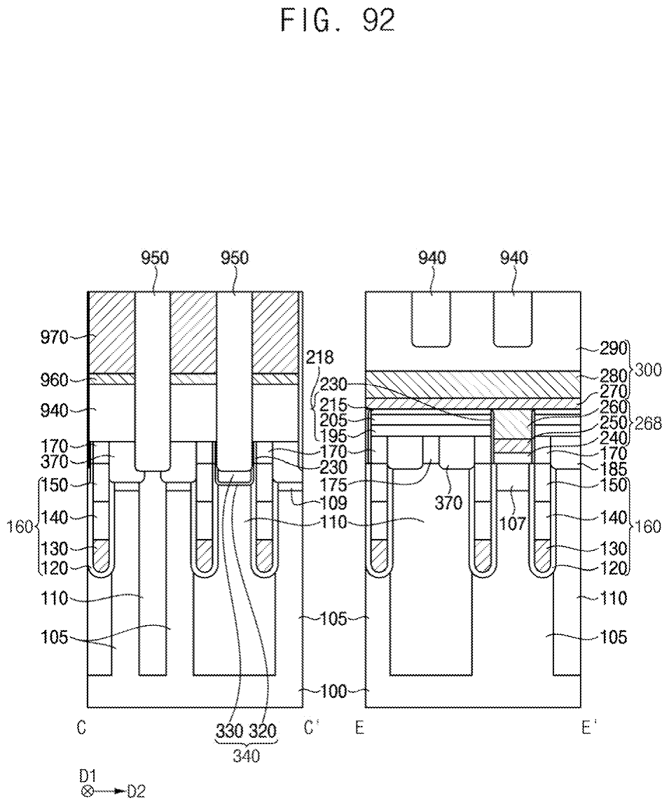

FIGS. 84 to 92 are plan views and cross-sectional views of stages in a method of manufacturing a semiconductor device in accordance with example embodiments. Specifically, FIGS. 84, 87 and 90 are the plan views, each of FIGS. 85, 88 and 91 includes cross-sectional views taken along line A-A′ and line B-B′, respectively, of a corresponding plan view, and each of FIGS. 86, 89 and 92 includes cross-sectional views taken along line C-C′ and line E-E′, respectively, of a corresponding plan view. This method of manufacturing the semiconductor device may include processes substantially the same as or similar to those illustrated with reference to FIGS. 4 to 42 and FIGS. 1 to 3, and repeated explanations may be omitted herein.

Referring to FIGS. 84 to 86, the processes described with reference to FIGS. 4 to 27 may be performed, a twelfth spacer layer may be formed on the bit line structure 300, the second spacer 310, the buffer structure 218, the filling structure 340, the first and second mold layers 170 and 175 and the second contact structure 370, and an anisotropic etching process may be performed on the twelfth spacer layer to form a twelfth spacer 900 on the outer sidewall of the second spacer 310.

A third spacer layer may be formed on the bit line structure 300, the second spacer 310, the twelfth spacer 900, the buffer structure 218, the filling structure 340, the first and second mold layers 170 and 175, and the second contact structure 370, and an anisotropic etching process may be performed on the third spacer layer to form a thirteenth spacer 910 on an outer sidewall of the twelfth spacer 900. Thus, each of the twelfth spacer 900 and the thirteenth spacer 910 may extend in the second direction D2.

The twelfth spacer 900 may include an oxide, e.g., silicon oxide, and the thirteenth spacer 910 may include a nitride, e.g., silicon oxycarbonitride, silicon oxynitride, silicon nitride, or the like. The twelfth and thirteenth spacers 900 and 910 may collectively form a fourth spacer structure 920.

An etching process may be performed using the bit line structure 300, the second spacer 310 and the fourth spacer structure 920 as an etching mask, so that the upper portions of the filling structure 340, the second contact structure 370 and first and second mold layers 170 and 175 may be etched.

Hereinafter, a space between structures including the bit line structure 300, the second spacer 310, and the fourth spacer structure 920 on the sidewall of the bit line structure 300 in the first direction D1 may be referred to as a thirteenth opening 930.

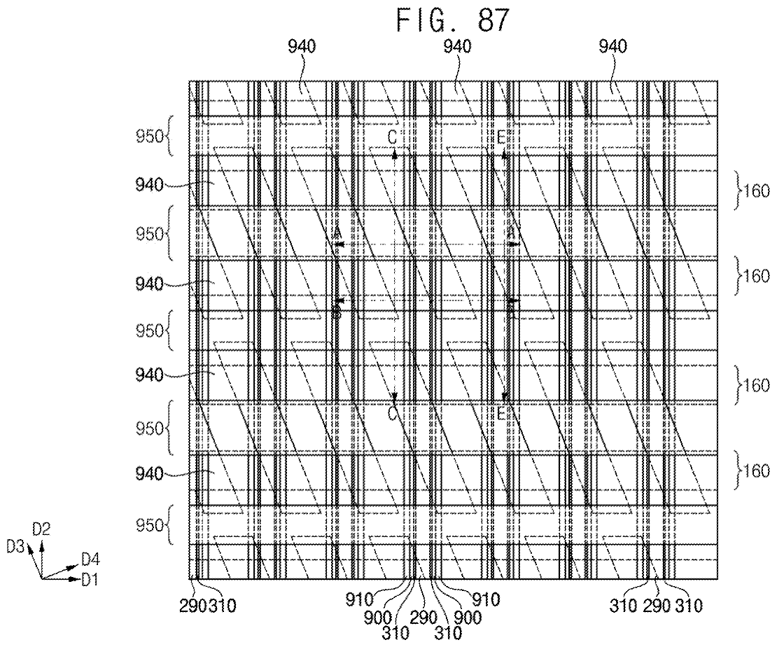

Referring to FIGS. 87 to 89, a fifth contact layer may be formed on the filling structure 340, the second contact structure 370, the first and second mold layers 170 and 175, the bit line structure 300, the second spacer 310 and the fourth spacer structure 920 to fill the thirteenth opening 930, and may be planarized until the upper surface of the bit line structure 300 is exposed to form the fifth contact layer in the thirteenth opening 930.

A fourth etching mask having a fourteenth opening extending in the first direction D1 may be formed on the bit line structure 300, the second spacer 310, the fourth spacer structure 920 and the fifth contact layer, and an etching process may be performed using the fourth etching mask to partially etch the fifth contact layer, an upper portion of the filling structure 340 and the second mold layer 175, and thus the second mold layer 175 extending in the first direction D1 may remain only under the bit line structure 300 to be divided into a plurality of second mold layers 175 spaced apart from each other in the first direction D1.

During the etching process, the upper lateral portion of the second contact structure 370 adjacent to the second mold layer 175 may also be partially removed. Accordingly, a fifteenth opening may be formed through the fifth contact layer to expose the upper surface of the isolation pattern 110, the upper sidewall of the second contact structure 370 adjacent to the upper surface of the isolation pattern 110, the upper surface of the filling structure 340 and the sidewall of the first spacer 230.

The fifth contact layer extending in the second direction D2 may be divided into fifth contact structures 940 spaced apart from each other in the second direction D2. In an implementation, during the etching process, the upper portion of the second mask 290 of the portion of the bit line structure 300 exposed by the fifteenth opening may be etched to be removed, and thus portions of the second spacer 310 and the fourth spacer structure 920 on the upper surface and the upper sidewall of the portion of the bit line structure 300 may also be removed.

In an implementation, the fifteenth opening may extend in the first direction D1 between the fifth contact structures 940, however, a bottom of a portion of the fifteenth opening on the bit line structure 300 may be higher than bottoms of other portions of the fifteenth opening.

A fourth fence pattern 950 may be formed in the fifteenth opening.

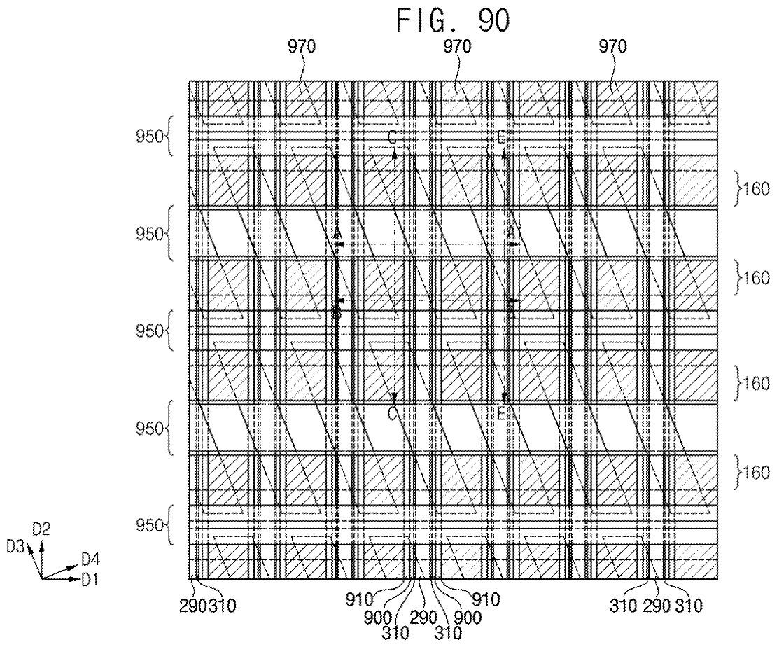

Referring to FIGS. 90 to 92, an upper portion of the fifth contact structure 940 may be removed by, e.g., an etch back process to reduce the height of an upper surface of the fifth contact structure 940.

In an implementation, during the etch back process, an upper portion of a portion of the fifth contact structure 940 under the fourth fence pattern 950 may not be removed.

A fourth ohmic contact pattern 960 and a sixth contact structure 970 may be sequentially formed on the fifth contact structure 940.

Referring back to FIGS. 81 to 83, processes substantially the same as or similar to those described with reference to FIGS. 40 to 42 and FIGS. 1 to 3 may be performed to complete the fabrication of the semiconductor.

By way of summation and review, as the DRAM device has been highly integrated, an area of each of the contact plug structures and a corresponding one of the active patterns contacting each other may decrease, so that electrical connection therebetween may be impacted.

One or more embodiments may provide a DRAM device.

One or more embodiments may provide a semiconductor device having improved electrical characteristics.

In the semiconductor device in accordance with example embodiments, the contact structure on the active pattern may be formed to be self-aligned with the bit line structure, and may have a rectangular shape in a plan view. Thus, the contact structure may establish a broad surface contact with the underlying active pattern and the overlying conductive structure so as to have an enhanced electrical connection thereto, and a total resistance of the active pattern, the contact structure and the conductive structure may decrease.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
an active pattern array including active patterns on the substrate;
a first contact structure on a central portion of each of the active patterns;
at least one bit line structure on the first contact structure;
a second contact structure on an end portion of each of the active patterns;
at least one third contact structure on the second contact structure; and
a capacitor electrically connected to the at least one third contact structure,
wherein:
the active pattern array includes active pattern rows spaced apart from each other in a second direction substantially parallel to an upper surface of the substrate,
each of the active pattern rows includes the active patterns spaced apart from each other in a first direction substantially parallel to the upper surface of the substrate and substantially orthogonal to the second direction,
each of the active patterns extends in a third direction having an acute angle with the first direction and the second direction,
the active patterns in each of the active pattern rows are aligned in the first direction, and
the second contact structure has a rectangular shape in a plan view.

2. The semiconductor device as claimed in claim 1, wherein the second contact structure includes polysilicon doped with impurities.

3. The semiconductor device as claimed in claim 2, further comprising an ohmic contact pattern on the second contact structure, the ohmic contact pattern including a metal silicide.

4. The semiconductor device as claimed in claim 1, wherein the at least one third contact structure has a lower portion and an upper portion, the lower portion having a first width, and the upper portion having a second width greater than the first width.

5. The semiconductor device as claimed in claim 1, wherein the first contact structure includes a pad, an ohmic contact pattern, and a metal pattern sequentially stacked in a vertical direction substantially perpendicular to the upper surface of the substrate, the pad including polysilicon doped with impurities, the ohmic contact pattern including a metal silicide, and the metal pattern including a metal.

6. The semiconductor device as claimed in claim 1, further comprising a spacer surrounding a sidewall of the second contact structure and including silicon oxide.

7. The semiconductor device as claimed in claim 1, further comprising an isolation pattern covering sidewalls of the active patterns,
wherein the at least one bit line structure extends in the second direction on the active patterns and the isolation pattern.

8. The semiconductor device as claimed in claim 7, further comprising a first buffer, a second buffer, and a third buffer sequentially stacked on the at least one bit line structure and the isolation pattern in a vertical direction substantially perpendicular to the upper surface of the substrate, the first buffer including silicon oxide, the second buffer including a high-k material, and the third buffer including silicon nitride.

9. The semiconductor device as claimed in claim 7, further comprising gate structures, each of the gate structures extending in the first direction through upper portions of the active patterns and the isolation pattern,
wherein the first contact structure is on an upper surface of a portion of each of the active patterns between the gate structures.

10. The semiconductor device as claimed in claim 7, wherein:
the at least one bit line structure includes a plurality of bit line structures spaced apart from each other in the first direction,
the at least one third contact structure includes a plurality of third contact structures, and
the semiconductor device further includes a fence pattern on the substrate, the fence pattern extending in the first direction and separating the third contact structures adjacent to each other in the second direction.

11. A semiconductor device, comprising:
a substrate;
an active pattern on the substrate;
a first contact structure on a central portion of the active pattern;
a bit line structure on the first contact structure;
a second contact structure on an end portion of the active pattern;
a third contact structure on the second contact structure;
a spacer surrounding the third contact structure and having a lower portion and an upper portion, a thickness of the upper portion being smaller than a thickness of the lower portion;
a landing pad on the third contact structure; and
a capacitor on the landing pad.

12. The semiconductor device of claim 11, wherein:
the second contact structure includes polysilicon doped with impurities, and
the third contact structure includes a metal.

13. The semiconductor device as claimed in claim 11, wherein the third contact structure has a lower portion and an upper portion, the lower portion having a first width, and the upper portion having a second width greater than the first width.

14. The semiconductor device as claimed in claim 11, wherein the spacer includes an oxide.

15. The semiconductor device as claimed in claim 11, further comprising an ohmic contact pattern between the second contact structure and the third contact structure, the ohmic contact pattern including a metal silicide.

16. The semiconductor device as claimed in claim 11, wherein the first contact structure includes a pad, an ohmic contact pattern, and a metal pattern sequentially stacked in a vertical direction substantially perpendicular to an upper surface of the substrate, the pad including polysilicon doped with impurities, the ohmic contact pattern including a metal silicide, and the metal pattern including a metal.

17. A semiconductor device, comprising:
a substrate;
an active pattern array including active patterns on the substrate;
an isolation pattern on the substrate, the isolation pattern covering sidewalls of the active patterns;
gate structures spaced apart from each other in a second direction substantially parallel to an upper surface of the substrate, each of the gate structures extending through upper portions of the active patterns and the isolation pattern in a first direction substantially parallel to the upper surface of the substrate and substantially orthogonal to the second direction;
bit line structures on central portions of the active patterns and the isolation pattern, each of the bit line structures extending in the second direction, and the bit line structures being spaced apart from each other in the first direction;
a first contact structure on an end portion of each of the active patterns;
a second contact structure on the first contact structure; and
a capacitor electrically connected to the second contact structure,
wherein:
the active pattern array includes active pattern rows spaced apart from each other in the second direction,
each of the active pattern rows includes the active patterns spaced apart from each other in the first direction,
each of the active patterns extends in a third direction having an acute angle with the first direction and the second direction,
the active patterns in each of the active pattern rows are aligned in the first direction, and
the second contact structure has a rectangular shape in a plan view.

18. The semiconductor device as claimed in claim 17, further comprising a third contact structure on the second contact structure,
wherein the third contact structure has a lower portion and an upper portion, the lower portion having a first width, and the upper portion having a second width greater than the first width.

19. The semiconductor device as claimed in claim 17, further comprising a spacer surrounding a sidewall of the second contact structure and including silicon oxide.

20. The semiconductor device as claimed in claim 19, wherein the spacer includes a lower portion and an upper portion, a thickness of the upper portion is smaller than a thickness of a lower portion.
